(19) United States
(12) Patent Application Publication
(10) Pub. No.: US 2015/0179623 A1
(43) Pub. Date: Jun. 25, 2015

(54) METHOD FOR MANUFACTURING SEMICONDUCTOR DEVICE

(71) Applicant: RENESAS ELECTRONICS CORPORATION, Kanagawa (JP)

(72) Inventors: Yoshihiro ONO, Kanagawa (JP); Shinji WATANABE, Kanagawa (JP); Tsuyoshi KIDA, Kanagawa (JP); Kentaro MORI, Kanagawa (JP); Kenji SAKATA, Kanagawa (JP); Yusuke YAMADA, Kanagawa (JP)

(21) Appl. No.: 14/567,876

(22) Filed: Dec. 11, 2014

(30) Foreign Application Priority Data
Dec. 25, 2013 (JP) 2013-268033

(51) Int. Cl. H01L 25/00; H01L 23/00; H01L 21/56

(52) U.S. Cl. CPC H01L 25/50; H01L 21/563; H01L 24/83; H01L 2224/8385; H01L 2224/83203; H01L 2224/16227; H01L 2224/16145; H01L 2224/32145; H01L 2224/32225

(57) ABSTRACT

To provide a semiconductor device having improved reliability.

A semiconductor chip is conveyed onto a chip mounting region of a wiring board by means of a bonding jig to electrically couple the semiconductor chip and the wiring board to each other. The bonding jig for mounting the semiconductor chip on the wiring board is equipped with a retention portion for adsorbing and retaining a logic chip, a pressing portion for pressing against the back surface of the semiconductor chip, and a sealing portion to be firmly attached to the peripheral edge portion of the back surface of the semiconductor chip. The surface of the sealing portion to be firmly attached to the back surface of the semiconductor chip is made of a resin.

### CROSS-REFERENCE TO RELATED APPLICATIONS

The disclosure of Japanese Patent Application No. 2013-268033 filed on Dec. 25, 2013 including the specification, drawings and abstract is incorporated herein by reference in its entirety.

### BACKGROUND

The present invention relates to a manufacturing technology of a semiconductor device and a semiconductor device, for example, a technology effective when applied to a semiconductor device having a semiconductor chip mounted on a wiring board so that an electrode formation surface of the semiconductor chip and a chip mounting surface of the wiring board face to each other.

Japanese Unexamined Patent Application Publication No. 2007-67175 (Patent Document 1) and Japanese Unexamined Patent Application Publication No. 2005-191053 (Patent Document 2) describe a method of manufacturing a semiconductor device having a semiconductor chip mounted on a wiring board by a flip chip coupling method so that the electrode formation surface of the semiconductor chip faces to the chip mounting surface of the wiring board. According to Patent Document 1 and Patent Document 2, after the semiconductor chip is placed on the wiring board via NCP (non-conductive paste), the back surface of the chip is pressed to couple the semiconductor chip to the package substrate.

Registered Utility Model No. 3067421 (Patent Document 3) describes a bonding tool for bonding a chip (IC) onto a board having thereon an anisotropic conductive film and an adhesive.
[Patent Document 1] Japanese Unexamined Patent Application Publication No. 2007-67175
[Patent Document 2] Japanese Unexamined Patent Application Publication No. 2005-191053
[Patent Document 3] Registered Utility Model No. 3067421

### SUMMARY

The present inventors have investigated a semiconductor device obtained through the so-called flip chip coupling method in which a semiconductor chip is mounted on a wiring board by facing the electrode formation surface of the semiconductor chip and the chip mounting surface of the wiring board to each other.

In the flip chip coupling method, a plurality of bump electrodes formed on the electrode formation surface of the semiconductor chip is electrically coupled to a plurality of terminals formed on the chip mounting surface of the wiring board, respectively, at the time of mounting the semiconductor chip.

In addition, in the flip chip coupling method, a resin (underfill resin) is placed between the semiconductor chip and the wiring board so as to seal the electrically coupled portion between the bump electrode and the terminal of the wiring board.

The flip chip coupling method is preferred because since no wire is placed in an electrically coupling path between the semiconductor chip and the wiring board, a current path can be shortened. In addition, the flip chip coupling method is preferred because since no wire is placed in the electrically coupling path between the semiconductor chip and the wiring board, the thickness of a semiconductor package can be reduced.

However, the investigation by the present inventors has revealed that the semiconductor device obtained using the flip chip coupling method has a problem in the reliability thereof.

The other problem and novel features of the invention will be apparent from the description herein and accompanying drawings.

In one aspect of the present invention, there is provided a method of manufacturing a semiconductor device including a step of mounting a first semiconductor chip on a first surface of a wiring board via a first adhesive material. The step of mounting the first semiconductor chip includes a step of adsorbing and retaining a first back surface of the first semiconductor chip by means of a bonding tool and conveying the first semiconductor chip onto the first adhesive material. The step of mounting the first semiconductor chip also includes a step of pressing the bonding tool against the first semiconductor chip from the side of the first back surface thereof to electrically couple a plurality of terminals of the wiring board to a plurality of first surface electrodes of the first semiconductor chip. The bonding tool is equipped with a retention portion for adsorbing and retaining the first semiconductor chip, a pressing portion for pressing against the first back surface of the first semiconductor chip, and a sealing portion to be firmly attached to the peripheral edge portion of the first back surface of the first semiconductor chip. A surface of the sealing portion to be firmly attached to the first back surface of the first semiconductor chip is made of a resin.

According to the above-mentioned aspect, a semiconductor device having improved reliability can be provided.

### BRIEF DESCRIPTION OF THE DRAWINGS

FIG. 1 is a perspective view of a semiconductor device according to First Embodiment of the invention;

FIG. 2 is a bottom view of the semiconductor device shown in FIG. 1;

FIG. 3 is a perspective plan view showing the inside structure of the semiconductor device on a wiring board while removing the sealing body shown in FIG. 1;

FIG. 4 is a cross-sectional view taken along the line A-A of FIG. 1;

FIG. 5 is an explanatory view schematically showing a circuit constitution example of the semiconductor device shown in FIGS. 1 to 4:

FIG. 6 is an enlarged cross-sectional view of the portion A shown in FIG. 4;

FIG. 7 is a plan view showing the surface side of the memory chip shown in FIG. 4;

FIG. 8 is a plan view showing one example of the back surface side of the memory chip shown in FIG. 7;

FIG. 9 is a plan view showing the surface side of the logic chip shown in FIG. 4;

FIG. 10 is a plan view showing one example of the back surface side of the logic chip shown in FIG. 9;

FIG. 11 is an explanatory view showing the outline of manufacturing steps of the semiconductor device described referring to FIGS. 1 to 10;

FIG. 12 is a plan view showing the overall structure of a wiring board provided in the substrate providing step shown in FIG. 11;

FIG. 13 is an enlarged plan view of one of the device regions shown in FIG. 12;

FIG. 14 is an enlarged cross-sectional view taken along the line A-A of FIG. 13;

FIG. 15 is an enlarged plan view showing a surface on the side opposite to that of FIG. 13;

FIG. 16 is an enlarged plan view showing an adhesive material placed in the chip mounting region shown in FIG. 13;

FIG. 17 is an enlarged cross-sectional view taken along the line A-A of FIG. 16;

FIG. 18 is a side view schematically showing an adhesive material placed on the wiring board shown in FIG. 17;

FIG. 19 is a side view schematically showing the adhesive material shown in FIG. 18 pressed against the wiring board by means of a roller;

FIG. 20 is an enlarged plan view showing a portion of the adhesive material pressed against the wiring board prior to the step shown in FIG. 19;

FIG. 21 is an explanatory view schematically showing the outline of manufacturing steps of the semiconductor chip having through electrodes shown in FIG. 6;

FIG. 22 is an explanatory view schematically showing the outline of manufacturing steps following those of FIG. 21;

FIG. 23 is an enlarged plan view showing the logic chip LC mounted on the chip mounting region of the wiring board shown in FIG. 16;

FIG. 24 is an enlarged cross-sectional view taken along the line A-A of FIG. 23;

FIG. 25 is an explanatory view schematically showing the logic chip placed over the adhesive material placed on the wiring board in the first chip mounting step shown in FIG. 11;

FIG. 26 is an explanatory view schematically showing the logic chip and the wiring board electrically coupled to each other in the first chip mounting step shown in FIG. 11;

FIG. 27 is an explanatory view schematically showing an aspect in which the logic chip is pressed while having a resin film between a bonding tool and the logic chip, which is an investigation example different from the example shown in FIG. 26;

FIG. 28 is a plan view of a surface of the bonding tool shown in FIGS. 25 and 26 placed so as to face to the semiconductor chip;

FIG. 29 is an enlarged plan view showing the adhesive materials placed on the back surface and therearound of the semiconductor chip shown in FIG. 17;

FIG. 30 is an enlarged cross-sectional view taken along the line A-A of FIG. 29;

FIG. 31 is an explanatory view schematically showing the outline of fabrication steps of the memory chip stack shown in FIG. 4;

FIG. 32 is an explanatory view schematically showing the outline of fabrication steps of the memory chip stack following that of FIG. 31;

FIG. 33 is an enlarged plan view showing the chip stack mounted on the back surface of the logic chip shown in FIG. 29;

FIG. 34 is an enlarged cross-sectional view taken along the line A-A of FIG. 33;

FIG. 35 is an explanatory view schematically showing the chip stack placed over the logic chip in the second chip mounting step shown in FIG. 11;

FIG. 36 is an explanatory view schematically showing the logic chip and the chip stack electrically coupled to each other in the second chip mounting step shown in FIG. 11;

FIG. 37 is an enlarged cross-sectional view showing stacked semiconductor chips sealed with a sealing body formed on the wiring board shown in FIG. 34;

FIG. 38 is a plan view showing an overall structure of the sealing body shown in FIG. 37;

FIG. 39 is an enlarged cross-sectional view showing solder balls bonded onto a plurality of lands of the wiring board shown in FIG. 37;

FIG. 40 is a cross-sectional view showing the multipiece wiring board shown in FIG. 39 after singulation;

FIG. 41 is a cross-sectional view showing a modification example of the bonding jig shown in FIG. 25;

FIG. 42 is a cross-sectional view showing another modification example of the bonding jig shown in FIG. 25;

FIG. 43 is a cross-sectional view showing a further modification example of the bonding jig shown in FIG. 25;

FIG. 44 is a plan view of the surface of the bonding jig shown in FIG. 43 placed so as to face to the semiconductor chip;

FIG. 45 is a cross-sectional view showing a modification example of the bonding jig shown in FIG. 43;

FIG. 46 is a cross-sectional view showing another modification example of the bonding jig shown in FIG. 45;

FIG. 47 is a cross-sectional view showing a still further modification example of the bonding jig shown in FIG. 25;

FIG. 48 is a plan view of the surface of the bonding jig shown in FIG. 47 placed so as to face to the semiconductor chip;

FIG. 49 is a side view showing a modification example of FIG. 18;

FIG. 50 is a plan view showing the side of the surface of the film conveyor jig shown in FIG. 49 facing to the adhesive material;

FIG. 51 is a cross-sectional view, in a cross-section taken along the line A-A of FIG. 50, schematically showing the adhesive material NCL1 pressed with a protruding portion of the film conveyor jig;

FIG. 52 is a plan view showing a semiconductor device on the side of a chip mounting surface thereof, which device is a modification example of the semiconductor device shown in FIG. 3;

FIG. 53 is an enlarged plan view showing a paste-like adhesive material placed in a chip mounting region of a wiring board, shown as a modification example of FIG. 16;

FIG. 54 is an enlarged plan view showing a logic chip LC mounted in the chip mounting region of the wiring board shown in FIG. 53;

FIG. 55 is an explanatory view schematically showing a logic chip mounted over the adhesive material placed on the wiring board shown in FIG. 53 in a first chip mounting step;

FIG. 56 is an explanatory view schematically showing the logic chip and the wiring board, each shown in FIG. 55, electrically coupled to each other;

FIG. 57 is an explanatory view schematically showing, by an arrow, a spreading direction of the adhesive shown in FIG. 53 in the first chip mounting step;

FIG. 58 is a plan view of a semiconductor device, which is a modification example of the semiconductor device shown in FIG. 52, on the side of the chip mounting surface;

FIG. 59 is an enlarged plan view showing a boundary portion of a region of the logic chip mounting region of the semiconductor device shown in FIG. 58;

FIG. 60 is an enlarged cross-sectional view taken along the line A-A of FIG. 59;

FIG. 61 is an enlarged plan view showing a boundary portion of a logic chip mounting region of a semiconductor device which is a modification example of that of FIG. 59;

FIG. 62 is an enlarged plan view showing a boundary portion of a logic chip mounting region of a semiconductor device which is a modification example of the semiconductor device shown in FIG. 52; and

FIG. 63 is a cross-sectional view of a semiconductor device which is a modification example of the semiconductor device shown in FIG. 4.

### DETAILED DESCRIPTION

### (Explanation of Description Manner, Basic Terms, and Usage in the Present Application)

In the present application, a description in each aspect may be made after divided in a plurality of sections if necessary for the sake of convenience. These sections are not independent from each other unless otherwise particularly specified, but they may each be a part of a single example or one of them may be a partial detail of the other or a modification example of a part or whole of the other one irrespective of their order of appearance. In principle, a description of a portion similar to that described before is omitted. Moreover, constituent components in each aspect are not essential unless otherwise particularly specified, limited to the number theoretically, or apparent from the context.

Similarly, in the description of each aspect or the like, the term “X made of A” or the like with regard to a material, component, or the like does not exclude a member including a component other than A unless otherwise particularly specified or unless otherwise evident from the context. For example, with regard to a component, the above term means “X containing A as a principal component” or the like. It is needless to say that for example, the term “silicon member” or the like is not limited to a pure silicon member but it may include a member containing a multicomponent alloy having silicon as a main component such as SiGe alloy, an additive, and the like. In addition, the term “gold plating”, “Cu layer”, “nickel plating”, or the like includes not only a pure member but also a member containing gold, Cu, nickel, or the like as a main component, respectively, unless otherwise particularly specified.

When a reference is made to a specific numerical value or amount, it may be more than or less than the specific numerical value or amount unless otherwise particularly specified, limited to the specific numerical value or amount theoretically, or apparent from the context.

In all the drawings in the embodiment, the same or like members will be identified by the same or like symbols or reference numerals and overlapping descriptions will be omitted in principle.

In the accompanying drawings, hatching or the like is sometimes omitted even from the cross-section when it makes the drawing complicated or when a member can be distinguished clearly from a vacant space. In relation thereto, even a planarly closed hole may be shown without a background contour thereof when it is obvious from the description or the like that the hole is planarly closed. On the other hand, in order to clearly show that a region is not a vacant space or to clearly show a boundary of regions, hatching or a dot pattern may be added even when the drawing is not a cross-sectional view.

In the application, the term “upper surface” or “lower surface” is sometimes used. A semiconductor device has various packaging aspects. After packaging of a semiconductor device is completed, for example, the upper surface thereof may come below the lower surface. In the present application, the plane of a semiconductor chip on the element formation surface side will hereinafter be called “upper surface” or “main surface”, while the plane on the side opposite to the upper surface will hereinafter be called “lower surface” or “back surface”.

### First Embodiment

In the present embodiment, a semiconductor device having a plurality of semiconductor chips stacked one after another will be described as an example of a semiconductor device using the flip chip mounting method. More specifically, the semiconductor device which will be described as an example in the present embodiment is a so-called “SIP” (system in package) semiconductor device having a plurality of semiconductor chips stacked one after another so as to have an arithmetic processing circuit on a memory circuit and therefore having a system in one package.

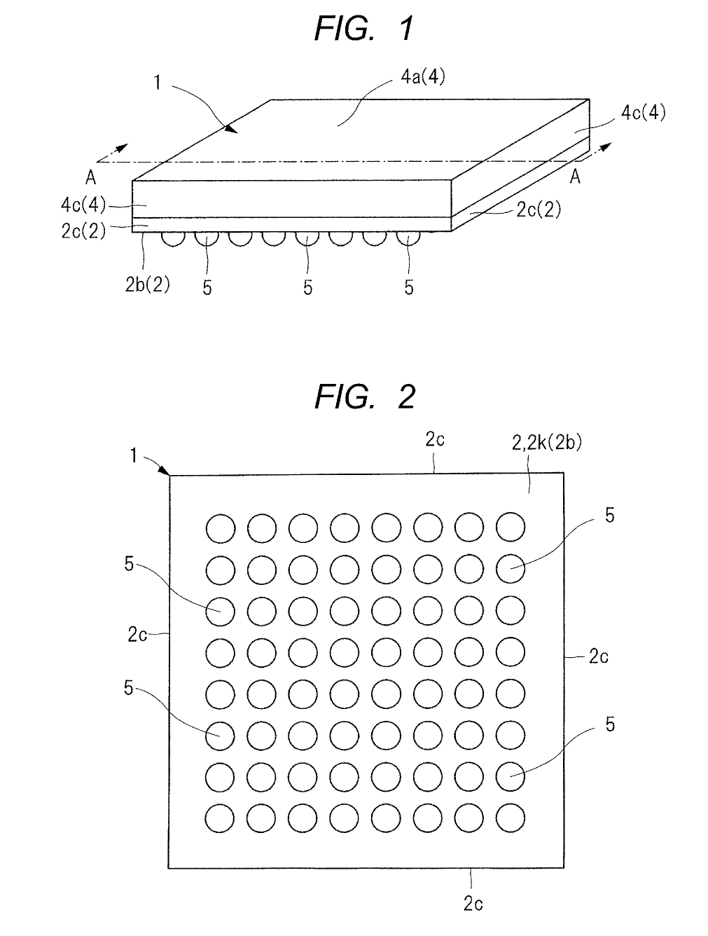

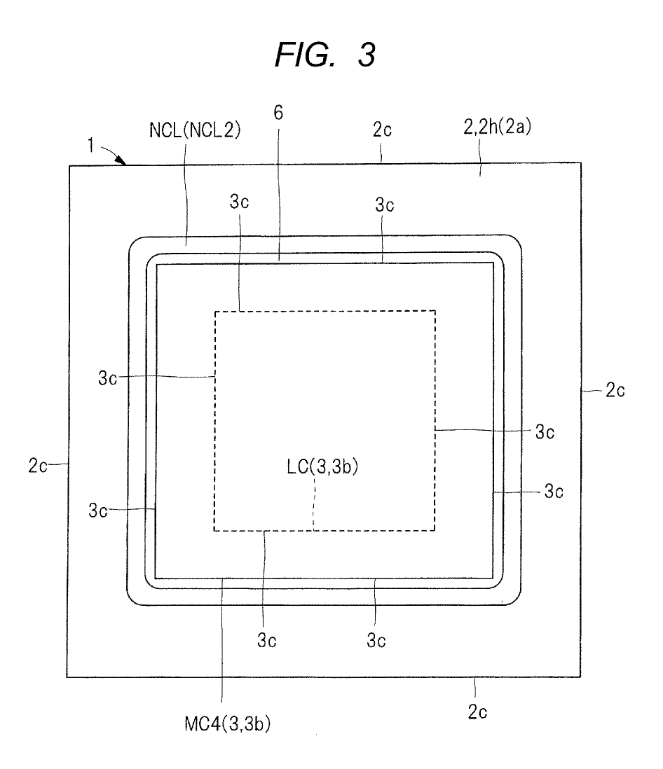

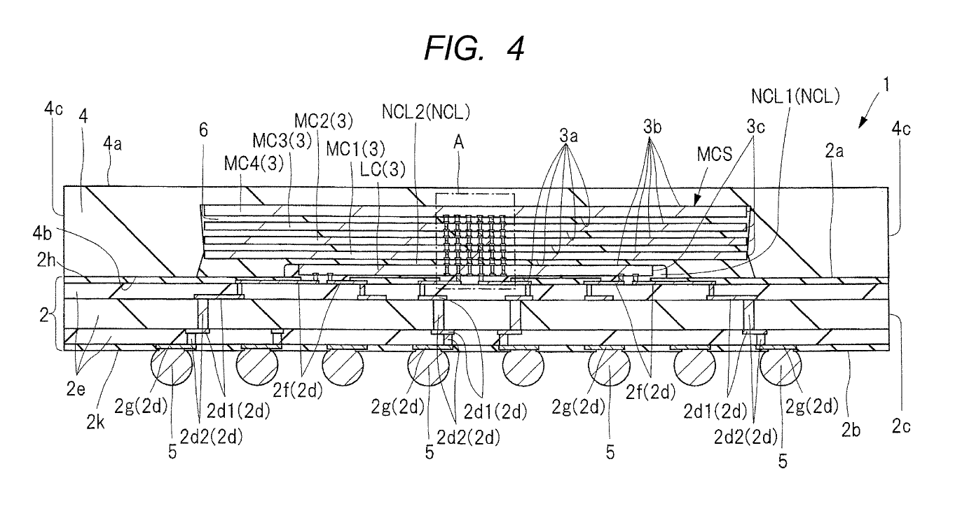

FIG. 1 is a perspective view of the semiconductor device according to First Embodiment of the invention; and FIG. 2 is a bottom view of the semiconductor device shown in FIG. 1. FIG. 3 is a transparent plan view showing the inside structure of the semiconductor device on the wiring board while removing the sealing body shown in FIG. 1. FIG. 4 is a cross-sectional view taken along the line A-A of FIG. 1. To facilitate viewing of FIGS. 1 to 4, the number of terminals is decreased, but the number of terminals (bonding leads 2f, lands 2g, solder balls 5) is not limited to the aspect shown in FIGS. 1 to 4. In FIG. 3, to clearly show a difference in the positional relationship or planar size, in plan view, between the logic chip LC and the memory chip MC4, the logic chip is defined with a dotted line.

### <Semiconductor Device>

As shown in FIG. 4, a wiring board 2 has an upper surface (surface, chip mounting surface) 2a having a plurality of semiconductor chips 3 thereon, a lower surface (surface, packaging surface) 2b on the side opposite to the upper surface 2a, and a side surface 2c placed between the upper surface 2a and the lower surface 2b. As shown in FIGS. 2 and 3, it has a square profile in plan view. In the example shown in FIGS. 2 and 3, with regard to the planar size (size in plan view, size of the upper surface 2a and the lower surface 2b, profile size), the wiring board 2 is, for example, a square, about 14 mm on a side. In addition, the wiring board 2 has a thickness (height), that is, a distance from the upper surface 2a to the lower surface 2b in FIG. 4, of for example, from about 0.2 mm to 0.5 mm.

The wiring board 2 is an interposer for electrically coupling the semiconductor chip 3 mounted on the upper surface 2a side thereof to a packaging substrate not shown and has a plurality of wiring layers (four layers in the example shown in FIG. 4) for electrically coupling the upper surface 2a side and the lower surface 2b side to each other. The wiring layers each have a plurality of wirings 2d and an insulating layer 2e for insulating between the wirings 2d or between wiring layers adjacent to each other. In the present embodiment, the wiring board 2 has three insulating layers 2e. The middle insulating layer 2e is a core layer (core material), but as the wiring board, a board not having the insulating layer 2e as a core, a so-called coreless board may be used. The wiring 2d includes a wiring 2d1 formed on the upper surface or lower surface of the insulating layer 2e and a via wiring 2d2 which is an interlayer conduction path penetrating through the insulating layer 2e in a thickness direction.

The wiring board 2 has, on the upper surface 2a thereof, a plurality of bonding leads (terminals, chip mounting side terminals, electrodes) 2f which are terminals to be electrically coupled to the semiconductor chip 3. On the other hand, the wiring board 2 has, on the lower surface 2b thereof, a plurality of lands 2g to which terminals for electrically coupling to a packaging board not shown, that is, a plurality of solder balls 5 serving as external coupling terminals of the semiconductor device 1 has been bonded. A plurality of the bonding leads 2f and a plurality of the lands 2g are electrically coupled to each other via a plurality of the wirings 2d, respectively. The wirings 2d to be coupled to the bonding leads 2f and the lands 2g are integrally formed with the bonding leads 2f and the lands 2g so that the bonding leads 2f and the lands 2g are each shown in FIG. 4 as a portion of the wiring 2d.

The wiring board 2 has the upper surface 2a and the lower surface 2b covered with insulating films (solder resist films) 2h and 2k, respectively. The wirings 2d formed on the upper surface 2a of the wiring board 2 are covered with the insulating film 2h. The insulating film 2h has therein an opening portion and from this opening portion of the insulating film 2h, at least a portion (junction with the semiconductor chip 3, bonding region) of each of the bonding leads 2f is exposed. Further, the wirings 2d formed on the lower surface 2b of the wiring board 2 are covered with the insulating film 2k. The insulating film 2k has therein an opening portion and from this opening portion of the insulating film 2k, at least a portion (junction with the solder balls 5) of each of the lands 2g is exposed.

A plurality of the solder balls (external terminals, electrodes, external electrodes) to be bonded to a plurality of the lands 2g on the lower surface 2b of the wiring board 2 as shown in FIG. 4 is arranged in rows and columns (in array form, in matrix form) as shown in FIG. 2. Although not illustrated in FIG. 2, a plurality of the lands 2g (refer to FIG. 4) to which a plurality of the solder balls 5 is bonded is also arranged in rows and columns (in matrix form). A semiconductor device having, on the packaging surface side of the wiring board 2, a plurality of external terminals (solder balls 5, lands 2g) arranged in rows and columns as described above is called an area-array type semiconductor device.

The area array type semiconductor device 1 is preferred because due to effective use of the packaging surface (lower surface 2b) side of the wiring board 2 as an arrangement space of external terminals, an increase in packaging area of the semiconductor device 1 can be suppressed even if the number of external terminals increases. This means that the semiconductor device 1 having an increased number of external terminals as its function and integration degree are improved can be packaged while saving a space.

The semiconductor device 1 is equipped with a semiconductor chip 3 to be mounted on the wiring board 2. In the example shown in FIG. 4, the wiring board 2 has, on the upper surface 2a thereof, a stack of a plurality of the semiconductor chips 3. These semiconductor chips 3 each have a surface (main surface, upper surface) 3a, a back surface (main surface, lower surface) 3b on the side opposite to the surface 3a, and a side surface 3c located between the surface 3a and the back surface 3b. It has a square profile in a plan view as shown in FIG. 3. Even by stacking a plurality of the semiconductor chips 3 to provide the semiconductor device 1 having an improved function, the packaging area can be reduced.

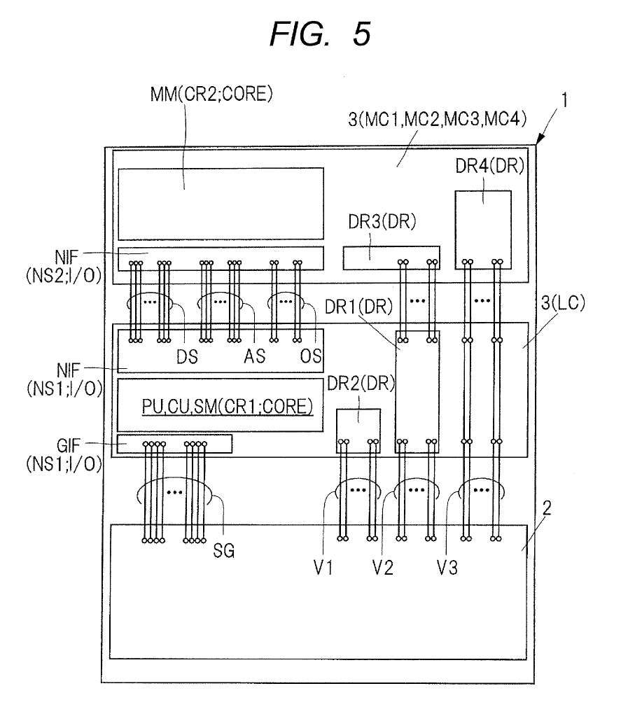

In the example shown in FIGS. 3 and 4, the semiconductor chip mounted on the bottom (at a position proximate to the wiring board 2) is a logic chip (semiconductor chip) LC having an arithmetic processing circuit PU (refer to FIG. 5). The semiconductor chips 3 mounted over the logic chip LC are memory chips (semiconductor chips) MC1, MC2, MC3, and MC4 each having thereon a main memory circuit (memory circuit) MM (refer to FIG. 5) for storing data to be communicated between them and the logic chip LC. The logic chip LC has, in addition to the above-mentioned arithmetic processing circuit, a control circuit for controlling the operation of the main memory circuit of the memory chips MC1, MC2, MC3, and MC4. The circuit constitution example of the semiconductor device 1 will be described later.

As shown in FIG. 4, an adhesive material NCL (insulating adhesive material) is placed between the logic chip LC mounted on the wiring board 2 and the wiring board 2 and also between the logic chip LC and the memory chip MC1. The adhesive material NCL is arranged so as to fill a space between the surface of the semiconductor chip 3 and the back surface 3b (or the upper surface 2a of the wiring board 2) of the semiconductor chip 3 lying therebelow.

Described specifically, this adhesive material NCL includes an adhesive material (insulating adhesive material) NCL1 for attaching and fixing the logic chip LC onto the wiring board 2 and an adhesive material (insulating adhesive material) NCL2 for attaching and fixing the chip stack MCS of the memory chips MC1, MC2, MC3, and MC4 onto the logic chip. The adhesive materials NCL1 and NCL2 are each made of an insulating (nonconductive) material (for example, a resin material). With the adhesive material NCL placed at a junction between the logic chip LC and the wiring board 2 and a junction between the logic chip LC and the stack chip MCS, a plurality of electrodes provided at the junctions can be electrically insulated from each other and at the same time, each of the junctions can be protected.

In the example shown in FIG. 4, the memory chips MC1, MC2, MC3, and MC4 have therebetween a sealing body (sealing body for stacked chips, resin body for stacked chips) 6 different from a sealing body 4 and the chip stack MCS of the memory chips MC1, MC2, MC3, and MC4 is sealed with the sealing body 6. The sealing body 6 is filled so as to firmly attach to the surface 3a and the back surface 3b of the memory chips MC1, MC2, MC3, and MC4 and the chip stack MCS of the memory chips MC1, MC2, MC3, and MC4 is integrated by the joint between the semiconductor chips 3 and the sealing body 6. The sealing body 6 is made of an insulating (nonconductive) material (for example, a resin material) and the sealing body 6 arranged at each of the junctions of the memory chips MC1, MC2, MC3, and MC4 contributes to electrical insulation between the electrodes provided at each of the junctions.

As shown in FIG. 4, however, the surface 3a of the memory chip MC1 mounted on the bottom (at a position proximate to the logic chip LC) of the chip stack MCS of the memory chips MC1, MC2, MC3, and MC4 is exposed from the sealing body 6. In addition, as shown in FIGS. 3 and 4, the back surface 3b of the memory chip MC4 arranged on the top of the chip stack MCS of the memory chips MC1, MC2, MC3, and MC4 is exposed from the sealing body 6.

The semiconductor device 1 is equipped with a sealing body 4 for sealing a plurality of the semiconductor chips 3. The sealing body 4 has an upper surface (plane, surface) 4a, a lower surface (plane, back surface, packaging surface) 4b on the side opposite to the upper surface 4a (refer to FIG. 4), and a side surface 4c placed between the upper surface 4a and the lower surface 4b. It has a square profile in plan view. In the example shown in FIG. 1, the planar size (size in plan view from the upper surface 4a side, profile size of the upper surface 4a) of the sealing body 4 is equal to that of the wiring board 2 and the side surface 4c of the sealing body 4 is coupled with the side surface 2c of the wiring board 2. In the example shown in FIG. 1, with regard to a planar size (size in plan view), the sealing body 4 is a square, about 14 mm on a side.

The sealing body 4 is a resin body for protecting a plurality of the semiconductor chips 3. The sealing body 4 formed so as to firmly attach to between the semiconductor chips 3 and between the semiconductor chip 3 and the wiring board 2 can prevent the thin semiconductor chips 3 from being damaged. The sealing body 4 is made of, for example, the following material from the standpoint of improving the function as a protecting member. Since the sealing body 4 is required to be attached easily to between the semiconductor chips 3 and between the semiconductor chip 3 and the wiring board 2 and at the same time, is required to have a certain level of hardness after sealing, it is preferred to contain a thermosetting resin such as epoxy resin. In addition, to provide a sealing body 4 having an improved function after curing, using a resin material containing filler particles such as silica (silicon dioxide: SiO₂) particles is preferred. For example, from the standpoint of suppressing the semiconductor chip 3 from being damaged due to thermal deformation after formation of the sealing body 4, it is preferred to adjust a mixing ratio of the filler particles and thereby reduce a difference in linear expansion coefficient between the semiconductor chip 3 and the sealing body 4.

### <Circuit Constitution of Semiconductor Device>

Next, a circuit constitution example of the semiconductor device 1 will be described. As shown in FIG. 5, the logic chip LC has, in addition to the above-mentioned arithmetic processing circuit PU, a control circuit CU for controlling the operation of the main memory circuit MM of the memory chips MC1, MC2, MC3, and MC4. The logic chip LC also has auxiliary memory circuits (memory circuits) SM, such as cash memory for temporarily storing data, having a storage capacity smaller than that of the above-mentioned main memory circuit MM. In FIG. 5, as one example, the arithmetic processing circuit PU, the control circuit CU, and the auxiliary memory circuit SM are collectively called “core circuit” (main circuit) CR1. The core circuit CR1 however may include a circuit other than those described above.

The logic circuit also has an external interface circuit (external input/output circuit) GIF for inputting/outputting a signal between this circuit and an external apparatus not shown. The external interface circuit GIF has a signal line SG coupled thereto for sending a signal between the logic chip LC and the external apparatus not shown. Further, the external interface circuit GIF is electrically coupled to the core circuit CR1 so that the core circuit CR1 can send a signal to the external apparatus via the external interface circuit GIF.

The logic chip LC further has an internal interface circuit (internal input/output circuit) for inputting/outputting a signal between this circuit and an internal apparatus (for example, the memory chips MC1, MC2, MC3, and MC4). The internal interface circuit NIF has, coupled thereto, a data line (signal line) DS for sending a data signal, an address line (signal line) AS for sending an address signal, and a signal line OS for sending another signal. These data line DS, address line AS, and signal line OS are each coupled to the internal interface circuit NIF of each of the memory chips MC1, MC2, MC3, and MC4. In FIG. 5, circuits, such as the external interface circuit GIF and internal interface circuit NIF, for inputting/outputting a signal between the circuit and electronic parts other than the logic chip LC are collectively shown as “input/output circuit NS1”.

The logic chip LC further has a power circuit DR for supplying a potential for driving the core circuit CR1 or input/output circuit NS1. The power circuit DR includes a power circuit (power circuit for input/output) for supplying a voltage for driving the input/output circuit NS1 of the logic chip LC and a power circuit (power circuit for core) DR2 for supplying a voltage for driving the core circuit CR1 of the logic chip LC. To the power circuit DR are supplied potentials (first power supply potential and second power supply potential) different from each other and a voltage to be applied to the core circuit CR1 or the input/output circuit NS1 is defined by this potential difference.

A semiconductor chip 3, such as the logic chip LC, in which circuits necessary for the operation of an apparatus or a system have been formed intensively is called “SoC” (System on a Chip). If the logic chip LC has the main memory circuit MM shown in FIG. 5, the logic chip LC can include a system alone. Depending on the apparatus or system to be operated, the capacity of the main memory circuit MM (refer to FIG. 5) necessary for it differs. It is therefore possible to improve the versatility of the logic chip LC by forming the main memory circuit MM in the semiconductor chip 3 different from the logic chip LC.

In addition, by coupling the memory chips MC1, MC2, MC3, and MC4 depending on the required storage capacity of the main memory circuit MM, the degree of design freedom of the capacity of the memory circuit which the system has is improved. In the example shown in FIG. 5, the memory chips MC1, MC2, MC3, and MC4 each have a main memory circuit MM. In FIG. 5, the main memory circuit MM is shown as a core circuit (main circuit) CR2 of the memory chips MC1, MC2, MC3, and MC4. The core circuit CR2 may further include a circuit other than the main memory circuit MM.

The memory chips MC1, MC2, MC3, and MC4 each have an internal interface circuit (internal input/output circuit) NIF for inputting/outputting a signal between this circuit and an internal apparatus (for example, the logic chip LC). In FIG. 5, the internal interface circuit NIF for inputting/outputting a signal between this circuit and an electronic part other than each of the memory chips MC1, MC2, MC3, and MC4 is shown as “input/output circuit NS2”.

The memory chips MC1, MC2, MC3, and MC4 further have a power circuit (drive circuit) DR for supplying a potential for driving the core circuit CR2 or the input/output circuit NS2. The power circuit DR includes a power circuit (power circuit for input/output) DR3 for supplying a voltage for driving the input/output circuit NS2 of the memory chips MC1, MC2, MC3, and MC4 and a power circuit (power circuit for core) DR4 for supplying a voltage for driving the core circuit CR2 of the memory chips MC1, MC2, MC3, and MC4. To the power circuit DR2 are supplied a plurality of potentials (for example, a first power supply potential and a second power supply potential) different from each other and a voltage to be applied to the core circuit CR2 or the input/output circuit NS2 is defined by this potential difference.

In the example shown in FIG. 5, the power circuit DR1 of the logic chip LC and the power circuit DR3 of the memory chips MC1, MC2, MC3, and MC4 share power lines. In other words, the input/output circuit NS1 of the logic chip LC and the input/output circuit NS2 of the memory chips MC1, MC2, MC3, and MC4 are driven by application of the same voltage supplied from a power line V2. Thus, by sharing some or all of the power lines of the power circuit DR, the number of power lines V1, V2, and V3 for supplying a potential (drive potential) to the power circuit can be reduced. A reduction in the number of the power lines V1, V2 and V3 leads to a reduction in the number of electrodes formed in the logic chip LC.

A semiconductor device, such as the semiconductor device 1, in which circuits necessary for the operation of an apparatus or system have been formed intensively is called SiP (system in package). FIG. 4 shows an example of four memory chips MC1, MC2, MC3, and MC4 stacked one after another on one logic chip LC, but as described above, there are various modification examples with respect to number of the semiconductor chips 3 stacked. Although not illustrated here, they include a modification example having one memory chip MC1 mounted on one logic chip LC as the minimum constitution.

From the standpoint of improving the versatility of the logic chip LC and the memory chips MC1, MC2, MC3, and MC4, it is preferred to minimize the planar size (size in plan view, size of the surface 3a and the back surface 3b, the profile size) of the logic chip LC and the memory chips MC1, MC2, MC3, and MC4 insofar as the semiconductor chips 3 can exhibit the respective functions. The planar size of the logic chip LC can be reduced by improving the integration degree of the circuit elements. The planar size of the memory chips MC1, MC2, MC3, and MC4, on the other hand, cannot be reduced freely because the capacity or transmission rate (for example, data traffic depending on the width of data bus) of the main memory circuit MM varies based on the planar size.

In the example shown in FIG. 4, therefore, the planar size of the memory chip MC4 is greater than that of the logic chip LC. With regard to the planar size, for example, the memory chip MC4 is a square, from about 8 mm to 10 mm on a side, while the logic chip LC is a square, from about 5 mm to 6 mm on a side. Although not shown here, the planar size of the memory chips MC1, MC2, and MC3 shown in FIG. 4 is equal to that of the memory chip MC4.

As described above, the logic chip LC has the external interface circuit GIF for inputting/outputting a signal between this circuit and an external apparatus not shown so that the logic chip LC is preferably placed on the bottom of the stack of the semiconductor chips 3, that is, placed at a position closest to the wiring board 2 from the standpoint of decreasing the transmission distance between the circuit and the external apparatus. This means that like the constitution of the semiconductor device 1, that obtained by stacking the semiconductor chips 3 (memory chips MC1, MC2, MC3, and MC4) having a larger planar size over the semiconductor chip 3 (logic chip LC) having a smaller planar size is preferred.

### <Structure Example of Semiconductor Chip>

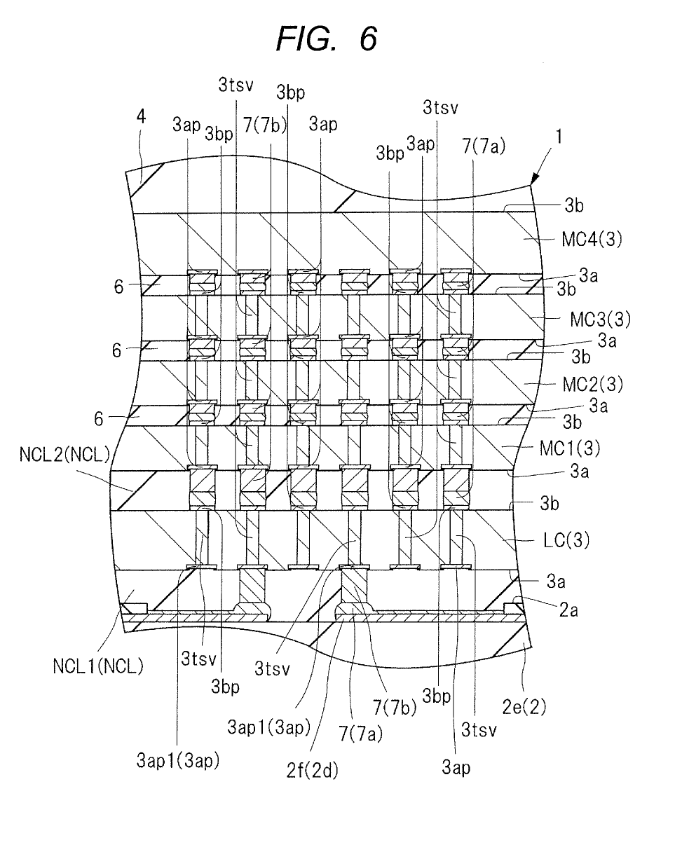

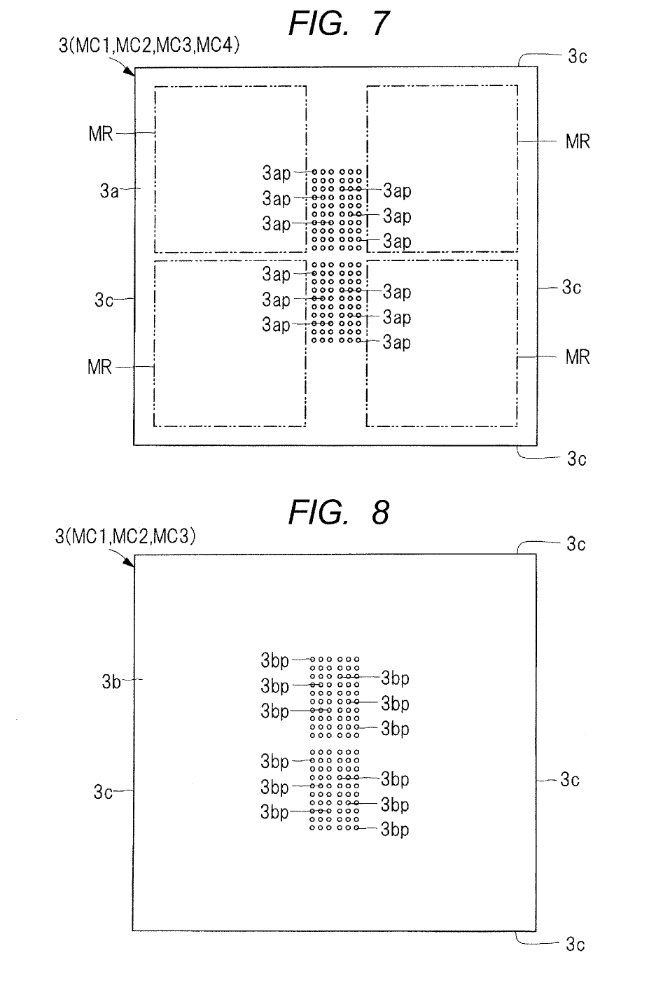

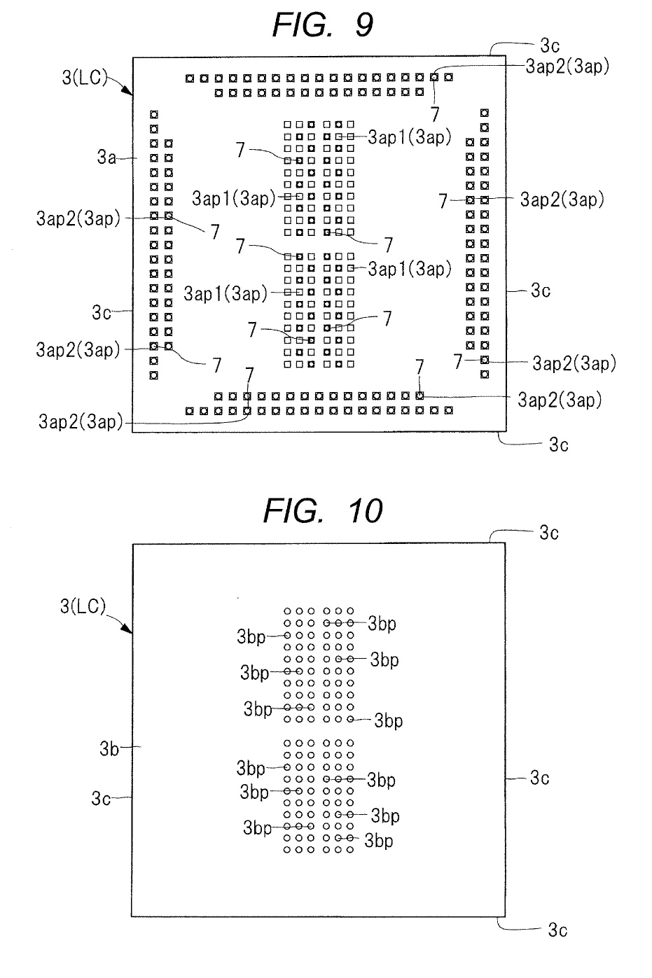

Next, details of the logic chip LC and the memory chips MC1, MC2, MC3, and MC4 shown in FIG. 4 and an electrical coupling method of the semiconductor chips 3 will be described. FIG. 6 is an enlarged cross-sectional view of the portion A shown in FIG. 4. FIG. 7 is a plan view showing the surface side of the memory chip shown in FIG. 4. FIG. 8 is a plan view showing one example of the back surface side of the memory chip shown in FIG. 7. FIG. 9 is a plan view showing the surface side of the logic chip shown in FIG. 4. FIG. 10 is a plan view showing one example of the back surface side of the logic chip shown in FIG. 9. In FIGS. 6 to 10, the number of electrodes is decreased in order to facilitate viewing of them. The number of electrodes (surface electrode 3ap, back-surface electrode 3bp, and through-electrode 3ts) is not limited to the aspect shown in FIGS. 6 to 10. FIG. 8 shows the back-surface view of the memory chips MC1, MC2, and MC3 but does not include the structure of the back surface of the memory chip MC4 (refer to FIG. 4) having no back-surface electrode 3bp because this memory chip is shown in FIG. 3.

The present inventors have investigated a technology for improving the performance of an SiP type semiconductor device. As part of this, they investigated a technology of increasing a signal transmission rate between a plurality of semiconductor chips mounted on the SiP to, for example, 12 Gbps (12 gigabit per second) or more. One of the methods for improving the transmission rate between semiconductor chips mounted on the SiP is to enlarge the width of a data bus of an internal interface and increase a data transmission amount at a time (which will hereinafter be called “bus width enlargement”). Another method is to increase the transmission frequency per unit time (which will hereinafter be called “clock number increase”). Further the bus width enlargement method and the clock number increase method may be employed in combination. The semiconductor device 1 described referring to FIGS. 1 to 5 uses bus width enlargement and clock number increase in combination and thereby has an internal interface transmission rate increased to 12 Gbps or more.

For example, the memory chips MC1, MC2, MC3, and MC4 shown in FIG. 4 are so-called wide I/O memories each having a data bus width of 512 bit. Described specifically, the memory chips MC1, MC2, MC3, and MC4 each have four channels having a data bus width of 128 bit and therefore have a bus width of 512 bit in total. The transmission frequency of each channel per unit hour reaches, for example, 3 Gbps or more due to the clock number increase.

When the crock number increase and bus width enlargement are combined, a large number of data lines should be operated at high speed. From the standpoint of reducing the influence of a noise, decreasing a transmission distance is necessary. As shown in FIG. 4, therefore, the logic chip LC and the memory chip MC1 are electrically coupled to each other via a conductive member placed between the logic chip LC and the memory chip MC1. The memory chips MC1, MC2, MC3, and MC4 are electrically coupled to each other via a conductive member placed between two adjacent ones of the memory chips MC1, MC2, MC3, and MC4. In other words, in the semiconductor device 1, the transmission path between the logic chip LC and the memory chip MC1 includes neither the wiring board 2 nor a wire (bonding wire) not shown. In addition, in the semiconductor device 1, the transmission path between two adjacent ones of the memory chips MC1, MC2, MC3, and MC4 includes neither the wiring board 2 nor a wire (bonding wire) not shown.

In the present embodiment, as a method of directly coupling a plurality of the semiconductor chips 3, employed is a technology of forming a through electrode 3tsv penetrating through the semiconductor chips 3 in a thickness direction and coupling the stacked semiconductor chips 3 by using this through electrode 3tsv. More specifically, as shown in FIG. 6, the logic chip LC has a plurality of surface electrodes (electrodes, pads, surface-side pads) 3ap formed on the surface 3a and a plurality of back-surface electrodes (electrodes, pads, back-surface side pads) 2bp formed on the back surface 2b. In addition, the logic chip LC has a plurality of through electrodes 3tsv penetrating from one of the surface 3a and the back surface 3b to the other one and electrically coupling a plurality of the surface electrodes 3ap to a plurality of the back-surface electrodes 3bp.

Various circuits (semiconductor elements and wirings coupled thereto) which the semiconductor chips 3 have are formed on the side of the surface 3a of the semiconductor chips 3. More specifically, the semiconductor chips 3 each have a semiconductor substrate (not illustrated) made of, for example, silicon (Si) and has a plurality of semiconductor elements (not illustrated) such as transistor on the main surface (element formation surface) of the semiconductor substrate. The semiconductor substrate has, on the main surface (on the side of the surface 3a) thereof, a wiring layer (not illustrated) having a plurality of wirings and an insulating film for insulating between the wirings. The wirings of the wiring layer are electrically coupled to the semiconductor elements, respectively, to include a circuit. A plurality of the surface electrodes 3ap formed on the surface 3a (refer to FIG. 4) of the semiconductor chip 3 is electrically coupled to the semiconductor element via the wiring layer provided between the semiconductor substrate and the surface 3a to include a portion of the circuit.

Therefore, as shown in FIG. 6, by forming the through electrode 3tsv penetrating through the semiconductor chip 3 in the thickness direction thereof to electrically couple the surface electrode 3ap and the back-surface electrode 3bp via the through electrode 3tsv, the back-surface electrode 3bp and the circuit of the semiconductor chip 3 formed on the side of the surface 3a can be electrically coupled to each other. This means that as shown in FIG. 6, by electrically coupling the surface electrode 3a of the memory chip MC1 to the back-surface electrode 3bp of the logic chip LC via an external terminal (protruding electrode, conductive member, bump electrode) 7, the circuit of the memory chip MC1 and the circuit of the logic chip LC are electrically coupled to each other via the through electrode 3tsv.

In the present embodiment, the logic chip LC placed between the memory chip MC1 and the wiring board 2 has a plurality of through electrodes 3tsv. By electrically coupling the memory chip MC1 and the logic chip LC to each other via the through electrode 3tsv, the wiring board 2 or a wire (bonding wire) not shown can be eliminated from the transmission path between the logic chip LC and the memory chip MC1. This results in reduction in impedance component in the transmission path between the logic chip LC and the memory chip MC1 and reduction in the influence of a noise generated due to the clock number increase. In other words, even when the signal transmission rate between the logic chip LC and the memory chip MC1 is increased, improvement in transmission reliability can be accomplished.

In the example shown in FIG. 6, the memory chips MC1, MC2, MC3, and MC4 are stacked over the logic chip LC so that improvement in signal transmission rate between two adjacent ones of these memory chips MC1, MC2, MC3, and MC4 is also preferred. Among the memory chips MC1, MC2, MC3, and MC4, the memory chips MC1, MC2, and MC3 each having thereon and thereunder the semiconductor chip 3 have, similar to the logic chip LC, a plurality of through electrodes. More specifically, the memory chips MC1, MC2, and MC3 each have a plurality of surface electrodes (electrodes, pads) 3ap formed on the surface 3a and a plurality of back-surface electrodes (electrodes, pads) 3bp formed on the back surface 3b. In addition, the memory chips MC1, MC2, and MC3 each have a plurality of through electrode 3tsv penetrating through one of the surface 3a and the back surface 3b to the other one and electrically couple a plurality of the surface electrodes 3ap and a plurality of the back-surface electrodes 3bp to each other.

As in the above-mentioned logic chip LC, when the surface electrode 3ap of any one of the semiconductor chips 3, that is, the memory chips MC1, MC2, MC3, and MC4 and the back-surface electrode 3bp of the semiconductor chip 3 lying therebelow are electrically coupled to each other via a conductive member such as the external terminal 7, circuits of the stacked semiconductor chips 3 are electrically coupled to each other via the through electrode 3tsv.

Therefore by coupling the semiconductor chips 3 to each other via the external terminal 7 (a solder material 7a and a protruding electrode 7b in the example shown in FIG. 6), the wiring board 2 or a wire (bonding wire) not shown can be eliminated from the transmission path between two adjacent ones of the memory chips MC1, MC2, MC3, and MC4. This makes it possible to reduce the impedance component in the transmission path among the stacked memory chips MC1, MC2, MC3, and MC4 and reduce the influence of a noise generated by the clock number increase. In other words, even when the signal transmission rate among the memory chip MC1, MC2, MC3, and MC4 is improved, improvement in transmission reliability can be accomplished.

In the example shown in FIG. 6, it is only necessary to couple the memory chip MC4 placed on the top only to the memory chip MC3 so that it has neither a plurality of the back-surface electrodes 3bp nor a plurality of the through electrodes 3tsv, though having a plurality of the surface electrodes 3ap. Since the memory chip MC4 placed on the top employs a structure having neither a plurality of the back-surface electrodes 3bp nor a plurality of the through electrodes 3tsv, the memory chip MC4 can be manufactured by a simplified step. Although not shown here, as a modification example, the memory chip MC4 may have, similar to the memory chips MC1, MC2, and MC3, both a plurality of the back-surface electrodes 3bp and a plurality of the through electrodes 3tsv. In this case, these stacked memory chips MC1, MC2, MC3, and MC4 each have the same structure so that a manufacturing efficiency can be improved.

The external terminal 7 placed between the stacked semiconductor chips 3 and electrically coupling the surface electrode 3ap of one of the semiconductor chips 3 and the back-surface electrode 3bp of the semiconductor chip 3 lying therebelow is, in the example shown in FIG. 6, made of the following material. The external terminal 7 for electrically coupling the logic chip LC to the wiring board 2 is a metal member obtained by stacking a nickel (Ni) film and a solder (for example, SnAg) film (solder material 7a) on the tip of a member (protruding electrode 7b) having a columnar shape (for example, a cylindrical shape) and composed mainly of copper (Cu). At a position where the logic chip LC and the wiring board 2 are electrically coupled to each other, a solder film at the tip of the external terminal 7 is boned to the bonding lead 2f.

In the example shown in FIG. 6, the external terminal 7 provided at a junction where the semiconductor chips 3 are electrically coupled to each other is also a metal member obtained by stacking a nickel (Ni) film and a solder (for example, SnAg) film (solder material 7a) on the tip of a member (protruding electrode 7b) having a columnar shape and composed mainly of copper (Cu). The semiconductor chips 3 stacked are electrically coupled to each other by bonding the solder film at the tip of the external terminal 7 to the back-surface electrode 3bp.

However, various modification examples can be employed insofar as the material including the external terminal 7 falls within a range satisfying the requirement in electrical characteristics or requirement in bonding strength. For example, at a position where the memory chips MC1, MC2, MC3, and MC4 are electrically coupled to each other, it is also possible to bond the solder material 7a to the surface electrode 3ap and the back-surface electrode 3bp without forming the protruding electrode 7b shown in FIG. 6. In addition, there are various modification examples with respect to the shape of the protruding electrode 7b. For example, a stud bump may be used as the protruding electrode 7b. It is formed using the so-called ball bonding technology, that is, a technology of melting the tip of a wire to form a ball portion and bonding the ball portion to the surface electrode 3ap while applying pressure. In this case, the protruding electrode 7b can also be formed from a metal material composed mainly of, for example, gold (Au).

The semiconductor chip 3, such as the logic chip LC or the memory chips MC1, MC2, and MC3 shown in FIG. 6, having the through electrode 3tsv has a thickness, that is, a distance from the surface 3a to the back surface 3b, as thin (small) as possible. Decreasing the thickness of the semiconductor chip 3 is preferred because it decreases a transmission distance of the through electrode 3tsv and thereby reduces an impedance component. When an opening portion (including a through hole or a non-through hole) is formed in the thickness direction of the semiconductor substrate, the processing accuracy deteriorates as the hole becomes deeper. In other words, when the thickness of the semiconductor chip 3 is decreased, the processing accuracy of an opening portion for forming the through electrode 3tsv can be improved. This makes it possible to form a plurality of through electrodes 3tsv having a uniform diameter (length in a direction orthogonal to the thickness direction of the semiconductor chip 3, width) and easily control the impedance component of a plurality of transmission paths.

In the example shown in FIG. 6, the thickness of the logic chip is smaller than the thickness of the chip stack MCS (refer to FIG. 4) of the memory chips MC1, MC2, MC3, and MC4 placed over the logic chip LC. For example, the thickness of each of the logic chip LC and the memory chips MC1, MC2, MC3, and MC4 is about 50 μm. On the other hand, the thickness of the chip stack MCS (refer to FIG. 4) of the memory chips MC1, MC2, MC3, and MC4 is about 260 μm.

When the thickness of the semiconductor chip 3 is reduced as described above, the semiconductor chip 3, if exposed, may be damaged. In the present embodiment, as shown in FIG. 4, a plurality of the semiconductor chips 3 is sealed with a sealing body 4 firmly attached thereto. The sealing body 4 can therefore function as a protecting member of the semiconductor chips 3 and inhibit the semiconductor chips 3 from being damaged. According to the present embodiment, since a plurality of the semiconductor chips 3 is sealed with a resin, the semiconductor device 1 can have improved reliability (durability).

In the semiconductor device 1 obtained by stacking the semiconductor chips 3 having the through electrode 3tsv, the distance between the semiconductor chip 3 and the wiring board 2 is preferably narrowed from the standpoint of decreasing the transmission distance. For example, in the example shown in FIG. 6, the distance between the surface 3a of the logic chip LC and the upper surface 2a of the wiring board 2 is, for example, from about 10 μm to 20 μm. The distance between the surface 3a of the memory chip MC1 and the upper surface 2a of the wiring board 2 is, for example, from about 70 μm to 100 μm. Thus, in the semiconductor device 1 obtained by stacking the semiconductor chips 3 equipped with the through electrode 3tsv, the thickness and the distance of the semiconductor chips 3 are preferably decreased to narrow the transmission distance.

The present embodiment employs a constitution capable of, in a layout of the surface electrode 3ap and the back-surface electrode 3bp in plan view, decreasing the transmission distance between the memory chips memory chips MC1, MC2, MC3, and MC4 and the logic chip LC.

As shown in FIG. 7, a plurality of the surface electrodes 3ap of the memory chips MC1, MC2, MC3, and MC4 are arranged intensively at the central part of the surface 3a. As shown in FIG. 8, a plurality of the back-surface electrodes 3bp of the memory chips MC1, MC2, and MC3 are arranged intensively at the central part of the back surface 3b. As shown in FIG. 6, a plurality of the surface electrodes 3ap of the memory chips MC1, MC2, MC3, and MC4 and a plurality of the back-surface electrodes 3bp of the memory chips MC1, MC2, and MC3 are arranged at a position overlapping with each other in a thickness direction.

As shown in FIG. 9, some (a plurality of surface electrodes 3ap1) of the surface electrodes 3ap of the logic chip LC are arranged intensively at the central part of the surface 3a. Some (a plurality of surface electrodes 3ap2) of the surface electrodes 3ap of the logic chip LC are arranged at the peripheral edge portion of the surface 3a along the side (side surface 3c) of the surface 3a. A plurality of the surface electrodes 3ap1 arranged at the central part of the surface 3a, among a plurality of the surface electrodes 3ap shown in FIG. 9, is electrically coupled to the back-surface electrode 3bp via the through electrode 3tsv shown in FIG. 6. This means that a plurality of the surface electrodes 3ap1 is an electrode for internal interface. On the other hand, a plurality of the surface electrodes 3ap2 arranged at the peripheral edge portion of the surface 3a, among a plurality of the surface electrodes 3ap shown in FIG. 9, is electrically coupled to an external apparatus not shown via the wiring board 2 shown in FIG. 4. More specifically, the surface electrodes 3ap2 are electrically bonded to the bonding lead 2f (refer to FIG. 4). This means that a plurality of the surface electrodes 3ap2 is an electrode for external interface.

From the standpoint of shortening the transmission distance among the semiconductor chips 3, a method of placing the surface electrode 3ap1 for internal interface and the back-surface electrode 3bp so as to overlap with each other in a thickness direction and coupling them via the external terminal 7 as shown in FIG. 6 is particularly preferred.

The planar size of the logic chip LC is, as described above, smaller than that of the memory chips MC1, MC2, MC3, and MC4. In addition, as shown in FIG. 3, in plan view of the semiconductor device 1, the logic chip LC is placed so that the central portion (central region) of the back surface 3b thereof overlaps with the central portion (central region) of the memory chip MC4. This means that in plan view, the four side surfaces 3c of the memory chip MC4 are placed outside the four side surface 3c of the logic chip LC. In other words, a plurality of the semiconductor chips 3 is stacked over the wiring board 2 so that the four side surfaces 3c of the memory chip MC4 are positioned between the four side surfaces 3c of the logic chip LC and the four side surfaces 2c of the wiring board 2. The memory chips MC1, MC2, and MC3 shown in FIG. 4 are placed at a position overlapping (at the same position) with the memory chip MC4.

In plan view, the peripheral edge portions (the peripheral edge portions of the surface 3a and the back surface 3b) of the memory chips MC1, MC2, MC3, and MC4 are placed at a position overlapping with the peripheral region outside the logic chip LC. In other words, the peripheral edge portions of the memory chips MC1, MC2, MC3, and MC4 and the wiring board 2 have therebetween no logic chip LC (refer to, for example, FIG. 4).

In order to place the surface electrode 3ap for internal interface and the back-surface electrode 3bp, of each of the semiconductor chips 3 shown in FIG. 6, at respectively different positions in the thickness direction, at least the surface electrode 3ap for internal interface and the back-surface electrode 3bp are preferably placed at a position overlapping with the logic chip LC in the thickness direction. As shown in FIG. 9, a plurality of the surface electrodes 3ap2 for external interface is placed as shown in FIG. 9 at the peripheral edge portion of the logic chip LC. At the surface 3a of the logic chip LC, therefore, a plurality of the surface electrodes 3ap1 for internal interface is preferably placed intensively at the central part of the surface 3a.

As shown in FIG. 7, the memory chips MC1, MC2, MC3, and MC4 have, on the side of the surface 3a thereof (more specifically, on the main surface of the semiconductor substrate), a plurality of memory regions (memory circuit element arrangement region) MR. In the example shown in FIG. 7, each of them has four memory regions MR corresponding to the above-mentioned four channels. Each of the memory regions MR has a plurality of memory cells (memory circuit elements) in array form. As shown in FIG. 7, when a plurality of the surface electrodes 3ap is arranged intensively at the central part of the surface 3a, the memory regions MR for four channels can be placed so as to surround a region having therein a surface electrode group. This makes it possible to equalize the distance from each of the memory regions MR to the surface electrode 3ap. This means that intensive arrangement of the surface electrodes is preferred because the channels can be made equal in transmission distance and therefore a difference in transmission rate among the channels can be reduced.

When the surface electrodes 3ap1 intensively formed at the central part of the surface 3a of the logic chip LC shown in FIG. 9 are utilized as an electrode exclusively used for internal interface, the surface electrodes 3ap1 can be allowed to function even without electrically coupling them to the wiring board 2 shown in FIG. 6. It is however preferred to electrically couple some of the surface electrodes 3ap1 to the bonding lead 2f of the wiring board 2 as shown in FIG. 6 because the some of the surface electrodes 3ap1 can be used as an electrode for external interface.

For example, a power circuit DR for driving the main memory circuit MM shown in FIG. 5 is formed on the memory chips MC1, MC2, MC3, and MC4. As a terminal for supplying this power circuit DR with a power supply potential (first reference potential) or a reference potential (second reference potential different from the first reference potential, for example, ground potential), using some of the surface electrodes 3ap1 shown in FIG. 9 can be considered. In other words, in the example shown in FIG. 9, a plurality of the surface electrodes 3ap1 placed at the central part of the surface 3a of the logic chip LC includes a first reference potential electrode to be supplied with a first reference potential (for example, power supply potential) and a second reference potential electrode to be supplied with a second reference potential (for example, ground potential) different from the first reference potential. In other words, in the example shown in FIG. 9, a plurality of the surface electrodes 3ap1 arranged at the central part of the surface 3a of the logic chip LC includes power lines V2 and V3 (refer to FIG. 5) for supplying a voltage for driving the circuit formed on the memory chip MC1.

In order to improve a signal transmission rate, it is preferred to decrease the transmission distance between a power supply source and a power consuming circuit from the standpoint of inhibiting the operation from becoming unstable due to an instantaneous voltage drop or the like. Therefore, electrically coupling between some of the surface electrodes 3ap1 of the logic chip LC and the wiring board 2 and thereby supplying a first reference potential (for example, power supply potential) or a second reference potential (for example, ground potential) is preferred from the standpoint of shortening the distance from the memory chips MC1, MC2, MC3, and MC4 having a power consumption circuit to the drive circuit. In addition, with regard to the first reference potential electrode supplied with a first reference potential (for example, power supply potential) and a second reference potential electrode supplied with a second reference potential (for example, ground potential) different from the first reference potential, the surface electrode 3ap and the back-surface electrode 3bp are placed so as to overlap with each other in the thickness direction and at the same time, be electrically coupled to each other via the through electrode 3tsv as shown in FIG. 6.

### <Manufacturing Method of Semiconductor Device>

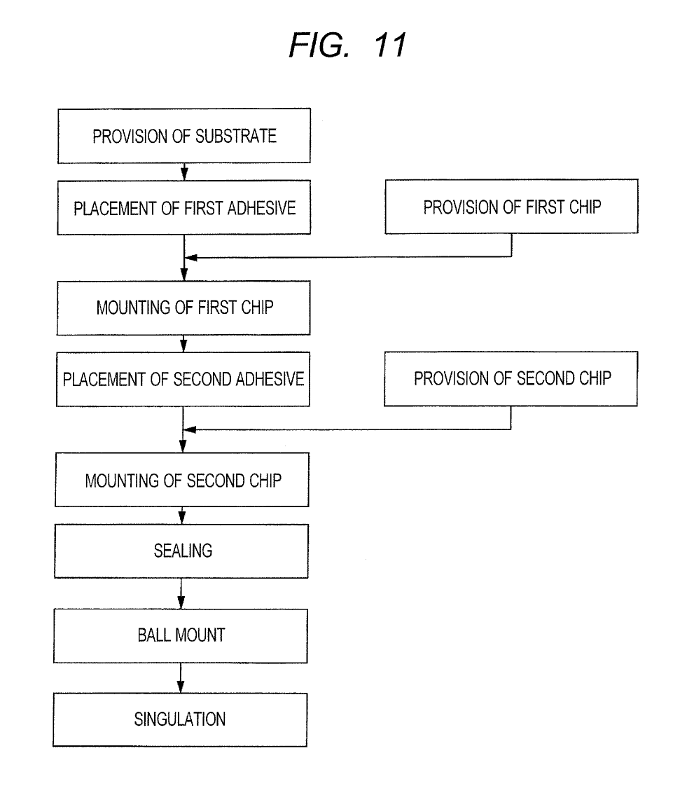

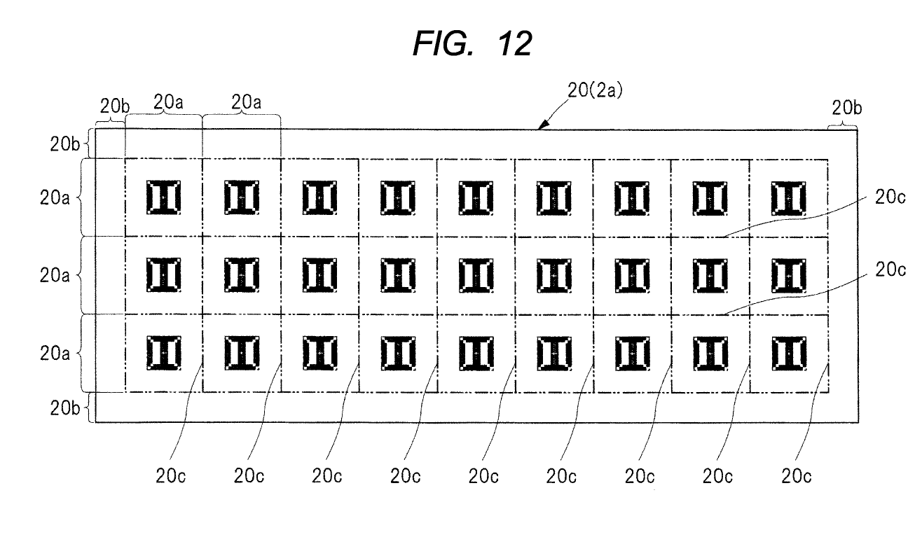

Next, manufacturing steps of the semiconductor device 1 described referring to FIGS. 1 to 10 will be described. The semiconductor device 1 is manufactured based on the flow shown in FIG. 11. FIG. 11 is an explanatory view showing the outline of manufacturing steps of the semiconductor device described referring to FIGS. 1 to 10. Details of each of the steps will next be described referring to FIGS. 12 to 40.

### <Board Providing Step>

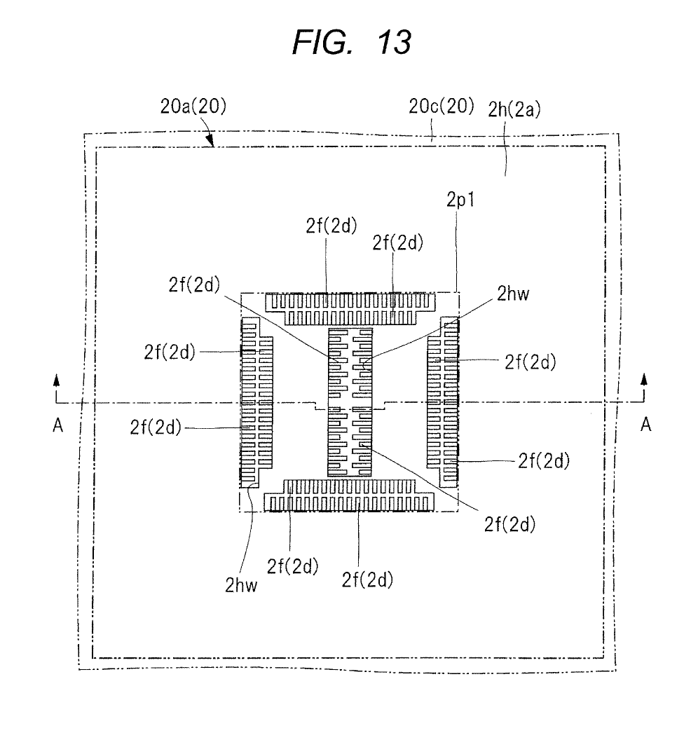

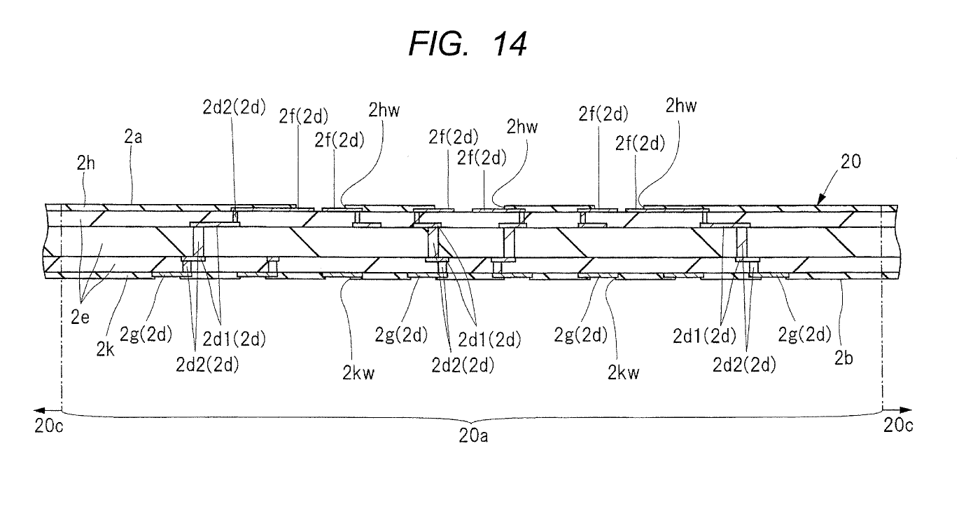

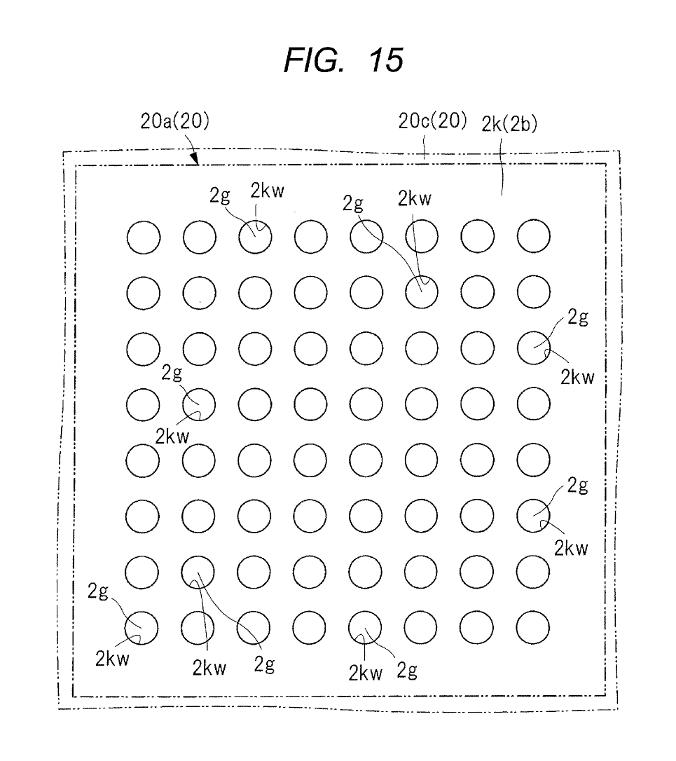

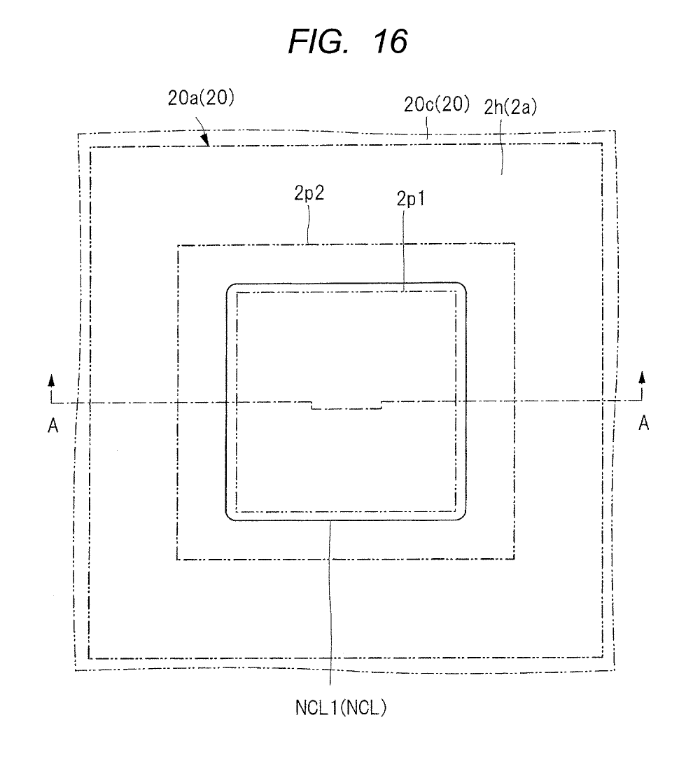

In the board providing step shown in FIG. 11, a wiring board 20 shown in FIGS. 12 to 17 is provided. FIG. 12 is a plan view showing an overall structure of the wiring board to be provided in the board providing step shown in FIG. 11. FIG. 13 is an enlarged plan view of one of the device regions shown in FIG. 12. FIG. 14 is an enlarged cross-sectional view taken along the line A-A of FIG. 13. FIG. 15 is an enlarged plan view showing the surface on the side opposite to that shown in FIG. 13. In FIGS. 12 to 15, the number of terminals is decreased to facilitate viewing, but the number of terminals (bonding leads 2f, lands 2g) is not limited to the aspect shown in FIGS. 12 to 15.

As shown in FIG. 12, the wiring board 20 provided in this step has a plurality of device regions 20a inside a frame portion (outer frame) 20b. More specifically, a plurality of (in FIG. 12, 27 pieces) of the device regions 20a is placed in rows and columns. These device regions 20a correspond to the wiring boards 2 shown in FIGS. 1 to 4, respectively. The wiring board 20 has a plurality of the device regions 20a and a dicing line (dicing region) 20c between two adjacent ones of the device regions 20a. It is a so-called multipiece board. Using such a multipiece board having a plurality of the device regions 20a can improve a manufacturing efficiency.

As shown in FIGS. 13 and 14, each of the device regions 20a has component members of the wiring board 2 described referring to FIG. 4. The wiring board 20 has an upper surface 2a, a lower surface 2b on the side opposite to the upper surface 2a, and a plurality of wiring layers (four layers in the example shown in FIG. 4) electrically coupling the upper surface 2a side and the lower surface 2b side to each other. Each of the wiring layers has a plurality of wirings 2d and an insulating layer (core layer) 2e for insulating between the wirings 2d and between the wiring layers adjacent to each other. The wirings 2d each includes a wiring 2d1 formed on the upper surface or lower surface of the insulating layer 2e and a via wiring 2d2 which is an interlayer conduction path penetrating through the insulating layer 2e in the thickness direction.

As FIG. 13 shows, the upper surface 2a of the wiring board 20 includes a chip mounting region (chip mounting portion) 2p1 which is a region on which the logic chip LC shown in FIG. 9 is to be mounted in the first chip mounting step shown in FIG. 11. The chip mounting region 2pa is present at the central part of the device region 20a on the upper surface 2a. In FIG. 13, in order to show the positions of the chip mounting region 2p1, the device region 20a, and the dicing line 20c, the profiles of the chip mounting region 2p1, the device region 20a, and the dicing line 20c are shown by a long dashed double-short dashed line. The chip mounting region 2p1 is, as described above, a region in which the logic chip LC is to be mounted so that presence of a visible boundary is not required. Also with regard to the device region 20a and the dicing line 20c, presence of a visible boundary is not required.

The wiring board 20 has, on the upper surface 2a thereof, a plurality of bonding leads (terminals, chip mounting side terminals, electrodes) 2f. The bonding leads 2f are terminals to be electrically coupled, in the first chip mounting step shown in FIG. 11, to a plurality of surface electrodes 3ap formed on the surface 3a of the logic chip LC shown in FIG. 9. In the present embodiment, the logic chip LC is mounted using the so-called face down mounting method, that is, a method of facing the surface 3a side of the logic chip LC to the upper surface 2a of the wiring board 20 so that a junction of a plurality of the bonding leads 2f is formed inside the chip mounting region 2p1.

The upper surface 2a of the wiring board 20 is covered with an insulating film (solder resist film 2h). The insulating film 2h has an opening portion 2hw and at this opening portion 2hw, at least a portion of each of the bonding leads 2f (junction with the semiconductor chip, bonding region) is exposed from the insulating film 2h. In the example shown in FIG. 13, each of bonding lead groups has an opening portion 2hw for exposing a plurality of the bonding leads 2f collectively.

The opening portion 2hw has a shape as shown in the aspect of FIG. 13 and in addition, there are various modification examples with respect to its shape. For example, an opening portion 2hw having a small opening area can be formed so as to selectively expose therefrom the respective coupling portions of a plurality of the bonding leads 2f. Alternatively, an opening portion 2hw exposing therefrom a plurality of bonding lead groups collectively can be formed by coupling a plurality of the opening portions 2hw with each other as shown in FIG. 13.

As shown in FIG. 15, the wiring board 20 has, on the lower surface 2b thereof, a plurality of lands 2g. The lower surface 2b of the wiring board 20 is covered with an insulating film (solder resist film) 2k. The insulating film 2k has an opening portion 2kw and at this opening portion 2kw, at least a portion of each of lands 2g (junction with a solder ball 5) is exposed from the insulating film 2k.

As shown in FIG. 14, a plurality of the bonding leads 2f and a plurality of the lands 2g are electrically coupled to each other via a plurality of the wirings 2d, respectively. Conductor patterns such as a plurality of the wirings 2d, a plurality of the bonding leads 2f, and a plurality of the lands 2g are made of, for example, a metal material composed mainly of copper (Cu). The portion of the bonding leads 2f placed in the opening portion 2hw and exposed from the insulating film 2h may have thereon an organic insulating layer (OSP: organic solderability preservative), a solder film, or a gold (Au) plating layer. The organic insulating layer (OSP), solder film, or gold (Au) plating layer formed in advance on the portion of the bonding lead 2f (portion to which the external terminal 7 shown in FIG. 9 is bonded) facilitates coupling between the external terminal 7 and the bonding lead 2f in the first chip mounting step shown in FIG. 11.

A plurality of the wirings 2d, a plurality of the bonding leads 2f, and a plurality of the lands 2g shown in FIG. 14 can be formed using, for example, electrolytic plating. The solder film or the gold (Au) plating layer formed on the portion of the bonding leads 2f can also be formed using, for example, electrolytic plating. As shown in FIG. 14, the wiring board 20 having four or more wiring layers (four layers in FIG. 14) can be formed, for example, by the so-called build-up method in which wiring layers are successively stacked on both sides of an insulating layer which will be a core material.

### <First Adhesive Material Placing Step>

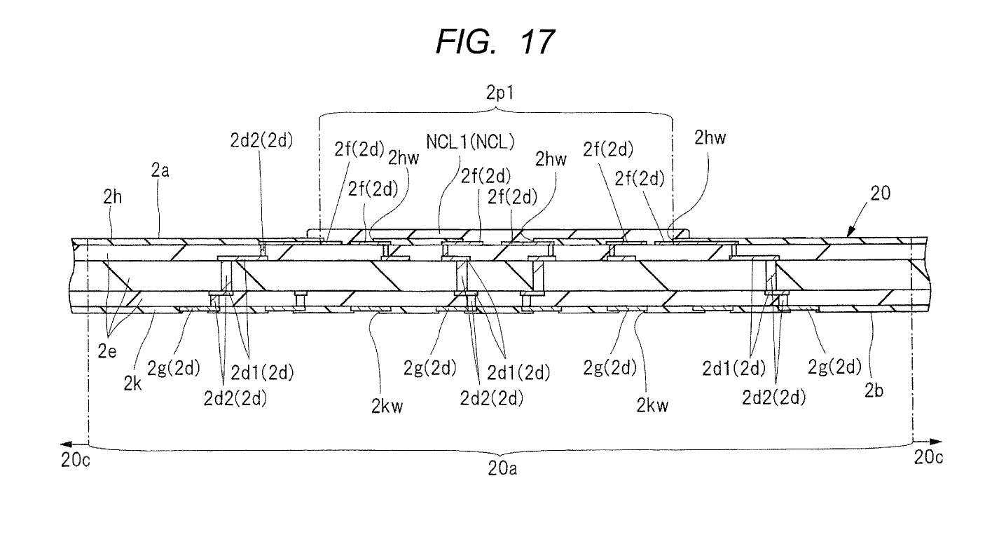

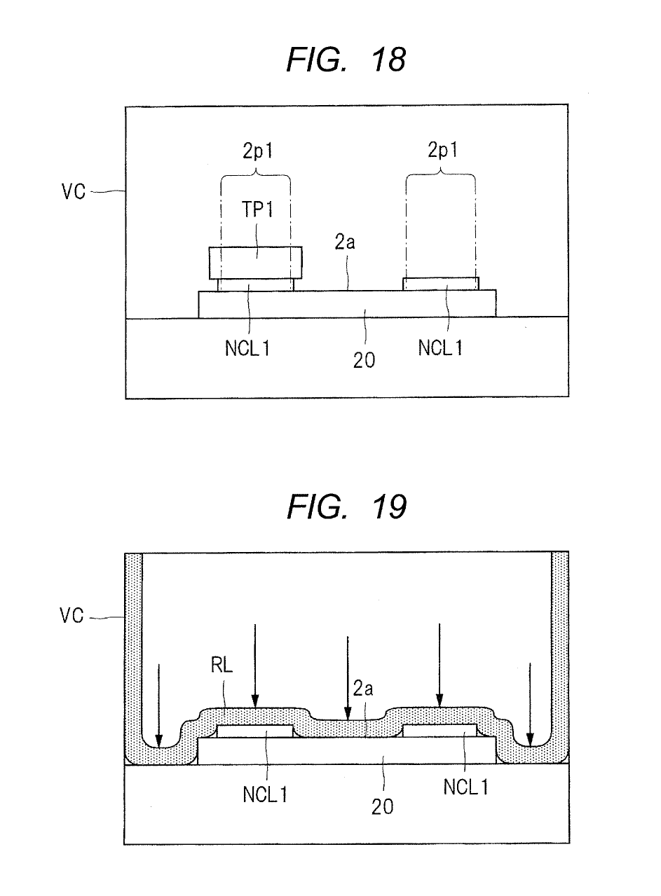

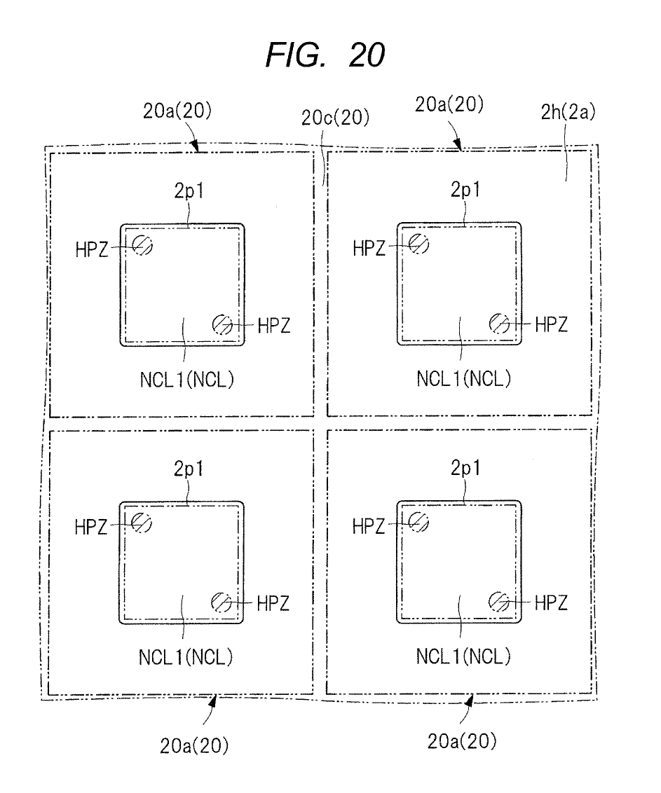

Next, in the first adhesive material placing step shown in FIG. 11, an adhesive material NCL1 is placed on the chip mounting region 2p1 of the upper surface 2a of the wiring board 20 as shown in FIGS. 16 and 17. FIG. 16 is an enlarged plan view showing the adhesive material placed in the chip mounting region shown in FIG. 13; FIG. 17 is an enlarged cross-sectional view taken along the line A-A of FIG. 16. FIG. 18 is a side view schematically showing the adhesive material placed on the wiring board shown in FIG. 17. FIG. 19 is a side view schematically showing the adhesive material shown in FIG. 18 pressed against the wiring board by means of a roller. FIG. 20 is an enlarged plan view showing a portion of the adhesive material pressed against the wiring board prior to the step shown in FIG. 19.

In FIG. 16, in order to show the position of each of the chip mounting regions 2p1 and 2p2, the device region 20a, and the dicing line 20c, the profile of each of the chip mounting regions 2p1 and 2p2, the device region 20a, and the dicing line 20c is shown with a long dashed double-short dashed line. In FIG. 20, the profile of each of a portion HPZ, the chip mounting region 2p1, the device region 20a, and the dicing line 20c is shown with a long dashed double-short dashed line. However, the chip mounting regions 2p1 and 2p2 are regions where the logic chip LC and the chip stack MCS are to be mounted so that presence of a visible boundary is not necessary. Also, with respect to the device region 20a and the dicing line 20c, presence of a visible boundary is not necessary. When the chip mounting regions 2p1 and 2p2, the device region 20a, and the dicing line 20c will hereinafter be shown in plan view, presence of a visible boundary is also not necessary. FIG. 20 is a plan view, but the portion HPZ is hatched in order to clearly show the position of the portion HPZ.

For mounting a semiconductor chip on a wiring board through a facedown mounting method (flip chip coupling method), it is the common practice to employ a method (post injection method) in which after electrically coupling between the semiconductor chip and the wiring board, the coupled portion is sealed with a resin. In this case, by making use of a capillary phenomenon, the space between the semiconductor chip and the wiring board is filled with a resin supplied from a nozzle placed in the vicinity of the space.

In the example described in the present embodiment, the logic chip LC is mounted using a method (pre-application method) in which prior to mounting the logic chip LC (refer to FIG. 9) in the first chip mounting step which will be described later, the adhesive material NCL1 is placed in the chip mounting region 2p1 and the logic chip LC is pressed against the wiring board 20 from above the adhesive material NCL1 to electrically couple them to each other.

In the above-mentioned post injection method, the space is filled with the resin by making use of a capillary phenomenon so that treatment time (resin injection time) for one of the device regions 20a becomes long. In the above-mentioned pre-application method, on the other hand, by the time the tip (for example, the solder material 7a formed at the tip of the protruding electrode 7b shown in FIG. 6) of the logic chip LC is brought into contact with the bonding lead 2f at their junction, a space between the wiring board 20 and the logic chip LC has already been filled with the adhesive material NCL1. Compared with the above-mentioned post injection method, therefore, the latter method is preferred because the treatment time for one of the device regions 20a can be decreased and a manufacturing efficiency can be improved.

The adhesive material NCL1 used in the pre-application method is made of, as described above, an insulating (non-conductive) material (for example, resin material). In addition, the adhesive material NCL1 is made of a resin material having a higher (increased) hardness when energy is applied thereto and in the present embodiment, it contains, for example, a thermosetting resin. The adhesive material NCL1 before curing is softer than the external terminal 7 shown in FIG. 6 and it is deformed by the logic chip LC pressed against it.

The adhesive material NCL1 before curing is classified roughly into two kinds according to a handling method. One is made of a paste-like resin (insulating material paste) called NCP (non-conductive paste) and from a nozzle not shown, it is applied to the chip mounting region 2p1. The other one is called NCF (non-conductive film) and made of a resin (insulating material film) formed in advance into a film form. It is conveyed to the chip mounting region 2pa as in film form and attached thereto. When the insulating material paste (NCP) is used, an attaching step necessary for the insulating material film (NCF) is not necessary so that it adds a smaller stress to the semiconductor chip or the like than the method using the insulating material film. In the method using the insulating film material (NCF), a placement area or thickness of the adhesive material NCL1 can be easily controlled due to higher shape retention than the insulating material paste (NCP).

In the example shown in FIGS. 16 and 17, the adhesive material NCL1 which is an insulating material film (NCF) is placed on the chip mounting region 2p1 and is attached firmly to the upper surface 2a of the wiring board 20. Although not shown here, an insulating material paste (NCP) can be used as a modification example.

In the present embodiment, as schematically shown in FIG. 18, the adhesive material NCL1 divided into pieces is conveyed while adsorbing and retaining it to a film conveying jig TP1 and then placed on the chip mounting region 2p1. Then, one of the surfaces of the adhesive material NCL1 is firmly attached and adhered to the upper surface 2a of the wiring board 20. At this time, the chip mounting region 2p1 of the wiring board 20 has therein many bonding leads 2f, for example, as shown in FIG. 13. It is therefore preferred to firmly attach the adhesive material NCL1 and the wiring board 20 without leaving air bubbles (also called air traps) therebetween.

In the present embodiment, therefore, at least a step of firmly attaching the adhesive material NCL1 to the wiring board 20 in the first adhesive material placing step is performed in a decompression chamber (decompression room, vacuum chamber) VC having a pressure lower than the pressure outside the chamber. For example, in the present step, after the adhesive material NCL1 is placed on the wiring board 20 in the decompression chamber VC, the adhesive material NCL1 is pressed against the wiring board 20 under reduced pressure condition to firmly attach it thereto. A method of pressing the adhesive material NCL1 against the wiring board has various modification examples. In the example shown in FIG. 19, an elastic material RL which is a pressing jig is used to press the adhesive material NCL1 against the wiring board 20. FIG. 19 shows a diaphragm type aspect in which a film-like elastic material RL is used as an example of the pressing jig and is pressed against the entirety of the board 20 by making use of an atmospheric pressure such as compressed air. The pressing method however has various modification examples. For example, a method of pressing the adhesive material NCL against the wire board by a roller not shown may be used.

As shown in FIG. 17, the chip mounting region 2p1 of the wiring board 20 has therein a plurality of the wirings 2d including bonding leads 2f. In addition, the chip mounting region 2p1 has therein an opening portion of the insulating film 2hw. Therefore, the upper surface 2a of the wiring board 20 has an irregular shape following the patterns of the wiring 2d and the insulating film 2hw. When the upper surface 2a having such an irregular shape and the adhesive material NCL1 are firmly attached to each other, air is trapped in the irregular portion between the adhesive material NCL1 and the wiring board 20 and sometimes remains as air bubbles even if they are firmly attached under reduced pressure condition as shown in FIG. 19.

To inhibit air bubbles from remaining, it is preferred to reduce the pressure in the decompression chamber VC prior to pressing the elastic material RL shown in FIG. 19 and discharge air under this pressure reduced condition. For example, in the present embodiment, the divided pieces of the adhesive materials NCL1 are each pressed at a plurality of positions thereof as shown in FIG. 20 prior to pressing with the elastic material RL shown in FIG. 19. For example, in the example shown in FIG. 20, in plan view, the pieces of the adhesive material NCL1 are each pressed at two positions thereof (hatched portions HPZ) with a pressing jig not shown. As a result, adhesion between the wiring board 20 and the adhesive material NCL1 becomes larger at preliminarily pressed portions (portions HPZ in FIG. 20) than at a preliminarily unpressed portion.

As shown in the example of FIG. 20, when a portion (portion HPZ) of the adhesive material NCL1 is pressed against the wiring board 20 in advance, misalignment of the adhesive material NCL1 can be prevented until the step of pressing with the elastic material RL as shown in FIG. 19. Adhesion between the wiring board 20 and the adhesive material NCL1 is smaller at a portion other than the portion HPZ than at the portion HPZ. Reduction in pressure in the decompression chamber VC before pressing with the elastic material RL as shown in FIG. 19 makes it possible to discharge air from between the adhesive material NCL1 and the wiring board 20 through a discharge path formed in this region with small adhesion. In addition, pressing the adhesive material NCL1 with the elastic material RL after air is discharged makes it possible to inhibit air bubbles from remaining after the adhesive material NCL1 and the wiring board 20 are firmly attached to each other.

### <First Chip Providing Step>

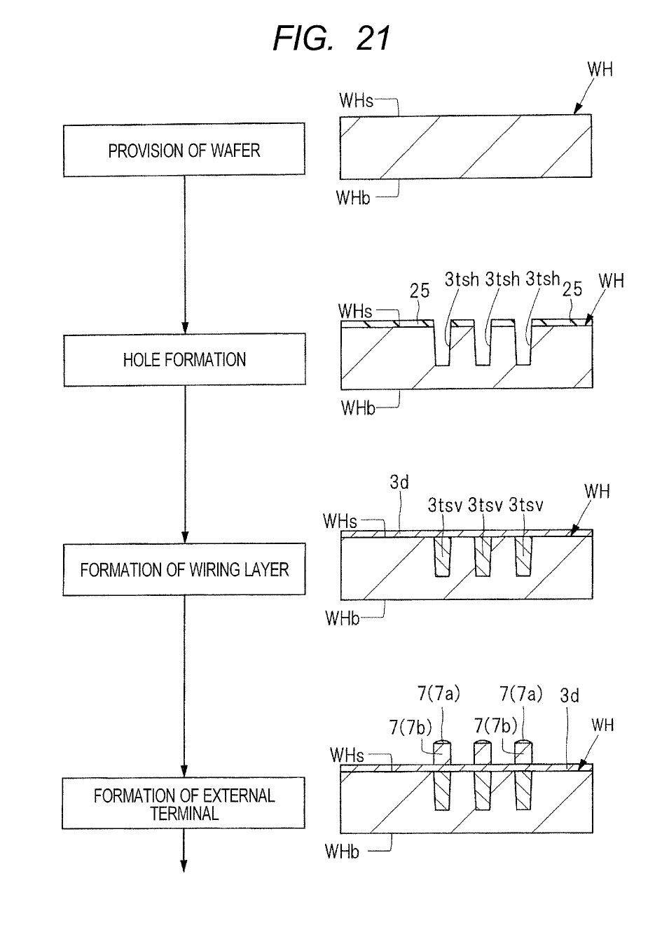

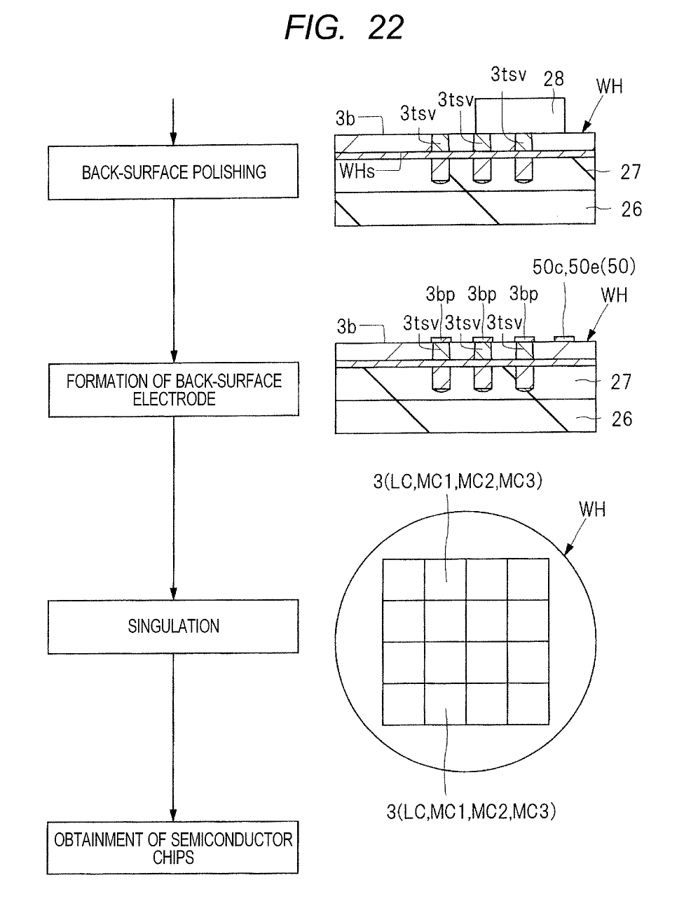

In the first chip providing step shown in FIG. 11, the logic chip LC shown in FIGS. 9 and 10 is provided. FIG. 21 is an explanatory view schematically showing the outline of manufacturing steps of the semiconductor chip having through electrodes shown in FIG. 6. FIG. 22 is an explanatory view schematically showing the outline of manufacturing steps following those of FIG. 21. In FIGS. 21 and 22, a manufacturing method of a through electrode 3tsv and a back-surface electrode 3bp electrically coupled to the through electrode 3tsv will be described mainly and illustration and description on a step of forming various circuits other than the through electrode 3tsv will be omitted. The manufacturing method of a semiconductor chip shown in FIGS. 21 and 22 can also be applied to a manufacturing method of the memory chips MC1, MC2, and MC3 as well as the logic chip LC shown in FIG. 4.

First, in the wafer providing step, a wafer (semiconductor substrate) WH shown in FIG. 21 is provided. The wafer WH is a semiconductor substrate made of, for example, silicon (Si) and it is round in plan view. The wafer WH has a surface (main surface, upper surface) WHs which is a semiconductor element formation surface and a back surface (main surface, lower surface) WHb on the side opposite to the surface WHs. The thickness of the wafer WH is greater than that of the logic chip LC and the memory chips MC1, MC2, and MC3 shown in FIG. 4 and is, for example, about several hundred μm.

Next, in the hole formation step, a hole (pore, opening) 3tsh for forming the through electrode 3tsv shown in FIG. 6 is formed. In the example shown in FIG. 21, the hole 3tsh is formed by placing a mask 25 on the surface WHS of the wafer WH, followed by etching. Semiconductor elements such as the logic chip LC and memory chips MC1, MC2, and MC3 shown in FIG. 4 can be formed, for example, after the present step and before a wiring layer formation step subsequent thereto.

Next, the hole 3tsh is filled with a metal material such as copper (Cu) to form a through electrode 3tsv. Next, as a wiring layer formation step, a wiring layer (chip wiring layer) 3d is formed on the surface WHs of the wafer WH. In this step, a plurality of surface electrodes 3ap shown in FIG. 7 or FIG. 9 is formed and a plurality of the through electrodes 3tsv and the plurality of surface electrodes 3ap are electrically coupled to each other. The surface electrode 3ap and an uppermost wiring layer 3d formed integrally with the surface electrode 3ap are formed, for example, from a metal film made of aluminum (Al).

In the present step, the semiconductor chips such as logic chip L and memory chips MC1, MC2, and MC3 shown in FIG. 4 are electrically coupled to a plurality of the surface electrodes 3ap shown in FIG. 7 or FIG. 9 via the wiring layer 3d. As a result, the semiconductor elements such as logic chip L and memory chips MC1, MC2, and MC3 are electrically coupled to each other via the wiring layer 3d.

Next, as an external terminal formation step, an external terminal 7 is formed on the surface electrode 3ap (refer to FIGS. 7 and 9). In the present step, as shown in FIG. 6, a protruding electrode 7b is formed on the surface electrode 3ap of the logic chip LC. A solder material 7a is formed at the tip of the protruding electrode 7b. Or, a solder material 7a is formed on the surface electrode 3ap of the memory chip MC1. This solder material 7a functions as a bonding material when the semiconductor chip 3 shown in FIG. 6 is mounted on the wiring board 2 or the semiconductor chip 3 lying therebelow.

Next, as the back surface polishing step shown in FIG. 22, the back surface WHb (refer to FIG. 21) of the wafer WH is polished to decrease the thickness of the wafer WH. By this polishing, the back surface 3b of the semiconductor chip 3 shown in FIG. 5 is exposed. In other words, the through electrode 3tsv penetrates through the wafer WH in the thickness direction thereof. A plurality of the through electrodes 3tsv is exposed from the wafer WH at the back surface 3b of the wafer WH. In the example shown in FIG. 22, in the back surface polishing step, the wafer WH is polished using a polishing jig 28 while supporting it with a supporting material 26 such as glass plate and a protecting layer 27 which protects the surface WHs side and thereby protects the external terminal 7.

Next, in the back-surface electrode formation step, a plurality of back-surface electrodes 3bp is formed on the back surface 3b and is electrically coupled to a plurality of the through electrodes 3tsv.

Next, in a singulation step, the wafer WH is divided along a dicing line to obtain a plurality of semiconductor chips 3. Then, a test is made according to need and the semiconductor chips 3 (logic chip LC and memory chips MC1, MC2, and MC3) as shown in FIG. 4 can be obtained.

When a semiconductor chip 3, like the memory chip MC4 shown in FIG. 6, having neither the through electrode 3tsv nor the back-surface electrode 3b is formed, the hole formation step shown in FIG. 21 and the back-surface electrode formation step shown in FIG. 22 can be omitted.

### <First Chip Mounting Step>

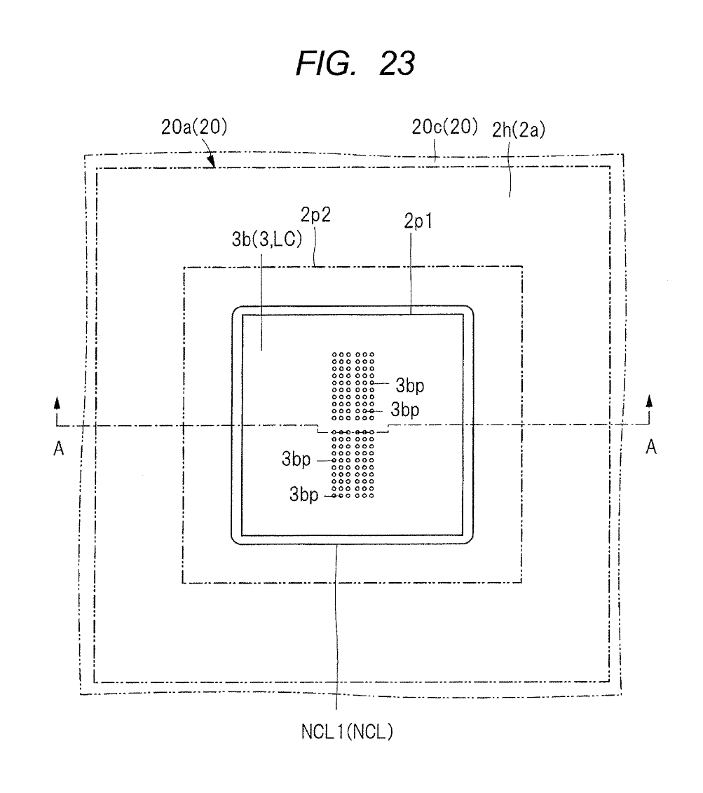

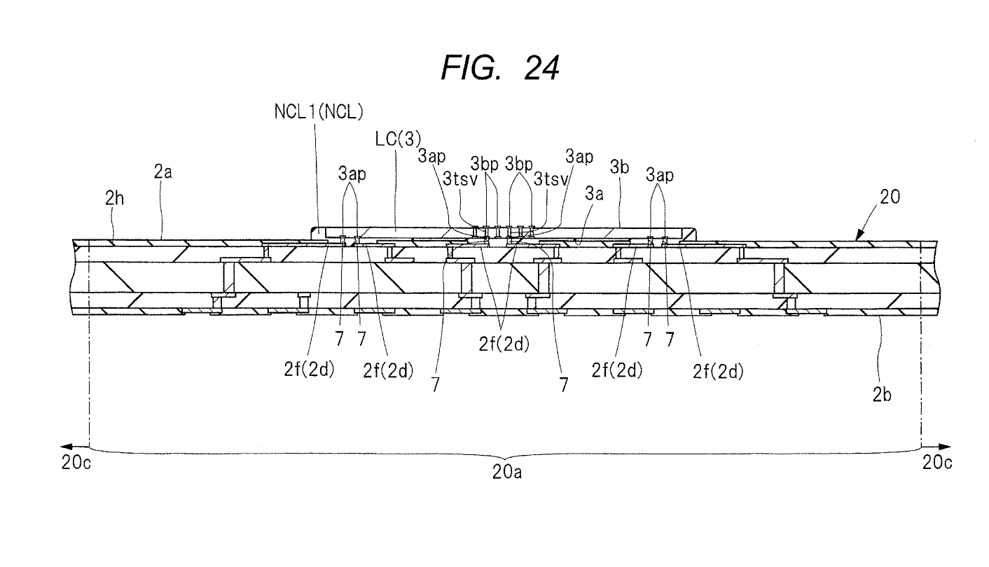

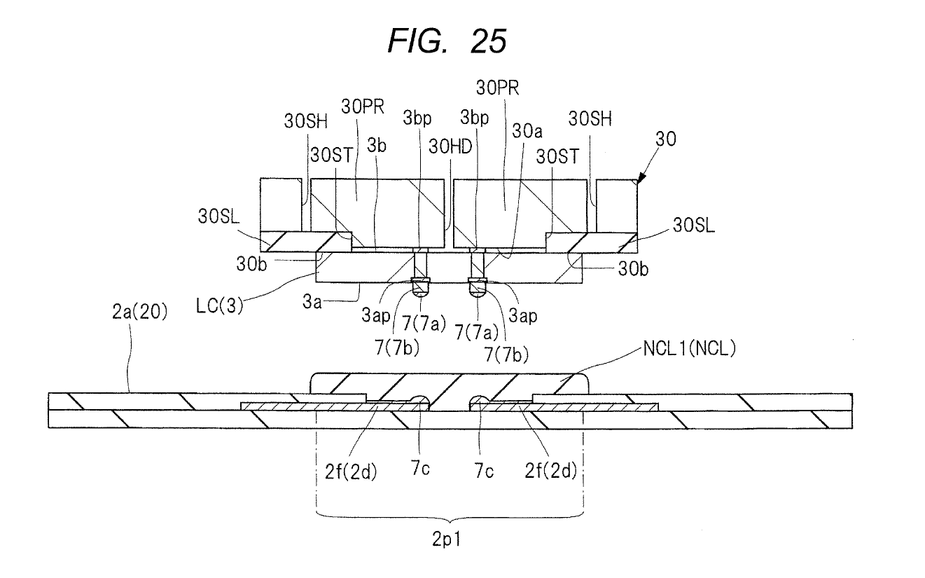

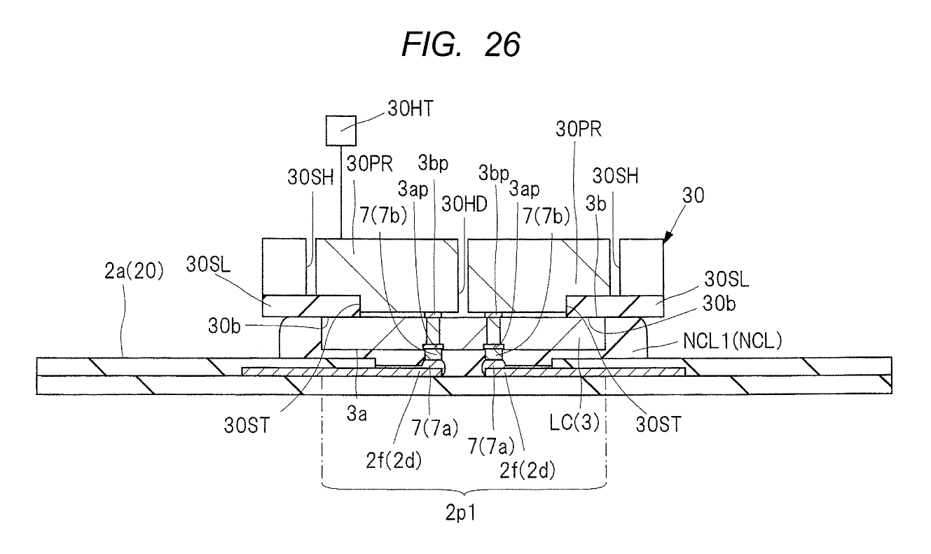

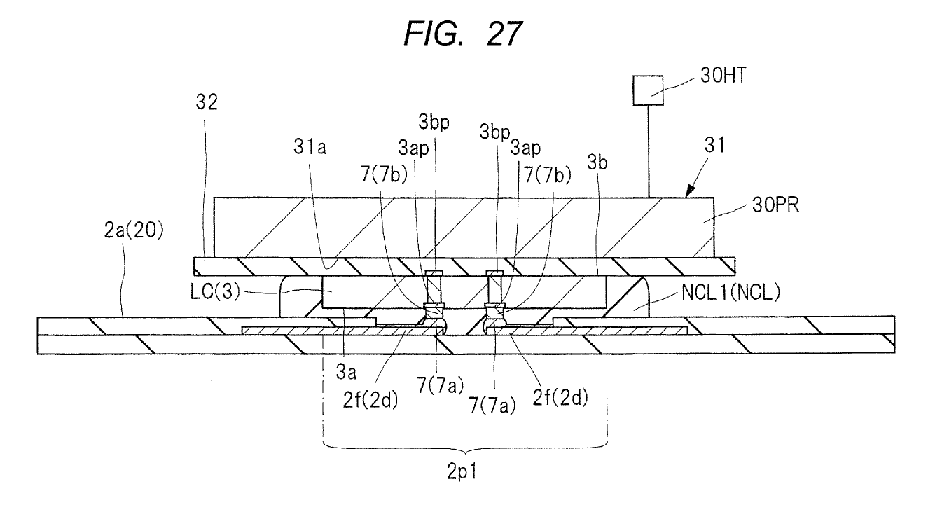

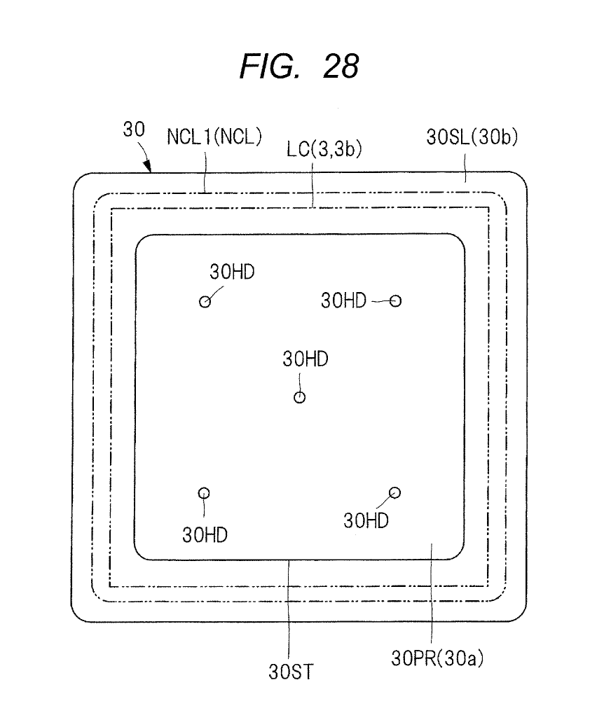

Next, in the first chip mounting step shown in FIG. 11, the logic chip LC is mounted on the wiring board 20 as shown in FIG. 23 or 24. FIG. 23 is an enlarged plan view showing the logic chip LC mounted on the chip mounting region of the wiring board shown in FIG. 16. FIG. 24 is an enlarged cross-sectional view taken along the line A-A of FIG. 23. FIG. 25 is an explanatory view schematically showing the logic chip placed over the adhesive material placed on the wiring board in the first chip mounting step shown in FIG. 11. FIG. 26 is an explanatory view schematically showing the logic chip and the wiring board electrically coupled to each other in the first chip mounting step shown in FIG. 11. FIG. 27 is an explanatory view schematically showing an aspect in which the logic chip is pressed while having a resin film between a bonding tool and the logic chip, which is an investigation example different from the example shown in FIG. 26. FIG. 28 is a plan view of a surface of the bonding tool shown in FIGS. 25 and 26 placed so as to face to the semiconductor chip. In FIG. 28, in order to show the planar positional relationship among the logic chip, the adhesive material, and the component member of the bonding jig shown in FIG. 26, the profile of the back surface 3b of the logic chip LC and the profile of the adhesive material NCL1 are shown with a long dashed double-short dashed line.

In the present step, as shown in FIG. 24, the logic chip LC is mounted by the so-called facedown mounting method (flip chip coupling method) so that the surface 3a of the logic chip LC faces to the upper surface 2a of the wiring board 20. By the present step, the logic chip LC and the wiring board 20 are electrically coupled to each other. Described specifically, a plurality of the surface electrodes 3ap formed on the surface 3a of the logic chip LC is electrically coupled to a plurality of the bonding leads 2f formed on the upper surface 2a of the wiring board 20 via the external terminal 7 (the protruding electrode 7b and the solder material 7a shown in FIG. 6). A detailed flow of the present step will next be described referring to FIGS. 25 to 28.

The first chip mounting step shown in FIG. 11 includes, as shown in FIG. 25, a first chip conveying step for conveying the logic chip LC (semiconductor chip 3) onto the adhesive material NCL1 in the chip mounting region 2p1 of the wiring board 20.

The logic chip LC is conveyed to over the adhesive material NCL1 in the chip mounting region 2p1 while being retained at the back surface 3b thereof with a bonding jig 30 and is placed over the adhesive material NCL1 so that the surface 3a positioned on the element formation surface side faces to the upper surface 2a of the wiring board 20.

The logic chip LC has, on the surface 3a side thereof, a protruding electrode 7b and the protruding electrode 7b has, at the tip thereof, a solder material 7a. On the other hand, at a junction of the bonding lead 2f formed on the upper surface 2a of the wiring board 20, a solder material 7c, which is a bonding material for electrically coupling it to the protruding electrode 7b, is formed in advance. In the present step, the planar positions of the logic chip LC and the wiring board 20 are aligned so that a plurality of the protruding electrodes 7b and a plurality of bonding leads 2f face to each other.

The bonding jig 30 has a retention portion 30HD for retaining the back surface 3b of the logic chip LC. In the example shown in FIG. 26, the retention portion 30HD is an air inlet hole penetrating therethrough and reaching a surface 30a which is a surface facing to the logic chip LC. The bonding jig 30 adsorbs and retains the logic chip LC by sucking air on the side of the logic chip LC via the retention portion 30HD which is an air inlet hole. As shown in FIG. 26, when the logic chip LC has, on the back surface 3b thereof, a metal pattern such as the back-surface electrode 3bp, a space appears between the surface 30a of the bonding jig 30 and the back surface 3b of the logic chip LC. This space has a thickness almost equal to that of the back-surface electrode 3bp so that even when there appears a space, the bonding jig 30 can adsorb and retain the logic chip LC.

The first chip mounting step includes a bonding step in which a plurality of the bonding leads 2f and a plurality of the surface electrodes 3ap are electrically coupled to each other by heating the back surface 3b of the logic chip LC via the bonding jig 30 and at the same time, pressing the bonding jig 30 against the logic chip LC from the back surface 3b thereof.

In the bonding step, a pressing portion 30PR of the bonding jig 30 is brought into contact with the back surface 3b of the logic chip LC and the logic chip LC is pressed against the wiring board 20. In the example shown in FIG. 26, a portion of the pressing portion 30PR is brought into contact with the back-surface electrode 3bp of the logic chip LC. In addition, a sealing portion 30SL provided at the peripheral edge portion of the pressing portion 30PR is firmly attached to the peripheral edge portion of the back surface 3b of the logic chip LC. Since the adhesive material NCL1 is not cured and is therefore still soft, when the logic chip LC is pushed by means of the bonding jig 30, the logic chip LC approaches the wiring board 20. When the logic chip LC approaches the wiring board 20, the tip (more specifically, the solder material 7a shown in FIG. 25) of a plurality of the external terminals 7 formed on the surface 3a of the logic chip LC are brought into contact with the bonding region (more specifically, the solder material 7c shown in FIG. 25) of the bonding lead 2f.

The thickness of the adhesive material NCL1 is greater than at least the sum of the height (protruding height) of the external terminal 7 and the thickness of the bonding lead 2f. A portion of the logic chip LC on the surface 3a side is embedded in the adhesive material NCL1 when pushed by means of the bonding jig 30. In other words, at least a portion of the side surface of the logic chip LC on the surface 3a side is embedded in the adhesive material NCL1.

In the bonding step, the logic chip LC and the adhesive material NCL1 are heated via the bonding jig 30 with the logic chip LC being pressed against the bonding jig 30. In the example shown in FIG. 26, the bonding jig 30 is coupled to a heat source 30HT such as heater and the entirety of the pressing portion 30PR of the bonding jig 30 is heated with the heat transferred from the heat source 30HT. The pressing portion 30PR is made of, for example, a metal material or a ceramic material. FIG. 26 schematically shows an example in which the heat source 30HT is provided outside the bonding jig 30 and they are physically coupled to each other, but the position of the heat source 30HT is not particularly limited. For example, a heater or the like can be buried in the bonding jig 30. Alternatively, the bonding jig 30 can be heated by firmly attaching a heating jig, not shown, having a heater therein to the bonding jig 30.

When the bonding jig 30 is heated, the solder material 7c (refer to FIG. 25) on the side of the bonding lead 2f and the solder material 7a on the side of the protruding electrode 7b are melted into one body at the junction between the logic chip LC and the wiring board 20 and as a result, it becomes a bonding material (solder material 7a) for electrically coupling the external terminal 7 and the bonding lead 2f to each other. This means that by heating the logic chip LC via the bonding jig 30, the protruding electrode 7b and the bonding lead 2f are electrically coupled to each other via the solder material 7a.

The adhesive material NCL1 is heated with the heat transferred from the bonding jig 30 and then the adhesive material NCL1 is cured. Curing of the adhesive material NCL1 occurs while sealing between the logic chip LC and the wiring board 20. Complete curing of the adhesive material NCL1 with the heat from the bonding jig 30 is not necessary. It is possible to employ an aspect in which after a portion of the thermosetting resin contained in the adhesive material NCL1 is cured (temporarily cured) enough to fix the logic chip LC therewith, the wiring board 20 is transferred to a heating furnace not shown and the remaining thermosetting resin is cured (fully cured). It takes time to complete the full curing treatment for curing the entirety of the thermosetting resin components contained in the adhesive material NCL1, but the full curing treatment performed in the heating furnace improves the manufacturing efficiency.

In the first chip mounting step, the logic chip LC is pushed into the adhesive material NCL1 in soft form so that the adhesive material NCL1 is deformed by the logic chip LC pushed therein. This means that a portion of the adhesive material NCL1 is pushed to the periphery of the chip mounting region 2p1 and has a fillet shape at the periphery of the logic chip LC. The adhesive material NCL1 pushed to the periphery of the logic chip LC poses no problem if not higher than the back surface 3b of the logic chip LC, but there is a possibility of it becoming higher than the logic chip LC, depending on the amount pushed to the periphery of the logic chip LC.

When the adhesive material NCL1 pushed to the periphery of the logic chip LC becomes higher than the back surface 3b of the logic chip LC, a fillet-like rising portion of the adhesive material NCL1 may hinder the mounting work of the chip stack MCS shown in FIG. 4 in the second chip mounting step shown in FIG. 11. When the adhesive material NCL1 attached to the bonding jig 30 is cured as is, the bonding jig cannot adsorb the semiconductor chip 3 easily upon adsorbing and retaining it. When the adhesive material NCL1 is pushed to the periphery of the logic chip LC and spreads even to the side of the back surface 3b of the logic chip LC, there is a possibility of the back-surface electrode 3bp of the logic chip LC being covered with the adhesive material NCL.

The present inventors therefore investigated a method of inserting, between a bonding jig 31 and the logic chip LC, a member (low elastic member) softer than the logic chip LC, for example, a resin film (film) 32 and covering the back surface 3b of the logic chip LC with the resin film 32. When the logic chip LC is pressed via the resin film 32, the resin film 32 is attached firmly to the back surface 3b of the logic chip LC. Even if the adhesive material NCL1 is pushed to the periphery of the logic chip LC, the adhesive material NCL1 can be prevented from spreading even to the back surface 3b of the logic chip LC.

In addition, by inserting the resin film 32 having an area wider than that of the back surface 3b of the logic chip LC and pressing the back surface 3b with a pressing surface 31a having an area greater than that of the back surface, the height of the adhesive material NCL1 pushed to the periphery of the logic chip LC can be prevented from exceeding the height of the back surface 3b of the logic chip LC.

Further, by inserting the resin film 32 between the bonding jig 31 and the logic chip LC, attachment of the adhesive material NCL1 to the bonding jig 31 can be prevented or suppressed.

When the entirety of the back surface 3b of the logic chip LC is covered with the resin film 32 as shown in FIG. 27, however, the adsorption and retention of both the resin film 32 and the logic chip LC is difficult. It is therefore necessary to successively carry out a step of conveying the logic chip LC onto the adhesive material NCL1 and leaving it on the adhesive material NCL1 (chip temporary mounting step) and a step of placing the resin film 32 on the back surface 3b of the logic chip LC. From the standpoint of improving the manufacturing efficiency, a method of pressing the logic chip LC against the adhesive material NCL1 without leaving it on the adhesive material NCL1 is preferred. Leaving the logic chip LC on the soft adhesive material NCL1 may incline the logic chip LC. From the standpoint of suppressing the misalignment of the logic chip LC, the method of pressing of the logic chip LC against the adhesive material NCL1 without leaving it on the adhesive material NCL1 is preferred. A mounting system in which the logic chip LC is pressed against the adhesive material NCL1 without leaving it on the adhesive material NCL1 will hereinafter be called “single path mounting system”. A mounting system in which the logic chip LC is left on the adhesive material NCL1 and then pressed against the adhesive material NCL1 via the resin film 32 will hereinafter be called “double path mounting system”.

With the foregoing problem in view, the present inventors investigated further on the single path mounting system. As a result, they have found the mounting system of the present embodiment shown in FIGS. 25 and 26. As shown in FIGS. 25, 26, and 28, the bonding jig 30 of the present embodiment has the retention portion 30HD for adsorbing and retaining the logic chip LC. The bonding jig 30 further has the pressing portion 30PR for pressing against the back surface 3b of the logic chip LC. The bonding jig 30 still further has the sealing portion 30SL to be firmly attached to the peripheral edge portion of the back surface 3b of the logic chip LC as shown in FIG. 26 in the above-mentioned bonding step.

At least a surface (a surface to be firmly attached) 30b of the sealing portion 30SL to be firmly attached to the back surface 3b of the logic chip LC is made of a resin (low elastic member) softer than the logic chip LC. In the example shown in FIGS. 25, 26, and 28, the entirety of the sealing portion 30SL is made of a resin member and is adsorbed and retained by the pressing portion 30PR while being sucked to an adsorption hole 30SH. This means that the sealing portion 30SL is formed detachable from the pressing portion 30PR. The sealing portion 30SL is retained by the adsorption hole 30SH which is a retention portion for sealing portion formed in the pressing portion 30PR.

The sealing portion 30SL shown in FIG. 28 has a frame shape in plan view and the surface 30b of the sealing portion 30SL is firmly attached to the back surface 3b of the logic chip LC over the entire circumference of the peripheral edge portion of the back surface 3b of the logic chip LC. Described specifically, as shown in FIGS. 25 and 28, the pressing portion 30PR has, at the peripheral edge portion thereof, a stepped portion 30ST having planarly a frame shape and the sealing portion 30SL is fitted in and retained by the stepped portion 30ST. The soft adhesive member NCL1 can therefore be inhibited from spreading to the side of the back surface 3b of the logic chip LC.

As shown in FIG. 26, the surface 30b of the sealing portion 30SL covers therewith the peripheral edge portion of a region where the adhesive member NCL1 is placed. The sealing portion 30SL has, on the side opposite to the surface 30b thereof, an outer periphery portion of the pressing portion 30PR. This means that the pressing portion 30PR presses, via the sealing portion 30SL, the adhesive material NCL1 pushed to the periphery of the logic chip LC. The rising of the adhesive material NCL1 can therefore suppressed so that the height of the adhesive material NCL1 pushed to the periphery of the logic chip LC does not exceed the height of the back surface 3b of the logic chip LC.

The surface 30b to be brought into contact with the adhesive material NCL1 is made of a resin. The surface 30b of the sealing portion 30SL made of a resin prevents the adhesive material NCL1 from attaching to the sealing portion 30SL. Particularly in the present embodiment, a resin material including the sealing portion 30SL is, for example, a fluororesin (a synthetic resin obtained by polymerizing a fluorine-containing olefin). The fluororesin is a particularly preferred material because the sealing portion made of this resin inhibits the adhesive material NCL1 from attaching thereto and the resin has heat resistance in the above-mentioned bonding step.

As shown in FIG. 26, the sealing portion 30SL is retained by the pressing portion 30PR through air suction from the air inlet hole (retention portion for sealing portion) 30SH formed in the pressing portion 30PR of the bonding jig 30. The sealing portion SL which has attached to the adhesive material NCL1 and cured or the sealing portion 30SL which has deteriorated is therefore detachable easily.

As shown in FIG. 26, the air inlet hole 30SH for retaining the sealing portion 30SL is formed at a position different from the retention portion 30HD for adsorbing and retaining the logic chip LC. The retention portion 30HD is formed at the central portion of the pressing portion 30PR and the central portion of the pressing portion 30PR is exposed from the sealing portion 30SL at the inside of the sealing portion 30SL. This means that the bonding jig 30 can adsorb and retain both the logic chip LC and the sealing portion 30L made of a resin collectively. Using the bonding jig 30 makes it possible to mount the logic chip LC on the wiring board 20 through the single path mounting system in which the logic chip LC is pressed against the adhesive material NCL1 without leaving it on the adhesive material NCL1.

When the central portion of the pressing portion 30PR is exposed from the sealing portion 30SL at the inside of the sealing portion 30SL as shown in FIG. 28, the pressing portion 30PR can be brought into contact with the logic chip LC as shown in FIG. 26. In this case, compared with the case where the pressing portion 30PR coupled to the heat source 30HT and the logic chip LC have therebetween the resin film 32 as shown in FIG. 27, heat can be transferred more efficiently.

### <Second Adhesive Material Placing Step>

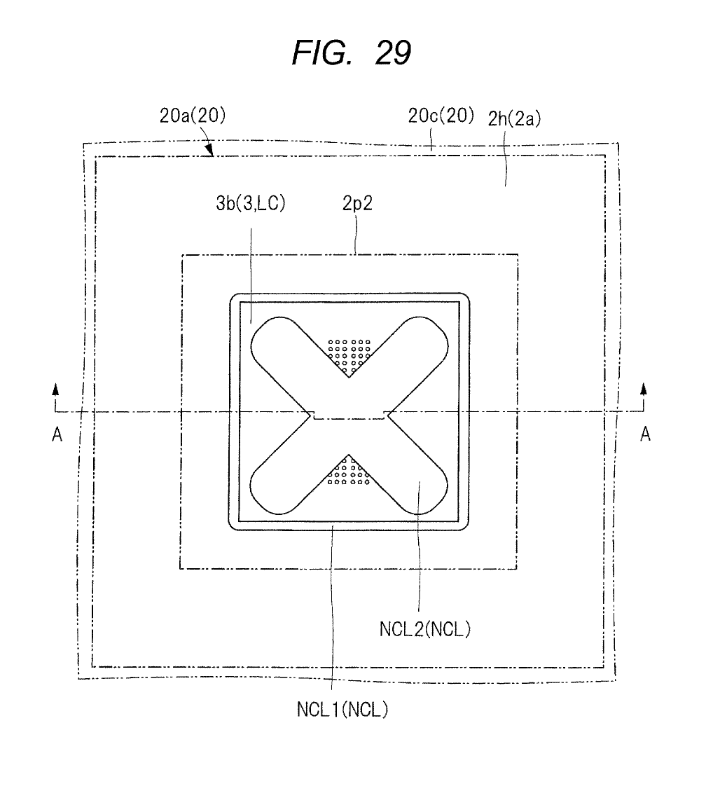

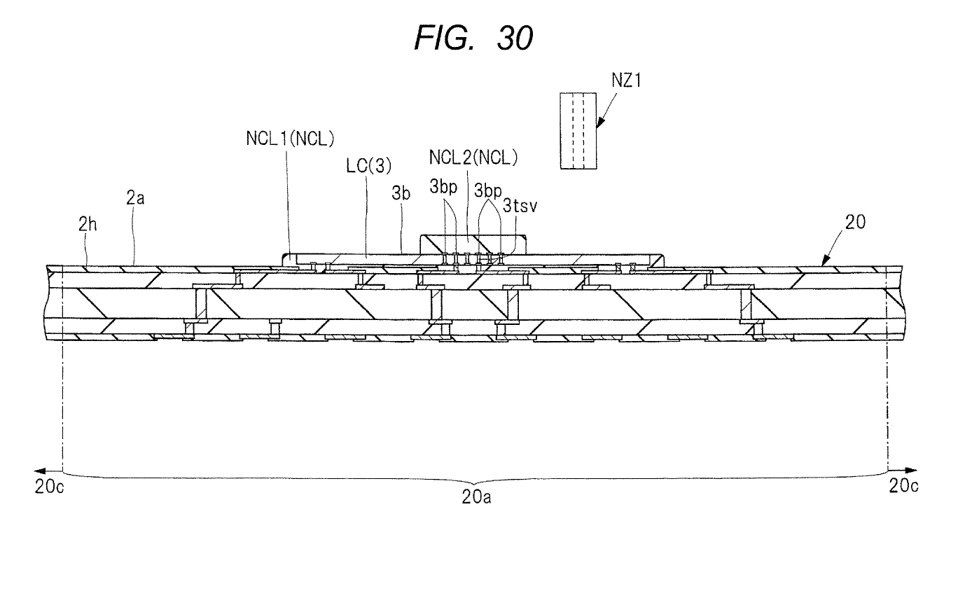

Next, in the second adhesive material placing step shown in FIG. 11, an adhesive material NCL2 is placed on the back surface 3b of the logic chip LC (semiconductor chip 3). FIG. 29 is an enlarged plan view showing the adhesive materials placed on the back surface and therearound of the semiconductor chip shown in FIG. 17. FIG. 30 is an enlarged cross-sectional view taken along the line A-A of FIG. 29.

As shown in FIG. 6, in the semiconductor device 1 of the present embodiment, among a plurality of the semiconductor chips 3 to be stacked, the logic chip LC to be mounted on the bottom stage (first stage) and the memory chip MC1 to be mounted on the second stage, counted from the bottom, are each mounted through the facedown mounting method (flip chip mounting method). As described in the first adhesive material placing step, the above-mentioned pre-application method is preferred from the standpoint of shortening the treatment time per device region 20a (refer to FIGS. 29 and 30) and improving the manufacturing efficiency.

The adhesive material NCL2 to be used in the pre-application method is, as described above, made of an insulating (nonconductive) material (for example, a resin material). The adhesive material NCL2 is made of a resin material that becomes hard (has an increased hardness) when exposed to energy. In the present embodiment, it contains, for example, a thermosetting resin. The adhesive material NCL2 before curing is softer than the protruding electrode 7b shown in FIG. 6 and is deformed by the logic chip LC pressed against it.

The adhesive material NCL2 before curing is classified roughly into a paste-like resin (insulating material paste) called “NCP” and a resin (insulating material film) formed into a film in advance and called “NCF” according to a difference in handling method. As the adhesive material NCL2 to be used in the present step, either one of NCP or NCF can be used. In the example shown in FIGS. 29 and 30, the adhesive material NCL2 belonging to NCP is discharged from a nozzle NZ1 (refer to FIG. 30) and the adhesive material NCL2 is placed on the back surface 3b of the logic chip LC.

This method and the post injection method described above in the first adhesive material placing step are similar in discharge of the paste-like adhesive material NCL2 from the nozzle NZ1. In the present embodiment, however, the adhesive material NCL2 is mounted in advance prior to mounting of the memory chip MC1 shown in FIG. 4. Compared with the post injection method in which a resin is injected through a capillary phenomenon, the method employed here can greatly improve the application rate of the adhesive material NCL2.

The adhesive material NCL2 has a function as a fixing material and can attach and fix the memory chip MC1 (refer to FIG. 4) and the logic chip LC (refer to FIG. 4) in the second chip mounting step shown in FIG. 11. Further, the adhesive material NCL2 functions as a sealing material and can seal and thereby protect the junction between the memory chip MC1 and the logic chip LC. The sealing function includes a stress relaxing function for dispersing and relaxing the stress transmitted to the junction between the memory chip MC1 and the logic chip LC and thereby protecting the junction.

From the standpoint of satisfying the function as a sealing material, in order to place the adhesive material NCL2 so as to wrap therewith the periphery of the junction between the memory chip MC1 and the logic chip LC, sealing of a plurality of the external terminals 7 shown in FIG. 6 with the adhesive material NCL2 is only necessary when at least the memory chip MC1 is mounted.

### <Second Chip Providing Step>

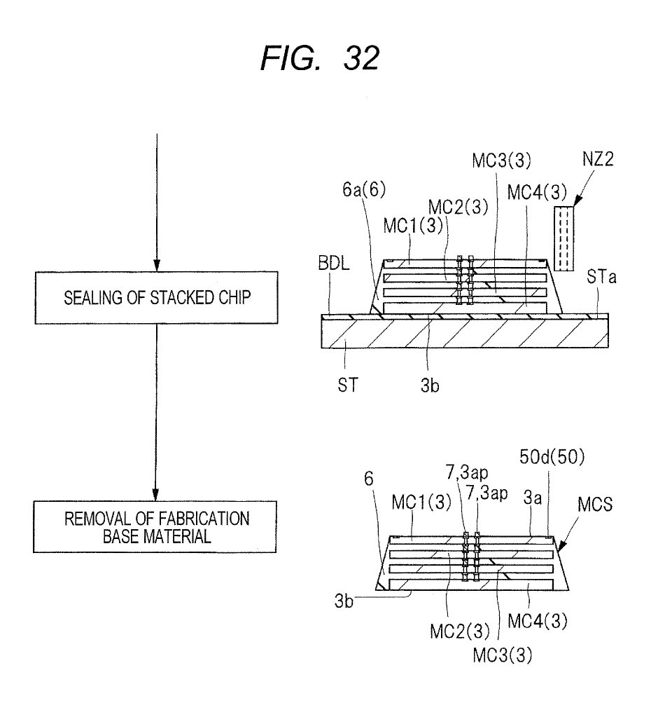

In the second chip providing step shown in FIG. 11, a chip stack MCS of the memory chips MC1, MC2, MC3, and MC4 shown in FIG. 4 is provided. As a modification example of the present embodiment, the memory chips MC1, MC2, MC3, and MC4 can be stacked one after another over the logic chip LC. In the present embodiment, an aspect in which the memory chips MC1, MC2, MC3, and MC4 are stacked in advance to form the chip stack (memory chip stack, semiconductor chip stack) MCS shown in FIG. 32 will be described. As described below, when the chip stack MCS of the memory chips MC1, MC2, MC3, and MC4 is formed, it can be formed independently at a place different from the place where steps shown in FIG. 11 other than the second chip providing step are performed. For example, the chip stack MCS can be provided as a purchased product. Using a purchased product is advantageous because it simplifies the manufacturing steps shown in FIG. 11 and improves the manufacturing efficiency as a whole.

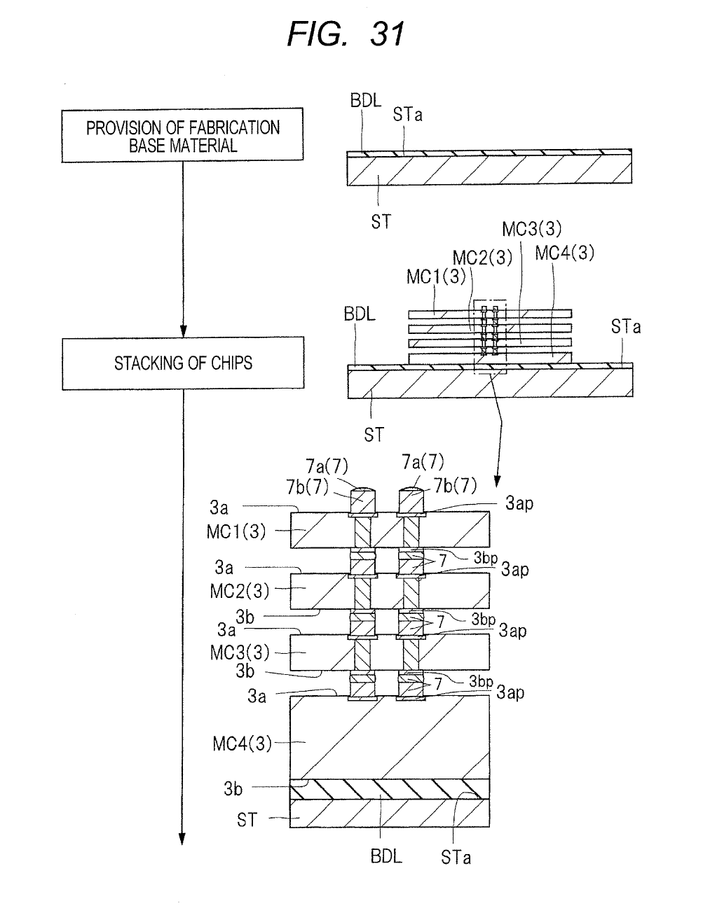

FIG. 31 is an explanatory view schematically showing the outline of fabrication steps of the memory chip stack shown in FIG. 4. FIG. 32 is an explanatory view schematically showing the outline of fabrication steps of the memory chip stack following that of FIG. 31. A description on the manufacturing method of each of the memory chips MC1, MC2, MC3, and MC4 shown in FIGS. 31 and 32 is omitted because the manufacturing method of a semiconductor chip described referring to FIGS. 21 and 22 can be applied to it.

First as a step of providing a fabrication base material, a base material (fabrication base material) ST for fabricating the chip stack MCS shown in FIG. 32 is provided. The base material ST has a fabrication surface STa over which the memory chips MC1, MC2, MC3, and MC4 are stacked and it has, on the fabrication surface STa thereof, an adhesive layer 35.

Next, as a chip stacking step, the memory chips MC1, MC2, MC3, and MC4 are stacked over the fabrication surface STa of the base material ST. In the example shown in FIG. 31, the memory chips MC4, MC3, MC2, and MC1 are successively stacked in order of mention so that the back surface 3b of each of the semiconductor chips 3 to be stacked faces to the fabrication surface STa of the base material ST. The back-surface electrode 3bp of a semiconductor chip 3 and the surface electrode 3ap of a semiconductor chip 3 lying therebelow are bonded, for example, with an external terminal 7 (the protruding electrode 7b and the solder material 7a shown in FIG. 6).

Next, in the stack sealing step shown in FIG. 32, a resin (underfill resin) is supplied between the stacked semiconductor chips 3 to form a sealing body (sealing body for chip stack, resin body for chip stack) 6. This sealing body 6 is formed by the post injection method described above in the first adhesive material placing step. Described specifically, after stacking the semiconductor chips 3 in advance, an underfill resin 6a is supplied from a nozzle NZ2 to fill between the stacked semiconductor chips. The underfill resin 6a has a viscosity lower than that of the sealing resin to be used in the sealing step shown in FIG. 11 and can fill a space between the semiconductor chips 3 by making use of a capillary phenomenon. The underfill resin 6a with which which a space between the semiconductor chips 3 has been filled is cured to obtain a sealing body 6.

This method of forming the sealing body 6 through the post injection method is superior in space filling characteristics to the so-called transfer molding method so that it is effective when applied to the case where the space between the stacked semiconductor chips 3 is small. When the space to be filled with the underfill resin 6a is formed in a plurality of stages, a plurality of the spaces can be filled with the underfill resin 6a collectively. This makes it possible to reduce the treatment time as a whole.

Next, in the fabrication base material removing step, the base material ST and the adhesive layer BDL are separated and removed from the back surface 3b of the memory chip MC4. As a method of removing the base material ST and the adhesive layer BDL, for example, a method of curing a resin component (for example, a ultraviolet curable resin) contained in the adhesive layer BDL can be used. By the above-mentioned steps, the chip stack MCS in which a plurality of the memory chips MC1, MC2, MC3, and MC4 is stacked and the coupled portions of the memory chips MC1, MC2, MC3, and MC4 are each sealed with the sealing body 6 can be obtained. This chip stack MCS can be regarded as one memory chip having a surface 3a (the surface 3a of the memory chip MC1) having a plurality of surface electrodes 3ap and a back surface 3b (the back surface of the memory chip MC4) located on the side opposite to the surface 3a.

### <Second Chip Mounting Step>

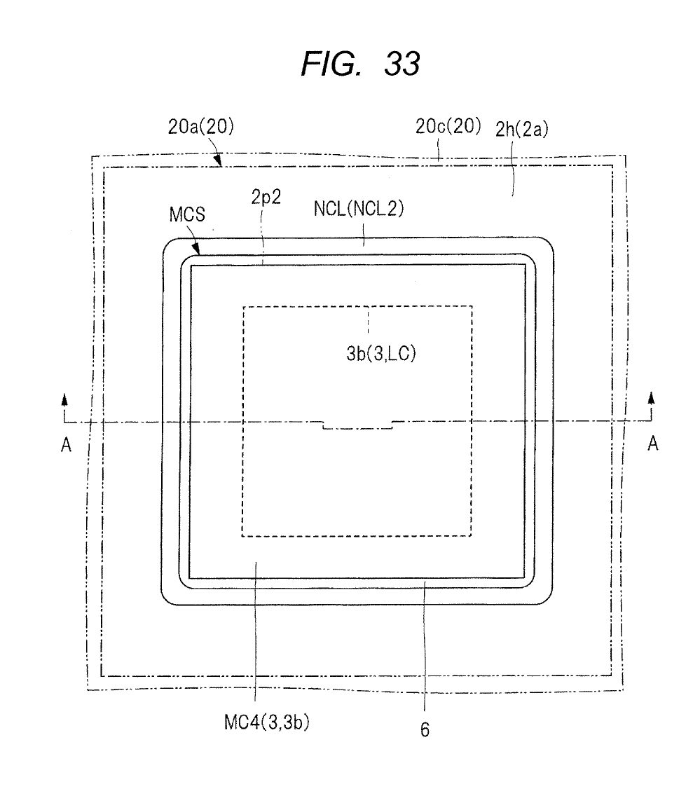

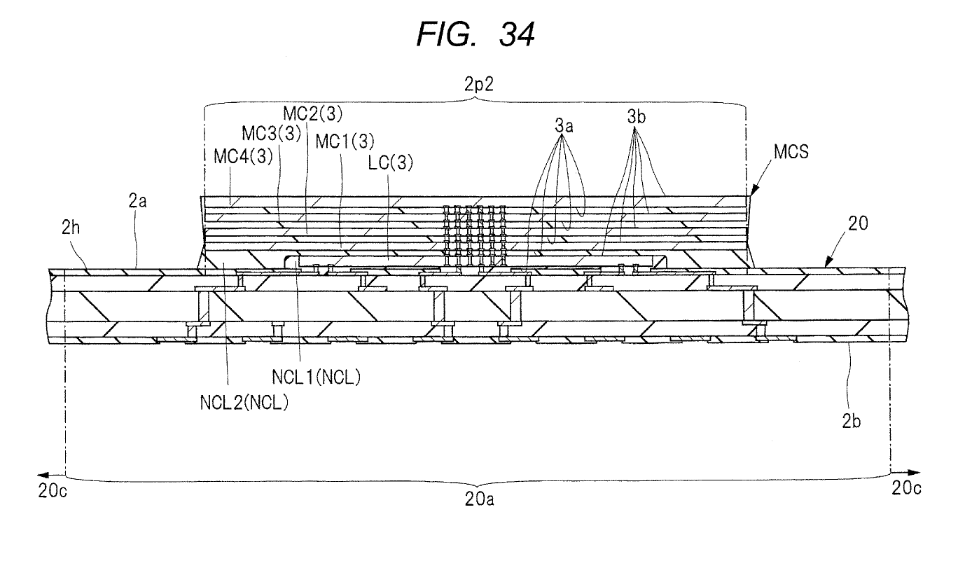

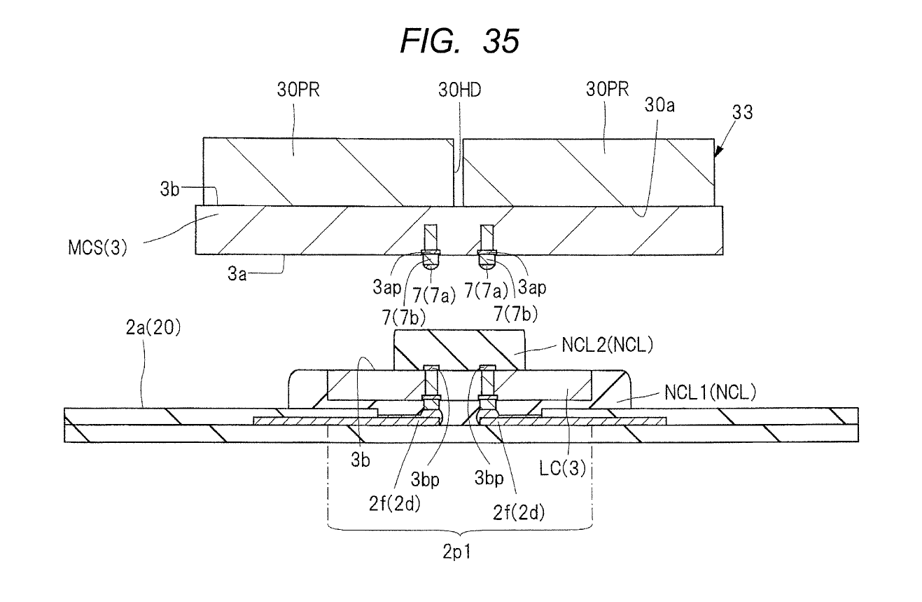

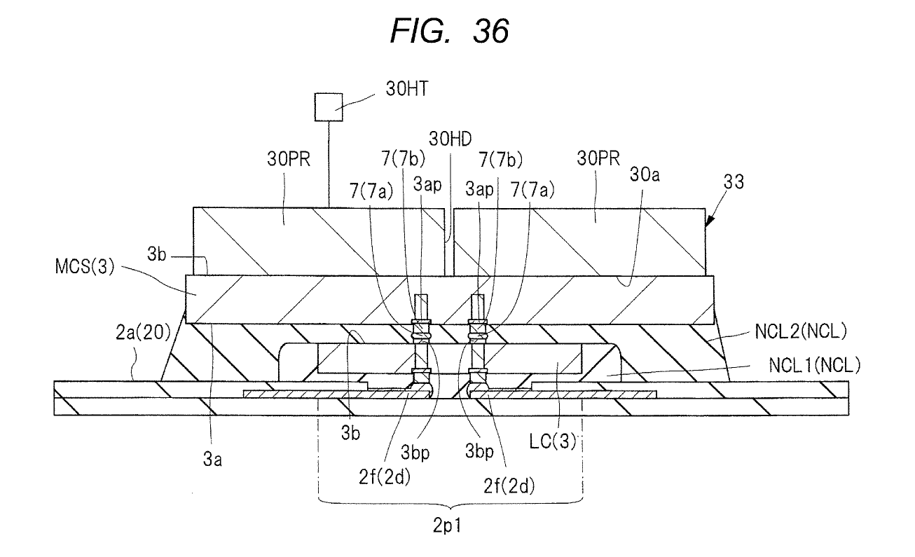

Next, in the second chip mounting step shown in FIG. 11, as shown in FIGS. 33 and 34, the chip stack MCS is mounted on the back surface 3b of the logic chip LC. FIG. 33 is an enlarged plan view showing the chip stack mounted on the back surface of the logic chip shown in FIG. 29. FIG. 34 is an enlarged cross-sectional view taken along the line A-A of FIG. 33. FIG. 35 is an explanatory view schematically showing the chip stack placed over the logic chip in the second chip mounting step shown in FIG. 11. FIG. 36 is an explanatory view schematically showing the logic chip and the chip stack electrically coupled to each other in the second chip mounting step shown in FIG. 11.

In the present step, as shown in FIG. 34, the chip stack MCS is mounted so that the surface 3a of the chip stack MCS (the surface 3a of the memory chip 3a) faces to the back surface 3b of the logic chip LC by using the so-called facedown mounting method (flip chip coupling method). By the present step, the memory chips MC1, MC2, MC3, and MC4 and the logic chip LC are electrically coupled to each other. Described specifically, as shown in FIG. 6, a plurality of the surface electrodes 3ap formed on the surface 3a of the chip stack MCS (memory chip MC1) and a plurality of the back-surface electrodes 3bp formed on the back surface 3b of the logic chip LC are electrically coupled to each other via the external terminal 7 (the protruding electrode 7b and the solder material 7a shown in FIG. 6). The detailed flow of the present step will hereinafter be described referring to FIGS. 35 and 36.

The second chip mounting step shown in FIG. 11 includes a second chip conveying step for conveying the chip stack MCS (semiconductor chips 3) onto the chip mounting region 2p2 of the wiring board 20 as shown in FIG. 35.

The chip stack MCS is conveyed to over the adhesive material NCL2 applied to the chip mounting region 2p2 while being retained, on the back surface 3b of the chip stack chip, by a bonding jig 33 and placed over the adhesive material NCL2 so that the surface 3a located on the element formation surface side faces to the back surface 3b of the logic chip LC. In the present step, the logic chip LC and the wiring board 20 are planarly aligned so that each of a plurality of the protruding electrodes 7b of the chip stack MCS and each of a plurality of the back-surface electrodes 3bp of the logic chip LC face to each other.

The second chip mounting step includes a bonding step in which as shown in FIG. 36, by heating the back surface 3b of the chip stack MCS via the bonding jig 33 and pressing the bonding jig 33 against the back surface 3b of the chip stack MCS, each of a plurality of the back-surface electrodes 3bp and each of a plurality of the surface electrodes 3ap are electrically coupled to each other.

In the bonding step, the pressing portion 30PR of the bonding jig 33 is brought into contact with the back surface 3b of the chip stack MCS and the chip stack MCS is pressed against the logic chip LC. In the example shown in FIG. 36, the entirety of the pressing portion 30PR is brought into contact with the back surface 3b of the chip stack MCS. Since the adhesive material NCL2 is still soft before curing, the chip stack MCS approaches the logic chip when the chip stack MCS is pushed by the bonding jig 33. In addition, the tip (more specifically, the solder material 7a shown in FIG. 35) of a plurality of the external terminals 7 formed on the surface 3a of the chip stack MCS is brought into contact with the back-surface electrode 3bp of the logic chip LC.

In addition, in the bonding step, the chip stack MCS and the adhesive material NCL2 are heated via the bonding jig 33 with the chip stack MCS being pressed against the bonding jig 33. In the example shown in FIG. 36, the bonding jig 33 is coupled to a heat source 30HT such as heater and the entirety of the pressing portion 30PR of the bonding jig 33 is heated with the heat transmitted from the heat source 30HT. FIG. 36 schematically shows an example in which the heat source 30HT is provided outside the bonding jig 33 and they are physically coupled to each other, but the position of the heat source 30HT is not particularly limited. For example, a heater or the like can be buried in the bonding jig 33. Alternatively, the bonding jig 33 can be heated by firmly attaching a heating jig, not shown, having a heater therein to the bonding jig 33.

When the bonding jig 33 is heated, the solder material 7a on the side of the protruding electrode 7b melts at the junction between the chip stack MCS and the logic chip LC and is bonded to the back-surface electrode 3bp of the logic chip LC.

The adhesive material NCL2 is heated with the heat transferred from the bonding jig 33 and then the adhesive material NC2 cures. As a result, the adhesive material NCL2 cures while sealing between the chip stack MCS and the wiring board 20 therewith. In the example shown in FIG. 26, a space between the chip stack MCS and the wiring board 20 is filled with the adhesive material NCL2. From the standpoint of protecting the junction between the chip stack MCS and the logic chip LC, filling at least a space between the chip stack MCS and the logic chip LC with the adhesive material NCL2 is only necessary.

In the second chip mounting step, similar to the first chip mounting step, the chip stack MCS can be mounted on the logic chip LC by using the bonding jig 30 shown in FIG. 25. In the example shown in FIGS. 35 and 36, however, the bonding jig 33 different from the bonding jig 30 (refer to FIG. 25) in structure is used for mounting the chip stack MCS on the logic chip.

The bonding jig 33 shown in FIG. 35 is different from the bonding jig 30 shown in FIG. 25 in that it does not have the sealing portion 30SL shown in FIG. 25. The chip stack MCS is mounted on the wiring board 20 via the logic chip LC as shown in FIG. 35 so that the distance from the upper surface of the wiring board 20 to the surface 3a of the chip stack MCS becomes relatively large. The thickness of the chip stack MCS is greater than that of the logic chip LC.

In the second chip mounting step, compared with the first chip mounting step, there is a small possibility of the height of the adhesive material NCL2 pushed to the periphery of the logic chip LC exceeding the height of the back surface 3b of the chip stack MCS. In the example shown in FIG. 35, therefore, the chip stack MCS is mounted using the bonding jig 33 having a structure simpler than that of the bonding jig 30 shown in FIG. 25. When the adhesive material NCL2 may reach the back surface 3b of the chip stack MCS, however, a bonding jig 30 having a sealing portion 30SL similar to the bonding jig 30 is preferably used.

### <Sealing Step>

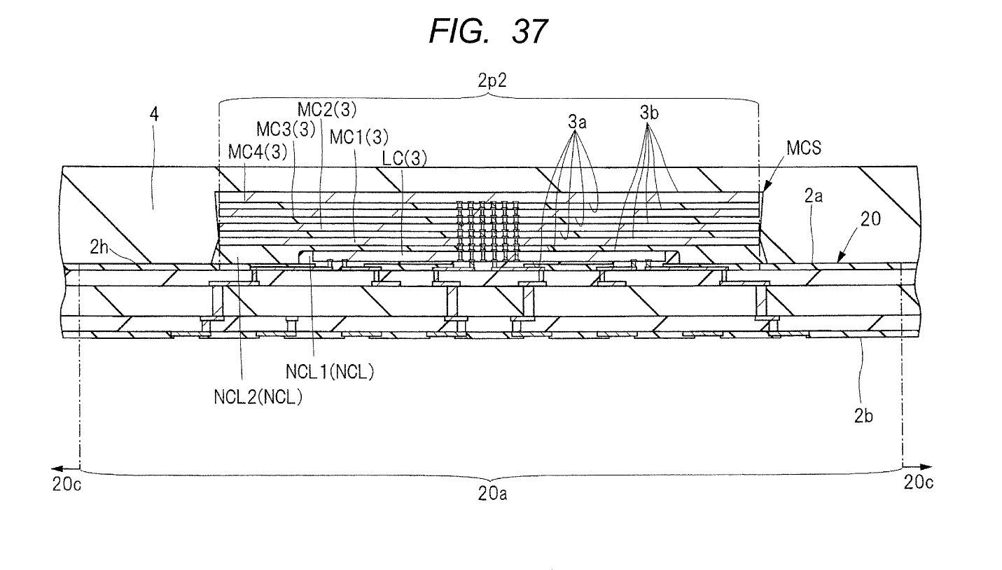

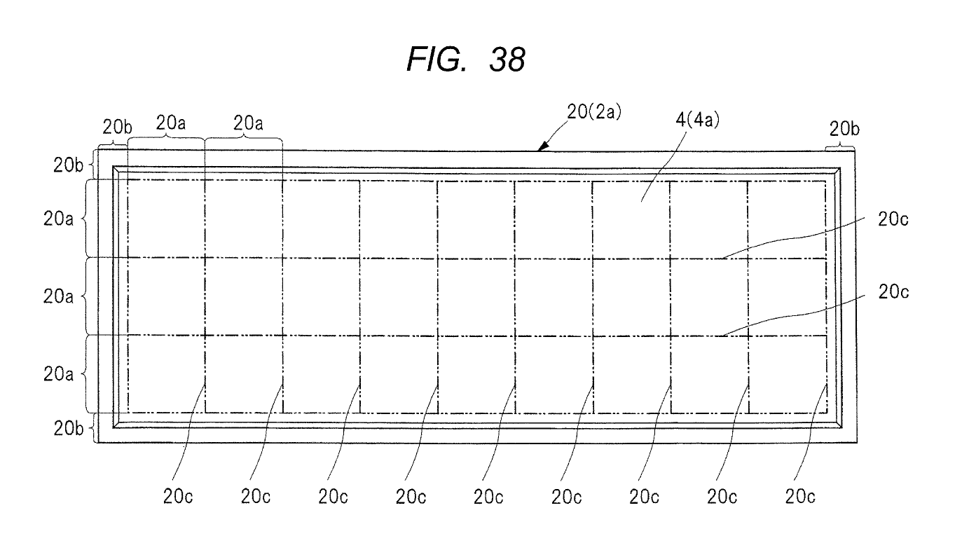

Next, in the sealing step shown in FIG. 11, a sealing body 4 is formed by sealing, with a resin, the upper surface 2a of the wiring board 20, the logic chip LC, and the chip stack MCS of the memory chips memory chips MC1, MC2, MC3, and MC4 as shown in FIG. 37. FIG. 37 is an enlarged cross-sectional view showing stacked semiconductor chips sealed with a sealing body formed on the wiring board shown in FIG. 34. FIG. 38 is a plan view showing an overall structure of the sealing body shown in FIG. 37.

In the present embodiment, as shown in FIG. 38, a sealing body 4 for sealing therewith a plurality of the device regions 20a is formed. Such a formation method of the sealing body 4 is called “block molding method” and a semiconductor package manufactured using this block molding method is called a “MAP (multi array package) type semiconductor device”. This block molding method is capable of reducing the distance between the device regions 20a, leading to an increase in an effective area per the wiring board 20. This means an increase in the number of products available from one wiring board 20. The manufacturing steps can be made more efficient by enlarging the effective area per the wiring board 20.

In the present embodiment, the sealing body is formed by the so-called transfer molding method in which a resin softened by heating is pressed and then molded in a mold not shown, followed by thermosetting of the resin. Compared with a sealing body obtained by curing a liquid resin, for example, the sealing body 6 for sealing the chip stack MCS shown in FIG. 37, the sealing body 4 formed using the transfer molding method has high durability and is therefore suited as a protecting member. When a thermosetting resin contains filler particles, for example, silica (silicon dioxide: SiO₂) particles, the resulting sealing body 4 can have improved functions (for example, resistance against warpage deformation).

In the present embodiment, the junction (electrically coupled portion) of the stacked semiconductor chips is sealed with the adhesive materials NCL1 and NCL2, and the sealing body 6. As a modification example, an aspect in which the sealing body 4 is not formed can be used. In this case, the sealing step shown in FIG. 11 can be omitted.

### <Ball Mounting Step>

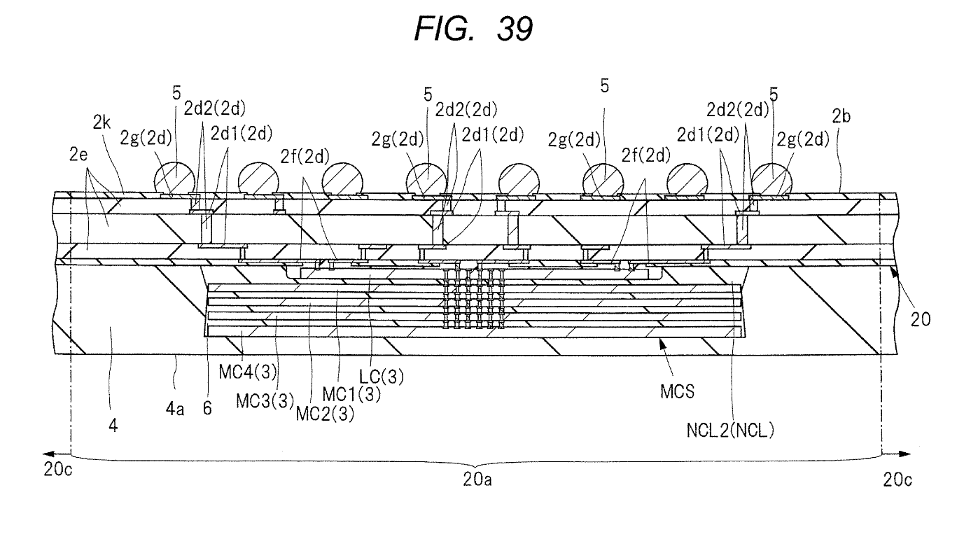

In the ball mounting step shown in FIG. 11, as shown in FIG. 39, a plurality of solder balls 5 serving as an external terminal are bonded to a plurality of lands 2g formed on the lower surface 2b of the wiring board 20. FIG. 39 is an enlarged cross-sectional view showing solder balls bonded onto a plurality of lands of the wiring board shown in FIG. 37.

In the present step, after the wiring board 20 is turned upside down as shown in FIG. 39 and the solder balls 5 are placed on the lands 2g exposed from the lower surface 2b of the wiring board 20, respectively, the solder balls 5 and the lands 2g are bonded by heating. By the present step, a plurality of the solder balls 5 is electrically coupled to a plurality of the semiconductor chips (logic chip LC and the memory chips MC1, MC2, MC3, and MC4) via the wiring board 20. The technology described in the present embodiment can however be applied not only to a so-called BGA (ball grid array) type semiconductor device in which the solder balls 5 have been bonded in array form. For example, as a modification example of the present embodiment, it can be applied to a so-called LGA (land grid array) type semiconductor device which is shipped while not forming the solder balls 5 but exposing the lands 2g or while applying a solder paste thinner than the solder balls 5 to the lands 2g. In the LGA type semiconductor device, this ball mounting step can be omitted.

### <Singulation Step>

Next, in the singulation step shown in FIG. 11, the wiring board 20 is divided into the device regions 20a as shown in FIG. 40. FIG. 40 is a cross-sectional view showing a multipiece wiring board shown in FIG. 39 after singulation.

In the present step, as shown in FIG. 40, the wiring board 20 and the sealing body 4 are cut along a dicing line (dicing region) 20c into individual semiconductor devices 1 (refer to FIG. 4). A cutting method is not particularly limited. FIG. 40 however shows an aspect in which the wiring board 20 and the sealing body 4 bonded and fixed to a tape material (dicing tape) 41 are cut from the lower surface 2b side of the wiring board 20 by a cutting work with a dicing blade (rotary blade) 40. The technology described in the present embodiment is however applied not only to the wiring board 20 which is a multipiece board having a plurality of the device regions 20a. For example, it can be applied to a semiconductor device having a plurality of the semiconductor chips 3 stacked over the wiring board 2 (refer to FIG. 4) corresponding to one semiconductor device. In this case, the singulation step can be omitted.

By the above-mentioned steps, the semiconductor device 1 described referring to FIGS. 1 to 11 can be obtained. Then, after necessary inspections and tests including visual test and electric test, the semiconductor device is shipped or packaged on a packaging board not shown.

### Modification Example

In the present embodiment, described is an aspect in which, in the first chip mounting step, the logic chip LC is mounted using the bonding jig 30 shown in FIGS. 25, 26, and 28 as a method of adjusting the height of the adhesive material NCL1 pushed to the periphery of the logic chip LC so as not to exceed the height of the back surface 3b of the logic chip LC. A modification example with respect to the bonding jig 30 will next be described.

When the entirety of the sealing portion 30SL is formed from a member made of a fluororesin as in the bonding jig 30, the sealing portion 30SL, if it has deteriorated, can be replaced easily with a new sealing portion 30SL. In addition, since the sealing portion 30SL made of a resin has elasticity, it can be firmly attached to the peripheral edge portion of the back surface 3b of the logic chip LC insofar as the surface 30b of the sealing portion 30SL and the surface 30a of the pressing portion 30PR have the same height or the surface 30b is below the surface 30a (on the side of the logic chip LC).

As described above, however, in the first chip mounting step, the bonding jig 30 is heated. The sealing portion 30SL is sometimes deformed by it. As shown in FIG. 28, the sealing portion 30SL has a frame shape in plan view and has the pressing portion 30PR inside the frame. The sealing portion 30SL is deformable in the direction away from the surface 30a of the pressing portion 30PR in plan view. In this case, there is a possibility of appearance of a space between the sealing portion 30SL and the pressing portion 30PR. There is also a possibility of deformation so that the height of the surface 30b becomes higher than the height of the surface 30a.

The present inventors therefore investigated a technology of suppressing deformation of the sealing portion 30SL or suppressing a deformation direction of the sealing portion 30SL.

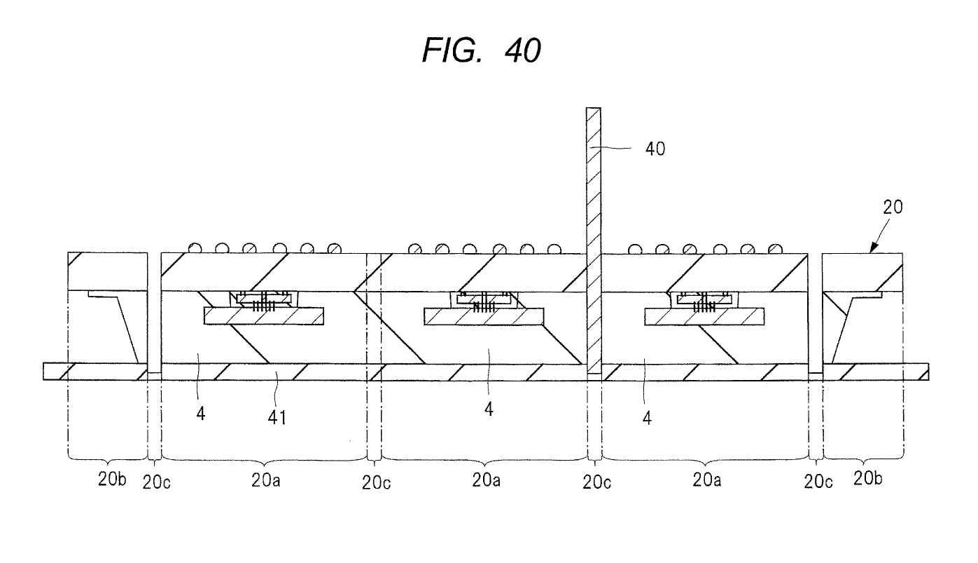

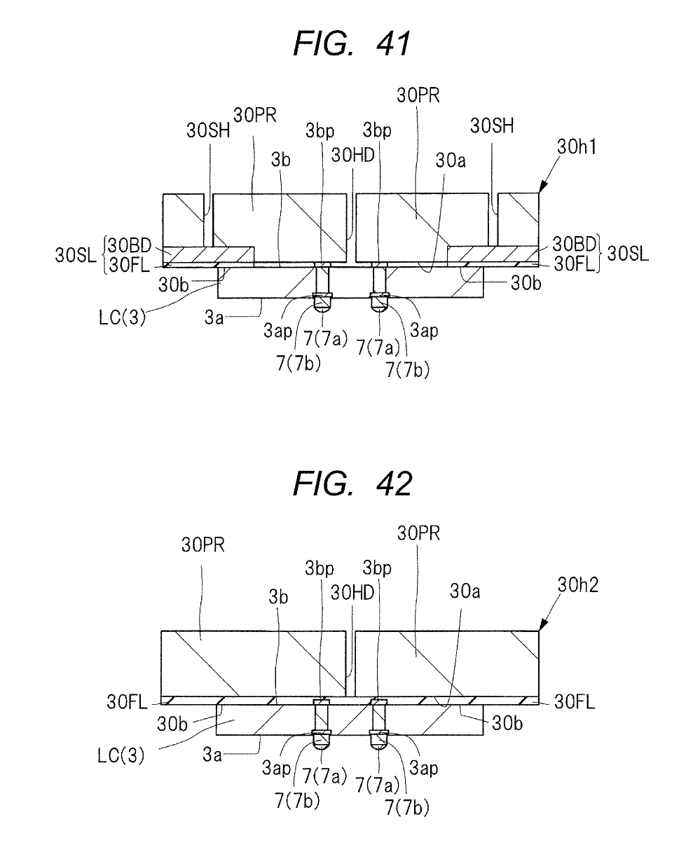

FIG. 41 is a cross-sectional view showing a modification example of the bonding jig shown in FIG. 25. The sealing portion 30SL of the bonding jig 30h1 shown in FIG. 41 has a resin film 30FL having a surface 30b facing to the peripheral edge portion of the back surface 3b of the logic chip LC and a support portion 30BD coated with the resin film 30FL. The support portion 30BD is made of, for example, a metal material or ceramic material same as that of the pressing portion 30PR and the resin film 30FL made of a fluororesin is formed on the surface 30b to be firmly attached to the logic chip LC. The resin film 30FL has a thickness (film thickness) of, for example, from about 2 μm to 50 μm.

The bonding jig 30h1 is similar to the bonding jig 30 (refer to FIG. 25) in that it can be replaced easily with a new one when the resin film 30FL has deteriorated. The resin film 30FL is applied with a small thickness so that it firmly attaches to the support portion 30BD made of the material same as that of the pressing portion 30PR of the bonding jig 30h1 so that it does not easily deform even if the sealing portion 30SL is heated. Compared with the bonding jig 30 shown in FIG. 25, however, the resin member is thin and therefore the sealing portion 30 undergoes less elastic deformation than the sealing portion 30SL of the bonding jig 30. The margin of processing accuracy of the sealing portion 30SL formed for bringing the back surface 3b of the logic chip LC and the surface 30b into contact with each other is greater than that of the bonding jig 30 shown in FIG. 25.

A material including the pressing portion 30PR and the support portion 30BD of the bonding jig is preferably harder than the resin film 30FL. Examples of such a material include metal materials such as stainless steel and ceramic materials such as aluminum nitride. From the standpoint of processing ease, the metal materials are preferred. From the standpoint of decreasing a linear expansion coefficient, on the other hand, the ceramic materials are preferable to the metal materials.

As an aspect in which a thin film of a resin such as fluororesin is applied to the surface 30b facing to the peripheral edge portion of the back surface 3b of the logic chip LC, there is a modification example such as a bonding jig 30h2 shown in FIG. 42. FIG. 42 is a cross-sectional view showing another modification example of the bonding jig shown in FIG. 25. In the bonding jig 30h2, an area of the surface 30a of the pressing portion 30PR is greater than that of the back surface 3b of the logic chip LC. In addition, the bonding jig 30h2 does not have the sealing portion 30SL as shown in FIG. 25 and it has, on the surface 30a, a thin resin film 30FL applied so as to be firmly attached to the pressing portion 30PR. In other words, in the bonding jig 30h2, the resin film 30FL applied to the surface 30a of the pressing portion 30PR functions as the sealing portion 30SL shown in FIG. 25. The resin film 30FL is, for example, a film made of a fluororesin and the resin film 30FL has a thickness (film thickness) of, for example, from about 2 μm to 50 μm.

When the bonding jig 30h2 is used in the above-mentioned first chip mounting step, the back surface 3b of the logic chip LC is, at the peripheral edge portion thereof, covered with the surface 30a of the resin film 30FL. The resin 30FL undergoes elastic deformation following the layout of the back-surface electrode 3bp so that if the resin film 30FL is thicker than the back-surface electrode 3bp of the logic chip LC, the peripheral edge portion of the back surface 3b and the surface 30a can be attached firmly. This means that in the bonding jig 30h2, the surface 30a of the pressing portion 30PR has also a function of the surface 30b of the sealing portion 30SL shown in FIG. 25.

When the logic chip LC is mounted using the bonding jig 30h2, a most part of (whole part except a portion facing to the retention portion 30HD) of the back surface 3b of the logic chip LC attaches firmly to the resin film 30FL. The bonding jig 30h2 can therefore add a well-balanced pressing force to the back surface 3b. In addition, the bonding jig 30h2 can reduce a temperature irregularity at the back surface 3b when the logic chip LC is heated.

When the resin film 30FL has deteriorated or the adhesive material NCL1 (refer to FIG. 25) attached to the resin film 30FL has cured, the resin film 30FL should be separated from the pressing portion 30PR and a new resin film 30FL should be applied. From the standpoint of ease of maintenance, the bonding jig 30 shown in FIG. 25 or the bonding jig 30h1 shown in FIG. 41 is preferred.

In the bonding jig 30h2, the resin film 30FL is inserted between the pressing portion 30PR made of a ceramic or metal and the logic chip LC. In consideration of an efficiency of heat transfer, the pressing portion 30PR made of a ceramic or metal is preferably exposed at a position facing to the logic chip LC as in the bonding jig 30 shown in FIG. 25 or the bonding jig 30h1 shown in FIG. 41.

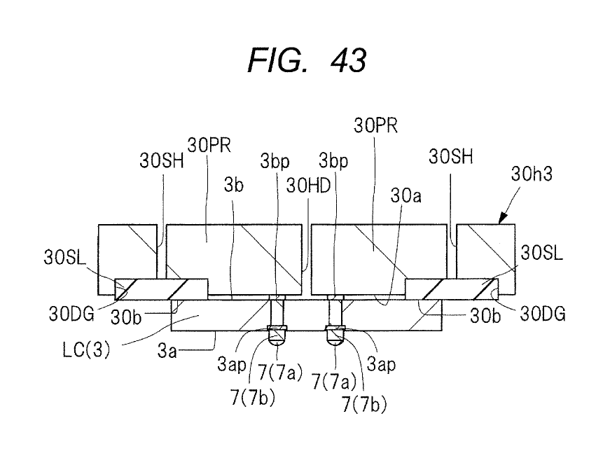

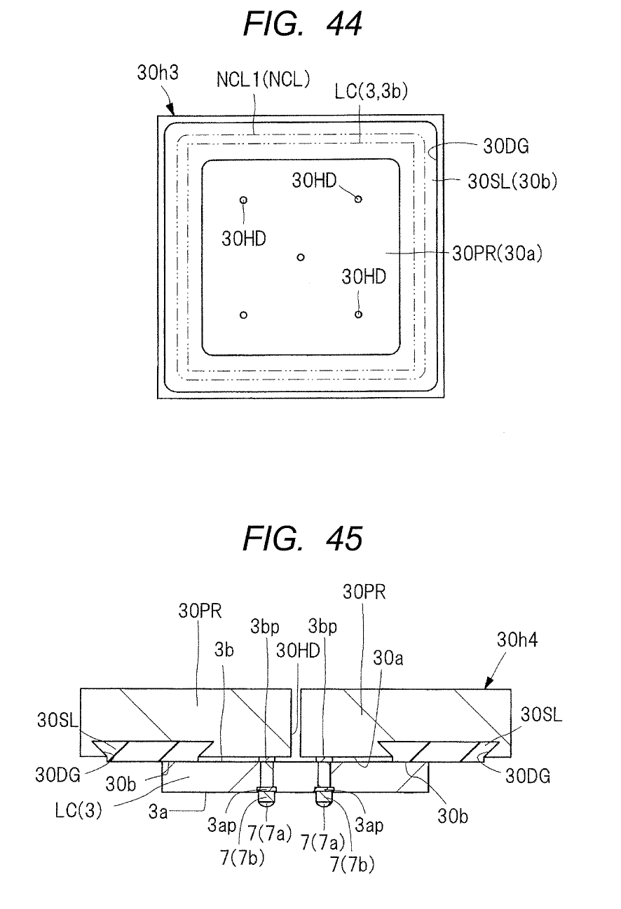

In the case of a bonding jig 30hs shown in FIGS. 43 and 44, it is retained by forming a frame-like trench portion 30DG at the peripheral edge portion of a pressing portion 30PR and inserting a sealing portion 30SL in the trench portion 30DG. FIG. 43 is a cross-sectional view showing a further modification example of the bonding jig shown in FIG. 25. FIG. 44 is a plan view of the surface of the bonding jig shown in FIG. 43 placed so as to face to the semiconductor chip.

The bonding jig has, at the pressing portion 30PR thereof made of a ceramic or metal, the trench portion 30DG. The trench portion 30DG has, as shown in FIG. 44, a frame shape along the peripheral edge portion of the back surface 3b of the logic chip LC. When the first chip mounting step is performed using the bonding jig 30h3, the trench portion 30DG functions as a guide for controlling the deformation direction of the sealing portion 30SL made of a resin. This means that even if the bonding jig 30hs is heated, the sealing portion 30SL made of a resin is undeformable in a planar direction. The sealing portion 30SL is deformable selectively in the thickness direction shown in FIG. 43. In addition, the trench portion 30DG and the sealing portion 30SL hardly have a space at the firmly attached surface therebetween.

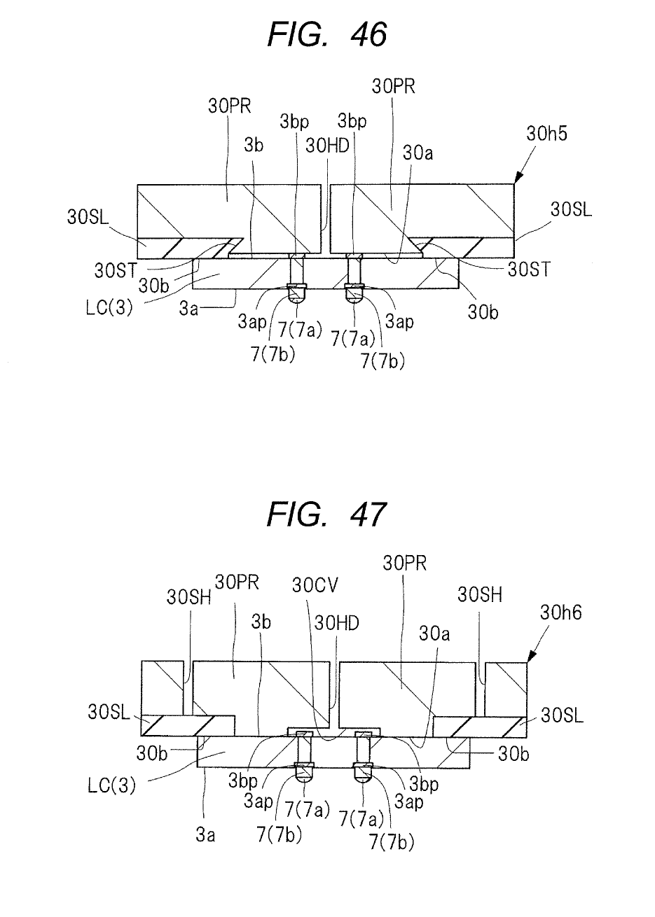

In the bonding jig 30 shown in FIG. 25, the bonding jig 30h1 shown in FIG. 41, and the bonding jig 30h3 shown in FIG. 43, the sealing portion 30SL is sucked to the adsorption hole 30SH and thereby adsorbed and retained by the pressing portion 30PR. The method of retaining the sealing portion 30SL has various modification examples. FIG. 45 is a cross-sectional view showing a modification example of the bonding jig shown in FIG. 43. FIG. 46 is a cross-sectional view showing another modification example of the bonding jig shown in FIG. 45.

In the bonding jig 30h4 shown in FIG. 45, the side surface of the trench portion 30DG has a surface inclined at an angle less than 90 degrees with respect to the surface 30a. In the example shown in FIG. 45, both side surfaces of the trench portion 30DG has a surface inclined at an angle less than 90 degrees with respect to the surface 30a. In this case, the sealing portion 30SL made of a resin is retained by the inclined surface of the trench portion 30DG so that the sealing portion 30SL can be retained without providing an adsorption hole 30SH as shown in FIG. 43.

In the bonding jig 30h5 shown in FIG. 46, a stepped portion 30ST is provided at a retaining position of the sealing portion 30SL made of a resin and the side surface of the stepped portion 30ST is inclined at an angle less than 90 degrees with respect to the surface 30a. From the standpoint of retaining stability of the sealing portion 30SL, the bonding jig 30h4 shown in FIG. 45 is preferred, but even a bonding jig 30h5 shown in FIG. 46 can retain the sealing portion 30SL without providing an adsorption hole 30SH as shown in FIG. 43.

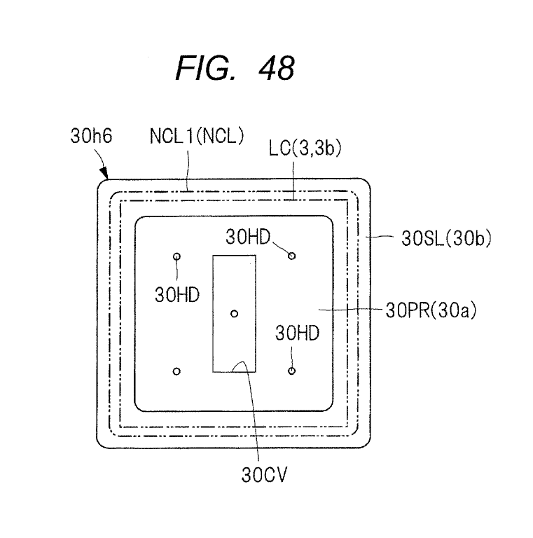

For a logic chip such as the logic chip LC having, on the back surface 3b thereof, a protrusion such as the back-surface electrode 3bp, a modification example such as a bonding jig 30hr6 shown in FIGS. 47 and 48 is preferred. FIG. 47 is a cross-sectional view showing a still further modification example of the bonding jig shown in FIG. 25. FIG. 48 is a plan view of the surface of the bonding jig shown in FIG. 47 placed to face to the semiconductor chip.

The bonding jig 30h6 has, in a portion of the surface 30a of the pressing portion 30PR, a recess portion 30CV. In the example shown in FIG. 48, the recess portion 30CV is formed at the center of the surface 30a of the pressing portion 30PR exposed from the sealing portion 30SL. The thickness of the recess portion 30CV is equal to or greater than the thickness of a protrusion formed on the back surface 3b of the logic chip LC, that is, the thickness of the back-surface electrode 3bp. In the example shown in FIG. 47, the depth of the recess portion 30CV is greater than the thickness of the back-surface electrode 3bp of the logic chip LC.

The recess portion 30CV is formed according to the position of the protrusion formed on the back surface 3b of the logic chip LC to be mounted. In the above-mentioned first chip mounting step, therefore, when the back surface 3b of the logic chip LC is pressed with the pressing portion 30PR while having a plurality of the back-surface electrodes 3bp housed in the recess portion 30CV, the surface 30a of the pressing portion 30PE firmly attaches to the back surface 3b without coming into contact with the plurality of the back-surface electrodes 3bp.

In the first chip mounting step, when the back surface 3b of the logic chip LC is pressed using the pressing portion 30PR while having a plurality of the back-surface electrodes 3bp housed inside the recess portion 30CV, the surface 30a of the pressing portion 30PR is attached firmly to the back surface 3b without being brought into contact with a plurality of the back-surface electrodes 3bp.

Firm attachment of the surface 30a of the pressing portion 30PR to the back surface 3b of the logic chip LC can increase an attachment area between the pressing portion 30PR made of a ceramic or a metal and the logic chip LC and thereby improve the heat transfer efficiency in the bonding step.

Retaining the logic chip LC without bringing the pressing portion 30PR into contact with a plurality of the back-surface electrodes 3bp in the first chip mounting step is preferred because of the following points. In the above-mentioned bonding step of the first chip mounting step, the pressing portion 30PR of the bonding jig 30hr is brought into contact with the back surface 2b of the logic chip LC and then, the logic chip LC is pressed against the wiring board 20 (refer to FIG. 26). At this time, as shown in FIG. 26, when the pressing portion 30PR and the logic chip LC are brought into contact with each other at the back-surface electrode 3bp, a pressing force at the time of mounting is applied intensively to a plurality of the back-surface electrodes 3bp. When the bonding jig 30h6 shown in FIGS. 47 and 48 is used, on the other hand, the back-surface electrode 3bp can be inhibited from damage which will otherwise be caused by the pressing force upon mounting because the back-surface electrode 3bp and the pressing portion 30PR are not in contact with each other. In addition, the logic chip LC can be inhibited from damage which will otherwise occur by the stress concentration on the periphery of the back-surface electrode 3bp. In particular, when the logic chip LC to be mounted has a thickness of about 50 μm as in the present embodiment, it is likely to be damaged compared with a semiconductor chip having a thickness of, for example, 100 μm or greater. From the standpoint of suppressing damage of the logic chip LC, using the bonding jig 30h6 shown in FIGS. 47 and 48 is particularly preferred.

In the first chip mounting step, firm attachment of the surface 30a of the pressing portion 30PR to the back surface 3b can improve the retention strength by the retention portion 30HD. In the first chip mounting step, misalignment between the logic chip LC and the bonding jig 30h6 due to deterioration in adsorption retentive power of the retention portion 30HD hardly occurs.

The bonding jig 30h6 shown in FIGS. 47 and 48 has been described as a modification example of the bonding jig 30 shown in FIGS. 25 and 28. The characteristic part of the bonding jig 30h6 can be used in combination with any of the bonding jig 30h1 shown in FIG. 41, the bonding jig 30h2 shown in FIG. 42, the bonding jig 30h3 shown in FIG. 43, the bonding jig 30h4 shown in FIG. 45, and the bonding jig 30h5 shown in FIG. 46.

### Second Embodiment

In First Embodiment, described is an aspect in which upon attaching the adhesive material NCL1, which is an insulating material film (NCF), to the chip mounting region 2p1 of the wiring board 20 in the first adhesive material placement step, a portion (portion HPZ) of the adhesive material NCL1 is pressed against the wiring board 20 as shown in FIG. 20, followed by firm attachment of them by pressing with the elastic material RL shown in FIG. 19. In the method described above in First Embodiment, remaining of air bubbles after pressing the adhesive material NCL1 against the wiring board can be inhibited because air between the adhesive material NCL1 and the wiring board 20 is discharged under a reduced pressure condition. When after the adhesive material NCL1 is placed in the chip mounting region 2p1 of the wiring board 20, the portion (portion HPZ) of the adhesive material NCL1 is pressed against the wiring board 20 with another jig, the number of working steps increases, leading to deterioration in manufacturing efficiency.

In the present embodiment, a technology capable of improving the manufacturing efficiency of First Embodiment will be described. Second Embodiment is a modification example of a part described in the section <first adhesive material placement step> in the technology described in First embodiment. The steps other than the first adhesive material placement step are common to these two embodiments so that an overlapping description will be omitted.

What is different in the present embodiment is, in the first adhesive material placement step, a step of conveying the adhesive material NCL1 divided into individual pieces while adsorbing and retaining them by a film conveyor jig and placing them on the chip mounting region 2p1 and a step of pressing a portion of the adhesive material NCL1 against the wiring board. The first adhesive material placement step of Second Embodiment is not different from that of First Embodiment except for the above-described steps so that a description on the first adhesive material placement step other than the above-mentioned difference will be omitted.

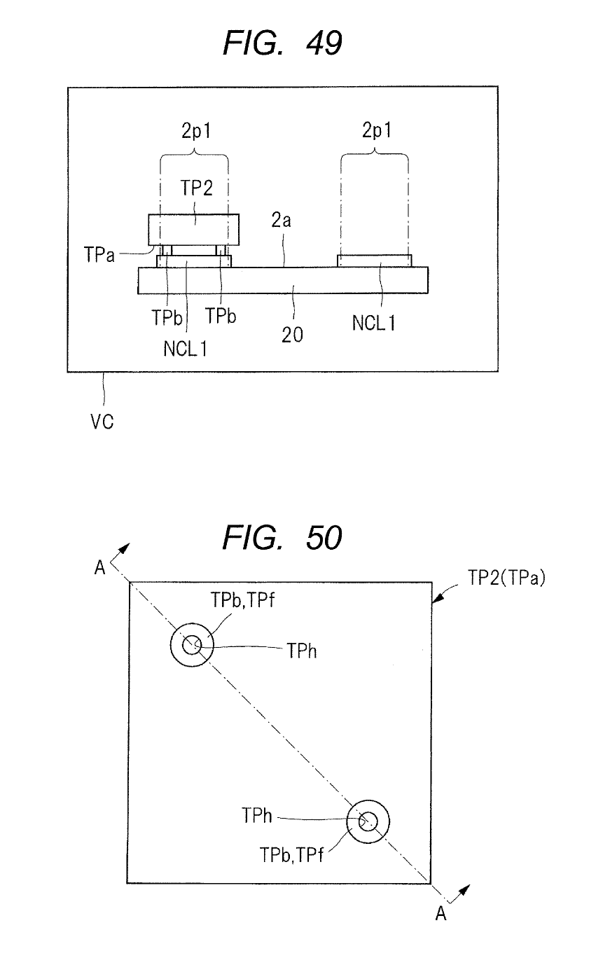

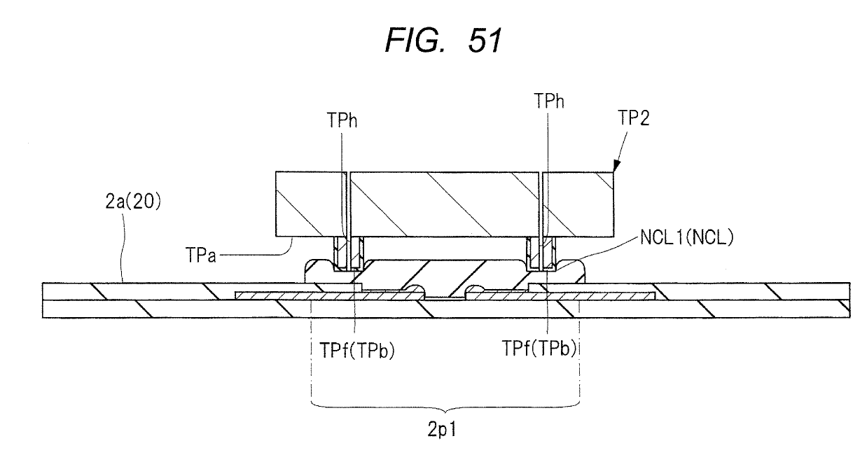

FIG. 49 is a side view showing a modification example of FIG. 18. FIG. 50 is a plan view showing the side of the surface of the film conveyor jig shown in FIG. 49 facing to the adhesive material. FIG. 51 is a cross-sectional view, in a cross-section taken along the line A-A of FIG. 50, schematically showing the adhesive material NCL1 pressed with a protruding portion of the film conveyor jig.

As shown in FIG. 49, a film conveyor jig TP2 of the present embodiment is different from the film conveyor jig TP2 shown in FIG. 18 in that the former one has a plurality of protruding portions TPb on the side of a surface TPa facing to the adhesive material NCL1. There are various modification examples with respect to the number of the protruding portions TPb. In the examples shown in FIGS. 49 to 51, the film conveyor jig TP2 has two protruding portions TPb. The protruding portions Tpb have two functions in the first adhesive material placement step of the present embodiment, that is, a function as a jig for conveying the adhesive material NCL1 and a function of pressing a portion of the adhesive material NCL1 against the wiring board 20.

As shown in FIGS. 50 and 51, a plurality of the protruding portions TPb each has an air inlet hole TPh. The air inlet hole TPh is a retention portion for adsorbing and retaining the adhesive material NCL1 (refer to FIG. 51) therewith. The film conveyor jig TP2 can retain the adhesive material NCL1 by sucking while bringing the tip of the protruding portion TPb into contact with the adhesive material NCL1 (refer to FIG. 51).

The protruding portion TPb has, on the exposed surface thereof (except the inside of the air inlet hole TPh), a resin film TPf such as a fluororesin film. The protrusion height of the protruding portion TPb from the surface TPa is greater than the thickness of the adhesive material NCL1. At the time of pressing the adhesive material NCL1 with the protruding portion TPb, the adhesive material NCL1 has difficulty in attaching to the protruding portion TPb or the main body of the film conveyor jig TP2.

In the first adhesive material placement step of the present embodiment, the film conveyor jig TP2 picks up the adhesive material NCL1 by sucking it while bringing the tip of the protruding portion TPb into contact with the adhesive material NCL1. Next, the adhesive material NCL1 is placed in the chip mounting region 2p1 of the wiring board 20. At this time, the chip mounting region 2p1 and the adhesive material NCL1 are aligned while retaining the adhesive material NCL1. Next, the film conveyor jig TP2 is brought close to the wiring board 20. At this time, a plurality of portions of the individual pieces of the adhesive material NCL1 is pressed by the protruding portion TPb. As a result, for example, as shown in FIG. 20, two portions (hatched portions HPZ), in plan view, of each of the pieces of the adhesive material NCL1 firmly attaches to the wiring board 20 with adhesive force relatively larger than that in the other portion.

As described in the above embodiment, misalignment of the adhesive material NCL1 can be prevented upon pressing it with the elastic material RL shown in FIG. 19, if a portion (the portion HPZ shown in FIG. 20) of the adhesive material NCL1 is pressed against the wiring board 20 in advance. Adhesive force between the wiring board 20 and the adhesive material NCL1 is smaller at a portion other than the portion HPZ than at the portion HPZ. Under a reduced pressure condition, air between the adhesive material NCL1 and the wiring board 20 is discharged through a discharge path formed at a portion having smaller adhesive force and therefore, remaining of air bubbles can be inhibited.

According to the present embodiment, a step of conveying the adhesive material NCL1 by using the film conveyor jig TP2 and a step of pressing a portion of the adhesive material NCL1 can be performed successively. This results in improvement in manufacturing efficiency compared with the first adhesive material placement step described in the above-mentioned embodiment.

### Third Embodiment

In First Embodiment, an aspect in which the adhesive material NCL1 is pressed with a portion of the bonding jig to be used upon mounting of the logic chip LC on the wiring board 20 in the first chip mounting step to adjust the height of the adhesive material NCL1 pushed to the periphery of the logic chip LC so as not to exceed the height of the back surface 3b of the logic chip LC has been described mainly. In the present embodiment, on the other hand, another aspect in which the height of the adhesive material NCL1 pushed to the periphery of the logic chip LC is adjusted so as not to exceed the height of the back surface 3b of the logic chip will be described.

As a result of investigation, the behavior of the adhesive material NCL1 at the time when the logic chip LC is pressed against the wiring board 20 as shown in FIG. 26 in the first chip mounting step described above in First Embodiment is presumed to be as follows. Described specifically, in a region sandwiched between the logic chip LC and the wiring board 20, the adhesive material NCL1 spreads in a direction along the upper surface 2a of the wiring board 20. In a region outside the peripheral edge portion of the logic chip LC, on the other hand, the adhesive material NCL1 is not sandwiched between the logic chip LC and the wiring board 20 so that the adhesive material NCL1 spreads in the thickness direction of the logic chip LC as well as in the direction along the upper surface 2a of the wiring board 20.

In the technology described in First Embodiment, the height of the adhesive material NCL1 is suppressed by pressing, with the sealing portion 30SL of the bonding jig 30, the adhesive material NCL1 which is spreading in the thickness direction. The adhesive material NCL1 exhibits the same behavior when as the adhesive material NCL1, an insulating material film (NCF) is used or an insulating material paste (NCP) is used.

Here, the present inventors have thought that if the adhesive material NCL1 pushed to the periphery of the logic chip LC easily spreads in a direction along the upper surface 2a of the wiring board 20, the height of the adhesive material NCL1 can be suppressed without pressing the adhesive material NCL1 with the sealing portion 30SL of the bonding jig 30. In the present embodiment, an aspect in which the height of the adhesive material NCL1 is adjusted not to exceed the height of the back surface 3b of the logic chip LC by suppressing the planarly spreading direction of the adhesive material NCL1, which has been pushed to the periphery of the logic chip LC, along the upper surface 2a of the wiring board 20 will be described.

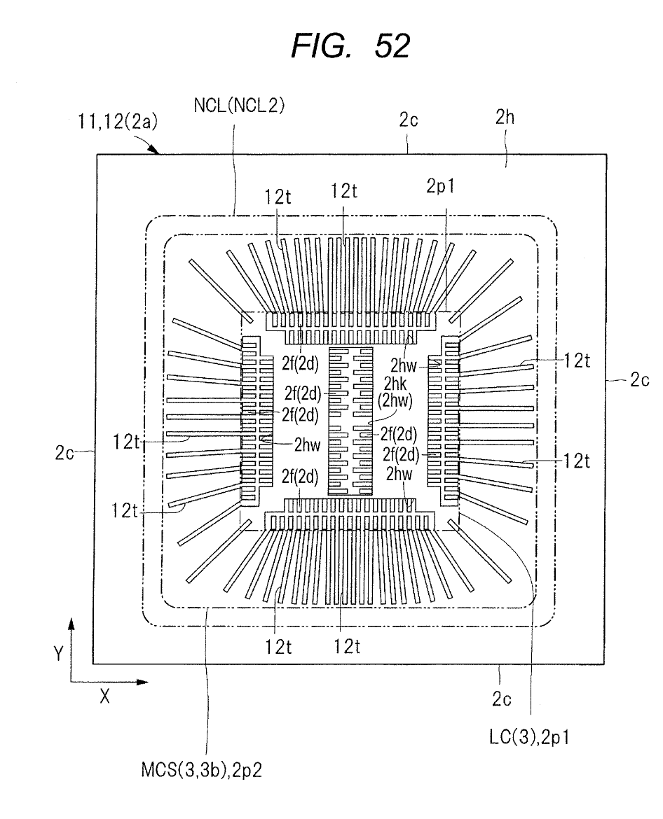

FIG. 52 is a plan view showing a semiconductor device on the side of a chip mounting surface thereof, which device is a modification example of the semiconductor device shown in FIG. 3. As shown in FIG. 52, a wiring board 12 which a semiconductor device 11 of the present embodiment has is different from that of the semiconductor device 1 of First Embodiment in that an insulating film 2h has, in the upper surface 2a thereof, a plurality of trenches 12t. The semiconductor device of the present embodiment is similar to the semiconductor device 1 described in the above embodiment in other points.

A plurality of the trenches 12t shown in FIG. 52 extends to the peripheral edge portion of the upper surface 2a from the chip mounting region 2p1 in plan view. A plurality of the trenches 12t is placed radially toward the peripheral edge portion of the upper surface 2a from the chip mounting region 2p1 in plan view.

In the present embodiment, the planarly spreading direction of the adhesive material NCL1, which has been pushed to the periphery of the logic chip LC, along the upper surface 2a of the wiring board 20 is controlled by making use of the trenches 12t formed outside the chip mounting region 2p1 of the wiring board 12. The behavior of the adhesive material NCL1 in the first chip mounting step of the manufacturing method of a semiconductor device according to the present embodiment will next be described.

The technology described in the present embodiment can also be applied to the case where an insulating material film (NCF) is used as in First Embodiment. The spreading direction of the adhesive material NCL2 in plan view can be understood more easily when an insulating material paste (NCP) is used. The present embodiment will therefore be described using, as an example, an aspect in which an insulating material paste (NCP) is used as the adhesive material NCL1.

Steps of the manufacturing method of a semiconductor device described in First Embodiment other than the first adhesive material placement step and the first chip mounting step are performed similarly in the present embodiment. An overlapping description will therefore be omitted in the present embodiment and a description will be made while focusing on the first adhesive material placement step and the first chip mounting step.

### <First Adhesive Material Placement Step>

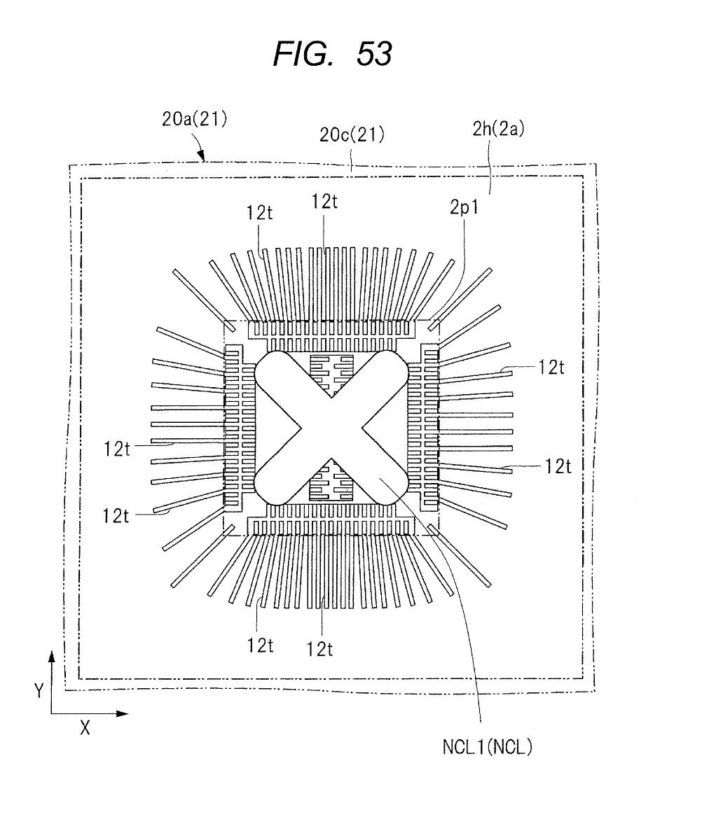

In the first adhesive material placement step of the present embodiment, an adhesive material NCL1 is placed in a chip mounting region 2p1 of a wiring board 21 as shown in FIG. 53. FIG. 53 is an enlarged plan view showing a paste-like adhesive material placed in the chip mounting region of the wiring board, shown as a modification example of FIG. 16.

The wiring board 21 shown in FIG. 53 is similar to the wiring board 20 shown in FIG. 16 except that the wiring board 21 has, in the insulating film 2h on the upper surface 2a thereof, a plurality of trenches 12t and the adhesive material NCL1 is a paste resin. Therefore, an overlapping description is omitted.

In the present step, in the example shown in FIG. 53, the adhesive material NCL1 which is NCP is discharged from a nozzle NZ1 (refer to FIG. 30) to place the adhesive material NCL1 on the chip mounting region 2p1. In the present embodiment, the adhesive material NCL1 spreads peripherally in the first chip mounting step subsequent to the first adhesive material placement step so that in the present step, placement of the adhesive material NCL1 in a portion of the chip mounting region 2p1 is only required. When an insulating material paste (NCP) is used as the adhesive material NCL1, the adhesive material NCL1 is likely to closely conform to the irregularity of the wiring board 21 while the adhesive material NCL1 spreads. In the present embodiment, therefore, the step of firmly attaching the adhesive material NCL1 to the wiring board 20 under reduced pressure atmosphere described in First Embodiment referring to FIG. 19 can be omitted.

FIG. 53 shows an example of placing the adhesive material NCL1 in a cross shape with the central portion of the chip mounting region 2p1 as a center. The planar shape of the adhesive material NCL1 after placement has various modification examples. Examples of the modification example include a method of placing a circular adhesive material NCL1 at the central portion of the chip mounting region 2p1 and a method of placing the adhesive material NCL1 at a plurality of positions in the chip mounting region 2p1.

### <First Chip Mounting Step>

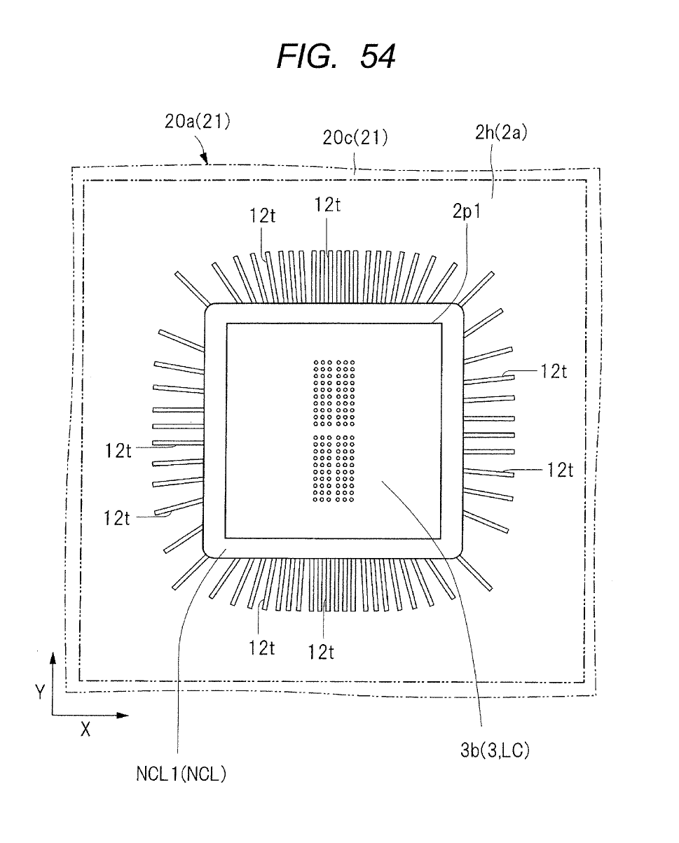

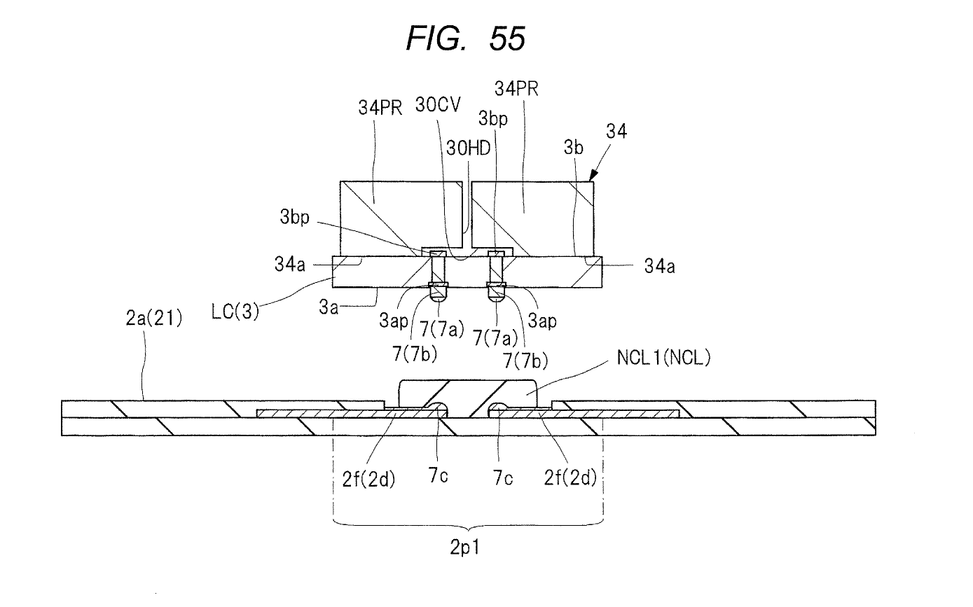

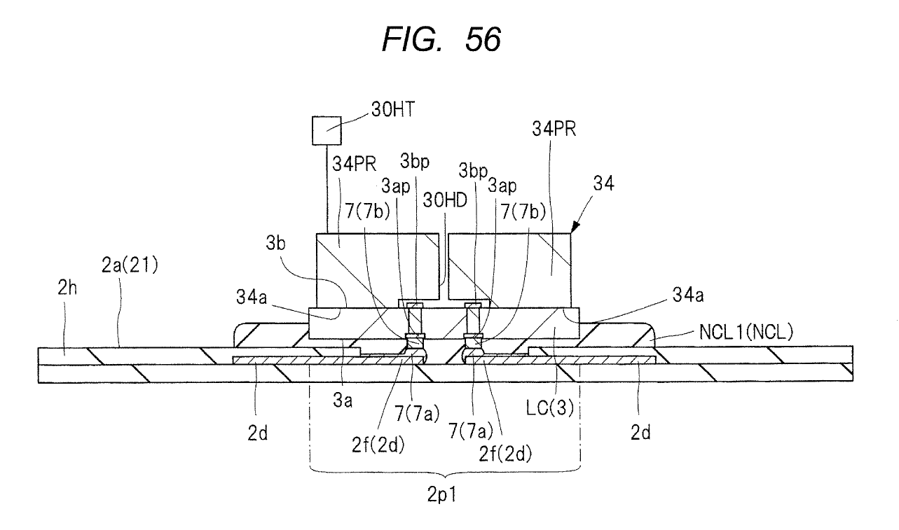

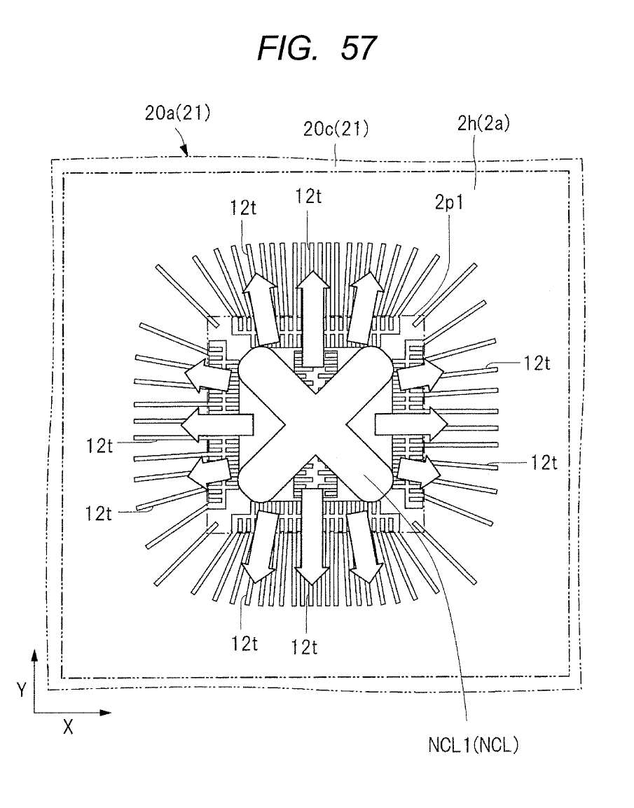

Next, in the first chip mounting step of the present embodiment, as shown in FIG. 54, the logic chip LC is mounted on the wiring board 21. FIG. 54 is an enlarged plan view showing the logic chip LC mounted in the chip mounting region of the wiring board shown in FIG. 53. FIG. 55 is an explanatory view schematically showing the logic chip mounted over the adhesive material placed on the wiring board shown in FIG. 53 in the first chip mounting step. FIG. 56 is an explanatory view schematically showing the logic chip and the wiring board, each shown in FIG. 55, electrically coupled to each other. FIG. 57 is an explanatory view schematically showing, by an arrow, a spreading direction of the adhesive material shown in FIG. 53 in the first chip mounting step.

The present step is similar to the first chip mounting step described in First Embodiment in that the logic chip LC is mounted on the wiring board 21 by using a facedown mounting method (flip chip coupling method). A detailed flow of the first chip mounting step of the present embodiment will next be described, while focusing on a difference from First Embodiment.

The first chip mounting step of the present embodiment includes a first chip conveying step for conveying the logic chip LC (semiconductor chip 3) to over the adhesive material NCL1 in the chip mounting region 2p1 of the wiring board 21 as shown in FIG. 55. The logic chip LC is conveyed to over the adhesive material NCL1 in the chip mounting region 2p1 while being retained, on the back surface 3b of the logic chip, by a bonding jig 34 and placed over the adhesive material NCL1 so that the surface 3a located on the side of the element formation surface faces to the upper surface 21 of the wiring board 20.

The first chip mounting step of the present embodiment includes a bonding step for heating the back surface 3b of the logic chip LC via the bonding jig 34 and pressing the bonding jig 34 against the back surface 3b of the logic chip 1C to electrically couple a plurality of the bonding leads 2f and a plurality of the surface electrodes 3a to each other.

In the bonding step, the pressing portion 34PR of the bonding jig 34 is brought into contact with the back surface 3b of the logic chip LC and the logic chip LC is pressed against the wiring board 21. In the example shown in FIG. 56, a surface 34a of the pressing portion 34PR is brought into contact with the back surface 3b of the logic chip LC. In the present embodiment, the logic chip LC is brought close to the upper surface 2a of the wiring board 21 and then, a plurality of the external terminals 7 and a plurality of the bonding leads 2f are electrically coupled to each other by heating the logic chip LC.

In the first chip mounting step of the present embodiment, the bonding jig 30 shown in FIG. 25 or various modification examples, each described in First Embodiment can also be used. In the example shown in FIG. 55, however, the bonding jig 34 is used. The bonding jig 34 is similar to the bonding jig 30 described in First Embodiment in that the bonding jig 34 has a retention portion 30HD for retaining the back surface 3b of the logic chip LC and the bonding jig 34 has a pressing portion 34PR for pressing the back surface 3b of the logic chip LC.

The bonding jig 34 is different from the bonding jig 30 described in First Embodiment in the following points. In the example shown in FIG. 55, the area of the surface 34a of the pressing portion 34PR is smaller than that of the back surface 3b of the logic chip LC. In addition, the bonding jig 34 is not equipped with the sealing portion 30SL which the bonding jig 30 shown in FIG. 25 has so that the peripheral edge portion of the back surface 3b of the logic chip LC is exposed from the pressing portion 34PR of the bonding jig 34.

In the present embodiment, as shown in FIG. 57, the wiring board 21 has, outside the chip mounting region 2p1 thereof, a plurality of trenches 12t. Since the wiring board has the plurality of trenches 12t, the adhesive material NCL1 is likely to spread along the extending direction of the trenches 12t in the present step. When as shown in FIG. 56, the logic chip LC is pressed against the wiring board 21 with the bonding jig 34, the adhesive material NCL1 spreads from the position, where it has been applied in the first adhesive material placement step, to the peripheral edge portion of the device region 20a, crossing the profile of the chip mounting region 2p1, as shown schematically in FIG. 57 with an arrow. As a result, as shown in FIG. 56, the adhesive material NCL1 pushed to the periphery of the logic chip LC is suppressed from spreading in the thickness direction of the logic chip LC. According to the present embodiment, therefore, by facilitating spreading of the adhesive material NCL1 planarly along the upper surface 2a of the wiring board 21, it is inhibited from spreading in the thickness direction of the logic chip LC.

In the present embodiment, therefore, the adhesive material NCL1 can be inhibited from spreading to the back surface 3b side of the logic chip LC even by using a jig, such as the bonding jig 34, not covering therewith the entirety of the back surface 3b of the logic chip LC.

In the present embodiment, since the adhesive material NCL1 is inhibited from spreading in the thickness direction of the logic chip LC, the adhesive material NCL1 does not easily attach to the bonding jig 34 even without providing the sealing portion 30SL shown in FIG. 25. This facilitates maintenance of the bonding jig 34 because it does not need a member made of a resin likely to deteriorate by heating.

In addition, the logic chip LC and the wiring board 21 can be electrically coupled to each other without having therebetween the resin film 32 shown in FIG. 27 so that the logic chip LC can be mounted using the single path mounting system described in First Embodiment.

As a modification example of the present embodiment, however, the bonding jig 30 described in the above embodiment or the bonding jig shown in the modification examples can be used. As the modification example of the present embodiment, the double path mounting system described in First Embodiment can also be used.

Next, a preferred aspect of a plurality of the trenches 12t formed on the wiring board 21 of the present embodiment will be described. First, as shown in FIG. 52, in the present embodiment, the chip mounting region 2p1 has, at the central portion thereof, an opening portion 2hk from which a plurality of bonding leads 2f is exposed collectively. In the example shown in FIG. 52, the opening portion 2hk provided at the center of the insulating film 2h extends along the direction Y.

In consideration of the behavior of the adhesive material NCL1 (refer to FIG. 56) in the first chip mounting step, when the chip mounting region 2p1 has therein the large opening portion 2hk, the adhesive material NCL1 is likely to spread along the extending direction of the opening portion 2hw. This means that in the example shown in FIG. 52, the amount of the adhesive material NCL1 spreading in the direction Y tends to be larger than the amount of the adhesive material NCL1 spreading in the direction X.

As shown in FIG. 52, therefore, the density of a plurality of the trenches 12t placed so as to extend along the direction Y on the extended line of the opening portion 2hk is preferably set larger than the density of a plurality of the trenches 12t placed so as to extend along the direction X orthogonal to the direction Y. This makes it possible to inhibit the adhesive material NCL1 (refer to FIG. 56) from spreading in the thickness direction of the logic chip LC (refer to FIG. 56) on the extended line of the opening portion 2hk at the central portion.

A plurality of the trenches 12t lie in the insulating film 2h serving as a protective film covering therewith a plurality of the wirings 2d (refer to FIG. 56) formed on the wiring board 21. If formation of the trenches 12t leads to exposure of a part or the whole of the wirings 2d, damage of the wirings 2d or coupling between two adjacent wirings 2d may occur. From the standpoint of protecting the wirings 2d, therefore, the following constitution is preferred.

First, a plurality of the trenches 12t shown in FIG. 52 each preferably extends along an extending direction of the wirings 32d covered with the insulating film 2h. In other words, a plurality of the trenches 12t is each preferably sandwiched between two adjacent wirings 2d of the wirings 2d covered with the insulating film 2h. By forming the trenches 12t along the wirings 2d, a portion of each of the wirings 2d exposed from the insulating film 2h in the trench 12t can be reduced.

When the trenches 12t is covered with the adhesive material NCL1 or adhesive material NCL2 even if a portion of each of the wirings 2d is exposed from the insulating film 2h, the wirings 2d can be protected. A plurality of the trenches 12t is therefore formed within a spreading region of the adhesive material NCL2 in the second chip mounting step described above in First Embodiment. As shown in FIG. 52, a plurality of the trenches 12t particularly preferably lies within a range of the chip mounting region 2p2. A plurality of the trenches 12t, if the trenches 12t are formed to stay inside the chip mounting region 2p2, can be covered securely with the adhesive material NCL1 or adhesive material NCL2.

From the standpoint of stably suppressing the spreading direction of the adhesive material NCL1, a portion of the trench 12t is preferably formed inside the chip mounting region 2p1. For example, in the example shown in FIG. 52, the insulating film 2h has, along each side including the outer periphery of the chip mounting region 2p1, a plurality of opening portions 2hw for exposing therefrom a plurality of the bonding leads 2f collectively. The trenches 12 are each coupled with anyone of the opening portions 2hw. The trenches 12t therefore each have a tip portion thereof inside the chip mounting region 2p1. When a portion of the trench 12t is formed inside the chip mounting region 2p1, the control of the spreading direction of the adhesive material NCL1 can be started earlier, enabling stable control of it.

The present embodiment is similar to First Embodiment except for the above-mentioned difference. An overlapping description will therefore be omitted.

### Modification Example

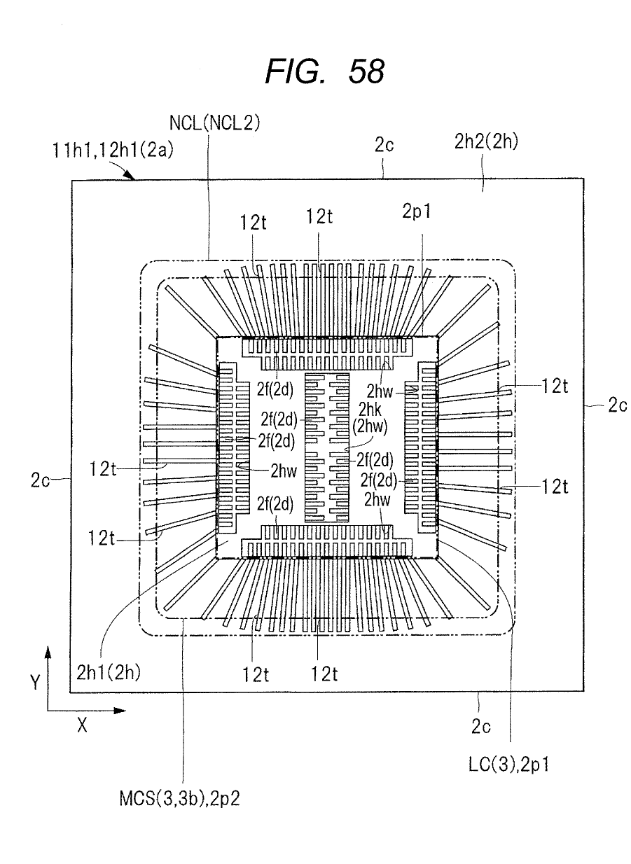

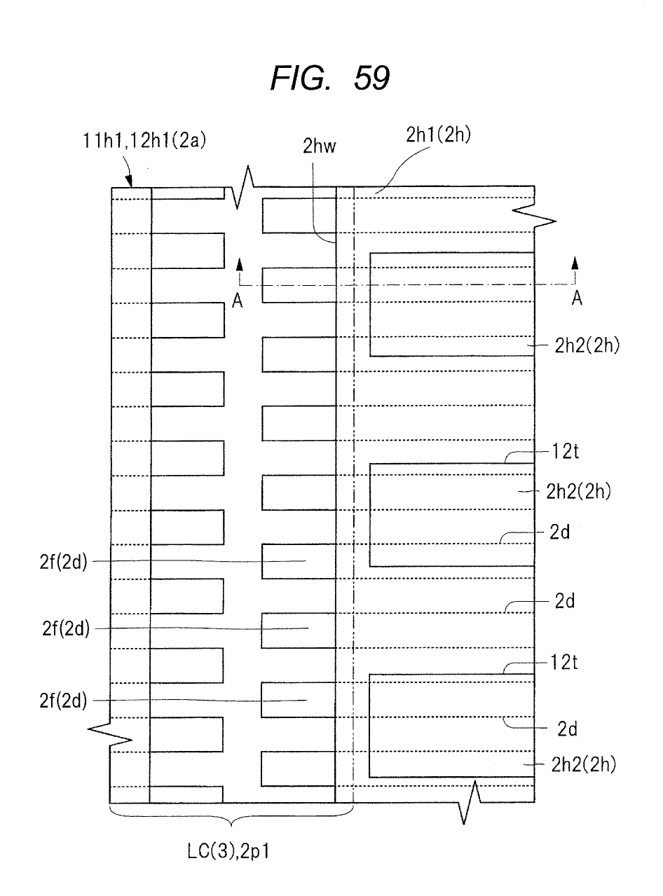

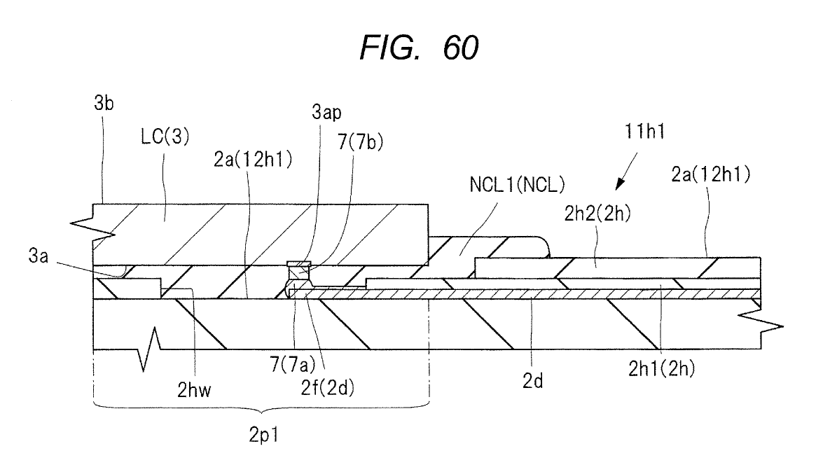

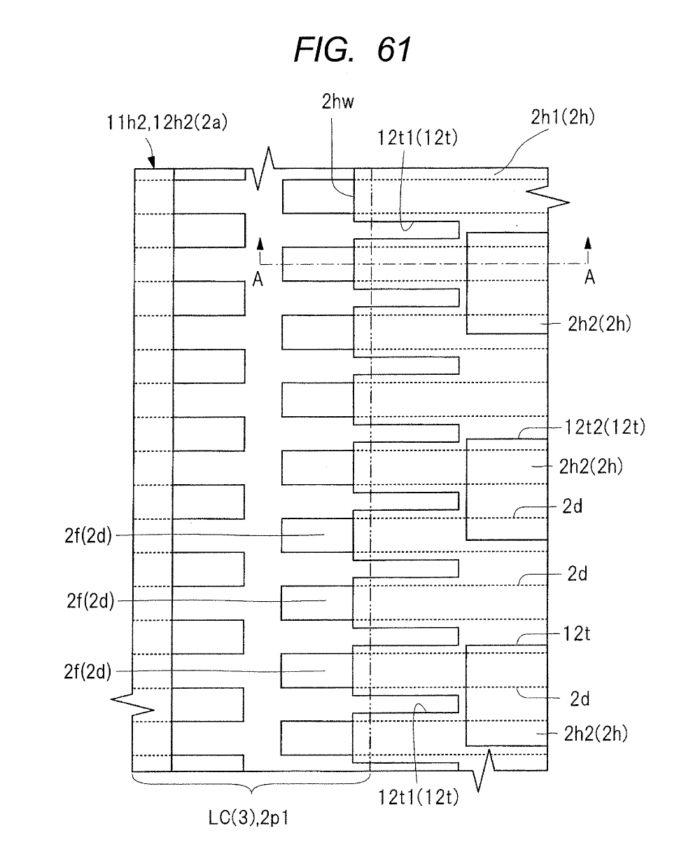

Next, modification examples with respect to the embodiment described referring to FIGS. 52 to 57 will be described. FIG. 58 is a plan view of a semiconductor device, which is a modification example of the semiconductor device shown in FIG. 52, on the side of the chip mounting surface. FIG. 59 is an enlarged plan view showing a boundary portion of the logic chip mounting region of the semiconductor device shown in FIG. 58. FIG. 60 is an enlarged cross-sectional view taken along the line A-A of FIG. 59. FIG. 61 is an enlarged plan view showing a boundary portion of a logic chip mounting region of a semiconductor device which is a modification example of the semiconductor device shown in FIG. 59.

The semiconductor device 11h1 shown in FIGS. 58 to 60 is different from the semiconductor device 11 shown in FIG. 52 in that the insulating film 2h covering the upper surface 2a side of the wiring board 12h1 has a stacked structure in which an insulating film 2h2 has been stacked over an insulating film 2h1.

In the example shown in FIG. 58, the insulating film 2h1 covers the entire upper surface 2a side of the wiring board 12h1 including the chip mounting region 2p1. It however does not cover a portion having therein an opening portion 2hw. The insulating film 2h2, on the other hand, is not formed in the chip mounting region 2p1 but surrounds the periphery of the chip mounting region 2p1.

In the semiconductor device 11h1, the trenches 12t formed in the insulating film 2h are each formed in the insulating film 2h2 placed as an upper layer but are not formed in the insulating film 2h1. This means that a plurality of the wirings 2d to be coupled to a plurality of the bonding leads 2f is covered with the lower insulating film 2h1. The present modification example prevents exposure of the wirings 2d due to the trenches 12t so that limitations on the shape of the trench 12t are fewer than those on the semiconductor device 11h1 shown in FIG. 58. In other words, the present modification example can provide the trenches 12t having an optimum shape from the standpoint of controlling the spreading of the adhesive material NCL1.

For example, in the example shown in FIG. 59, the trenches 12t extend over a plurality of the wirings 2d. In this case, the trenches 12t each have a wider width and such trenches can be obtained by easy processing.

In the present modification example, a plurality of the wirings 2d is each covered with the lower insulating film 2h1 so that a portion of each of the trenches 12t is not necessarily filled with the adhesive material NCL1 or adhesive material NCL2. In the example shown in FIG. 58, the trenches 12t extend to the outside of the chip mounting region 2p2. When the trenches 12t are formed so as to extend to the outside of the chip mounting region 2p2, the spreading direction of the adhesive material NCL2 can be controlled by the trenches 12t in the second chip mounting step described above in First Embodiment. In the example described above in First Embodiment, since the chip stack MCS mounted in the second chip mounting step has a sufficient thickness, even if the adhesive material NCL2 pushed to the periphery of the chip stack MCS spreads in the thickness direction of the chip stack MCS, there is a small possibility of it being brought into contact with the bonding jig. When the memory chips MC1, MC2, MC3, and MC4 are stacked successively and the semiconductor chip 3 stacked as the second or higher layer is thin, however, there is a possibility of the adhesive material NCL2 reaching the back surface 3b side. In this case, it is preferred to form the trenches 12t so as to extend to the outside of the chip mounting region 2p2 and control the spreading direction of the adhesive material NCL2.

As another modification example of FIG. 58, a plurality of trenches 12t can be formed in the insulating film 2h1 and the insulating film 2h2, each covering the upper surface 2a side of the wiring board 12h2, as the semiconductor device 11h2 shown in FIG. 61. In the modification example shown in FIG. 61, the insulating film 2h1 has a plurality of trenches 12t1 extending from the inside of the chip mounting region 2p1 to the peripheral edge portion of the wiring board 12h2. The insulating film 2h2 covering therewith the insulating film 2h1 has a plurality of trenches 12t2. In plan view, a plurality of the trenches 12t2 each lie on the outer peripheral side of the wiring board 12h2 than a plurality of the trenches 12t1.

As described above in First Embodiment, a small distance between the logic chip LC and the wiring board makes it difficult to form the multilayer insulating film 2h immediately below the logic chip LC. When the trenches 12t are not formed in the insulating film 2h1, therefore, the trenches 12t cannot easily be extended to the inside of the chip mounting region 2p1 as shown in FIG. 59.

According to the modification example shown in FIG. 61, by forming a plurality of the trenches 12t1 in the insulating film 2h1, the trenches 12t1 can be extended to the chip mounting region 2p1. In the modification example shown in FIG. 61, even if the extension distance of the trenches 12t1 is decreased, the spreading direction of the adhesive material NCL1 can be controlled by a plurality of the trenches 12t2 formed in the insulating film 2h2.

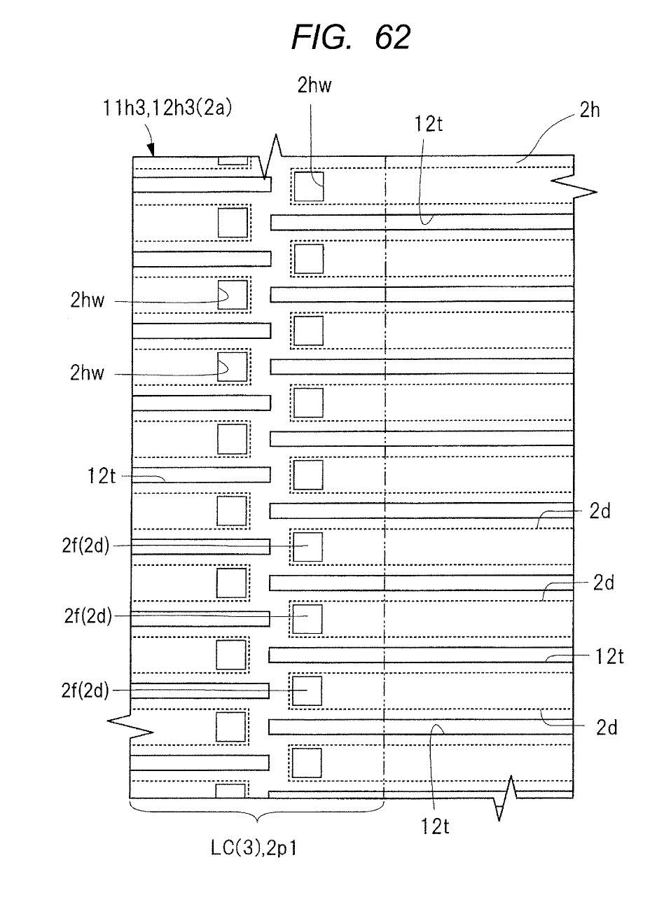

A semiconductor device 11h3 shown in FIG. 62 is different from the semiconductor device 11 shown in FIG. 52 in that an opening portions 2hw formed in the insulating film 2h covering the upper surface 2a side of a wiring board 12h3 are provided at a bonding position of a plurality of the bonding leads 2f. FIG. 62 is an enlarged plan view of a boundary portion of a logic chip mounting region of the semiconductor device which is a modification example of the semiconductor device shown in FIG. 52.

The wiring board 12h3 has the opening portions 2hw selectively at the bonding position of the bonding lead 2f so that the chip mounting region 2p1 has, also inside thereof, the trenches 12t. This makes it possible to control the spreading direction of the adhesive material NCL1 (refer to FIG. 52) from inside the chip mounting region 2p1.

The modification example shown in FIG. 62 is shown representatively as a modification example of the semiconductor device 11 shown in FIG. 52. It can also be combined with each of the modification examples described referring to FIGS. 58 to 61.

The invention made by the present inventors has been described specifically based on embodiments. It is needless to say that the invention is however not limited to or by these embodiments but can be changed without departing from the scope of the invention.

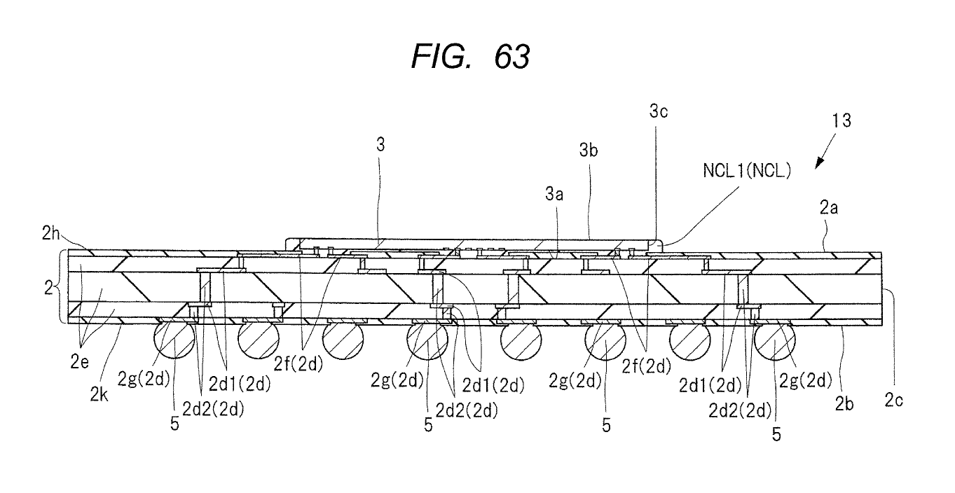

For example, in First to Third Embodiments, the semiconductor device obtained by stacking a plurality of semiconductor chips 3 has been described, but the number of the semiconductor chips 3 to be stacked over the wiring board 2 is not limited. For example, the above-mentioned technology can be applied to a package having a single semiconductor chip 3 on the wiring board 2, like a semiconductor device 13 shown in FIG. 63. In the semiconductor device 13, an increase in the thickness of the package can be suppressed by inhibiting the height of the adhesive material NCL pushed to the periphery of the semiconductor chip 3 from exceeding the height of the back surface 3b of the semiconductor chip 3.

In the above-mentioned embodiments, described is the case where the planar size of the chip stack MCS to be mounted on the upper side is larger than the planar size of the logic chip LC to be mounted on the lower side. The invention however can also be applied to the case where the planar size of the chip stack MCS is smaller than that of the logic chip to be mounted on the lower side.

The embodiments or the modification examples described above in each of the embodiments may be used in combination without departing from the scope of the technical concept described in the above embodiments.

The technical concept will next be extracted from the manufacturing method of the semiconductor device described in the above embodiments.

### [Supplement 1]

A method of manufacturing a semiconductor device, including the steps of:

(a) providing a wiring board having a chip mounting surface, a plurality of terminals formed on the chip mounting surface, and a packaging surface on the side opposite to the chip mounting surface;

(b) placing a first adhesive material on the chip mounting surface of the wiring board; and

(c) after the step (b), mounting a first semiconductor chip having a first surface, a plurality of first surface electrodes exposed from the first surface, a plurality of first bump electrodes bonded to the plurality of first surface electrodes, respectively, a first back surface on the side opposite to the first surface, a first back-surface electrode formed on the first back surface, and a through electrode for electrically coupling some of the first surface electrodes to the first back-surface electrode on the chip mounting surface of the wiring board via the first adhesive material so that the first surface of the first semiconductor chip faces to the chip mounting surface of the wiring board, and thereby electrically coupling the terminals and the first surface electrodes to each other;

wherein the step (c) includes a step of heating the first back surface of the first semiconductor chip via a bonding jig and pressing the bonding jig against the first back surface of the first semiconductor chip to electrically couple the terminals and the first surface electrodes to each other;

wherein the bonding jig has a retention portion for adsorbing and retaining the first semiconductor chip, a pressing portion for pressing against the first back surface of the first semiconductor chip in the step (c), and a sealing portion to be firmly attached to a peripheral edge portion of the first back surface of the first semiconductor chip;

wherein the sealing portion has a frame shape in plan view,

wherein a second surface of the pressing portion is exposed inside the sealing portion in plan view;

wherein the pressing portion has, in a portion of the second surface, a recess portion having a depth greater than the thickness of the first back-surface electrode, and

wherein in the step (C), the first back-surface electrode is housed in the recess portion and the second surface is contiguous to the first back surface.

### [Supplement 2]

A method of manufacturing a semiconductor device, including the steps of:

(a) providing a wiring board having a chip mounting surface, a plurality of terminals formed on the chip mounting surface, and a packaging surface on the side opposite to the chip mounting surface;

(b) placing a first adhesive material on the chip mounting surface of the wiring board, and

(c) after the step (b), mounting a first semiconductor chip having a first surface, a plurality of first surface electrodes exposed from the first surface, a plurality of first bump electrodes bonded to the plurality of first surface electrodes, respectively, and a first back surface on the side opposite to the first surface on the chip mounting surface of the wiring board via the first adhesive material so that the first surface of the first semiconductor chip faces to the chip mounting surface of the wiring board and thereby electrically coupling the terminals and the first surface electrodes to each other;

wherein the step (b) includes the steps of:

(b1) retaining the first adhesive material in film form by means of a film conveyor jig and conveying the material to over the chip mounting surface of the wiring board;

(b2) pressing a plurality of protruding portions provided on the film conveyor jig against the first adhesive material to locally press the first adhesive material, and

(b3) pressing the first adhesive material against the chip mounting surface of the wiring board under reduced pressure atmosphere to firmly attach the first adhesive material to the chip mounting surface of the wiring board.

### [Supplement 3]

A semiconductor device including:

a wiring board having a chip mounting surface, a plurality of terminals formed on the chip mounting surface, a plurality of wirings formed on the chip mounting surface and to be electrically coupled to the terminals, an insulating film formed to cover therewith the wirings, and a packaging surface on the side opposite to the chip mounting surface; and

a first semiconductor chip having a first surface, a plurality of first surface electrodes exposed from the first surface, a plurality of first bump electrodes bonded to a plurality of the first surface electrodes, respectively, and a first back surface on the side opposite to the first surface and mounted on the chip mounting surface of the wiring board via a first adhesive material so that the first surface faces to the first chip mounting region of the chip mounting surface of the wiring board,

wherein the insulating film of the wiring board has therein a plurality of trenches extending from the first chip mounting region to the peripheral edge portion of the wiring board in plan view.

### [Supplement 4]

The semiconductor device according to Supplement 3,

wherein a portion of the insulating film overlapping with the first chip mounting region has a first opening portion extending in a first direction and from which the terminals are exposed collectively, and

wherein the trenches have a plurality of first trenches and a plurality of second trenches and a density of first trenches placed on an extended line of the first opening portion so as to extend along the first direction is greater than a density of the second trenches placed to extend along a second direction orthogonal to the first direction.

### [Placement 5]

The semiconuctor device according to Supplement 3,

wherein a portion of each of the trenches lies inside the first chip mounting region.

### [Supplement 6]

The semiconductor device according to Supplement 6,

wherein the insulating film has a first insulating film covering therewith the wirings and a second insulating film stacked to cover a portion of the first insulating film, and

wherein the trenches are formed in the second insulating film.

### [Supplement 7]

The semiconductor device according to Supplement 6,

wherein the second insulating film is formed at a position not overlapping with the first chip mounting region in plan view;

wherein the first insulating film has therein a plurality of first trenches, and

wherein the trenches formed in the second insulating film are second trenches.

### [Supplement 8]

The semiconductor device according to Supplement 6,

wherein the first insulating film does not have therein the trenches.

What is claimed is:

1. A method of manufacturing a semiconductor device, comprising the steps of:
(a) providing a wiring board having a chip mounting surface, a plurality of terminals formed over the chip mounting surface, and a packaging surface over a side opposite to the chip mounting surface;
(b) placing a first adhesive material over the chip mounting surface of the wiring board; and
(c) after the step (b), mounting a first semiconductor chip having a first surface, a plurality of first surface electrodes exposed from the first surface, a plurality of first bump electrodes bonded to the plurality of the first surface electrodes, respectively, and a first back surface on the side opposite to the first surface over the chip mounting surface of the wiring board via the first adhesive material so that the first surface of the first semiconductor chip faces to the chip mounting surface of the wiring board and thereby electrically coupling the terminals and the first surface electrodes to each other;
wherein the step (c) comprises the steps of:
(c1) conveying the first semiconductor chip to over the first adhesive material while adsorbing and retaining the first back surface of the first semiconductor chip by means of a bonding jig; and
(c2) heating the first semiconductor chip from a side of the first back surface thereof by means of the bonding jig and pressing the bonding jig against the first semiconductor chip from the side of the first back surface thereof to electrically couple the terminals and the first surface electrodes to each other;
wherein the bonding jig has a retention portion for adsorbing and retaining the first semiconductor chip therewith, a pressing portion for pressing against the first back surface of the first semiconductor chip in the step (c2), and a sealing portion to be firmly attached to a peripheral edge portion of the first back surface of the first semiconductor chip, and
wherein a first surface of the sealing portion facing to the first back surface of the first semiconductor chip has a resin.

2. The method of manufacturing a semiconductor device according to claim 1,
wherein the sealing portion has a frame shape in plan view;
wherein a second surface of the pressing portion is exposed inside the sealing portion in plan view,
wherein in the step (c2), the first surface of the sealing portion is firmly attached to the first back surface of the first semiconductor chip over the entire circumference of the peripheral edge portion of the first back surface of the first semiconductor chip and the second surface of the pressing portion comes into contact with a portion of the first semiconductor chip.

3. The method of manufacturing a semiconductor device according to claim 2,
wherein the sealing portion is detachable from the pressing portion, and
wherein in the step (c2), the sealing portion is retained by a sealing portion retention portion formed in the pressing portion.

4. The method of manufacturing a semiconductor device according to claim 3,
wherein the pressing portion has an air inlet hole for adsorbing and retaining the sealing portion.

5. The method of manufacturing a semiconductor device according to claim 2,
wherein the sealing portion has a resin film having the first surface and a support portion having the resin film.

6. The method of manufacturing a semiconductor device according to claim 1,
wherein an area of a second surface of the pressing portion facing to the first semiconductor chip in the step (c2) is greater than an area of the first back surface of the first semiconductor chip, and
wherein the second surface of the pressing portion has a resin film having the first surface of the sealing portion.

7. The method of manufacturing a semiconductor device according to claim 2,
wherein the pressing portion has a trench portion having a frame shape in plan view, and
wherein the sealing portion having a resin as a whole is inserted in the trench portion in the frame form.

8. The method of manufacturing a semiconductor device according to claim 7,
wherein the trench portion has, as both side surfaces thereof, a surface inclined at an angle less than 90 degrees with respect to the second surface of the pressing portion.

9. The method of manufacturing a semiconductor device according to claim 2,
wherein a stepped portion is provided at a position where the sealing portion having a resin as a whole is retained, and
wherein the side surface of the stepped portion is a surface inclined at an angle less than 90 degrees with respect to the second surface of the pressing portion.

10. The method of manufacturing a semiconductor device according to claim 1,
wherein the first semiconductor chip has a first back-surface electrode to be electrically coupled to some of the first surface electrodes and a through electrode for electrically coupling some of the first surface electrodes and the first back-surface electrode to each other.

11. The method of manufacturing a semiconductor device according to claim 10,
wherein the sealing portion has a frame shape in plan view;
wherein in plan view, a second surface of the pressing portion is exposed inside the sealing portion;
wherein the pressing portion has, in a portion of the second surface thereof, a recess deeper than the thickness of the first back-surface electrode, and
wherein in the step (C2), the first back-surface electrode is housed in the recess and the second surface is brought into contact with the first back surface.

12. The method of manufacturing a semiconductor device according to claim 10, further comprising the steps of:
(d) placing a second adhesive material over the first back surface of the first semiconductor chip, and
(e) after the step (d), mounting a second semiconductor chip having a second surface, a plurality of second surface electrodes exposed from the second surface, a plurality of second bump electrodes bonded to the plurality of second surface electrodes, respectively, and a second back surface on the side opposite to the second surface over the first back surface of the first semiconductor chip via the second adhesive material so that the second surface of the second semiconductor chip faces to the first back surface of the first semiconductor chip and thereby electrically couple the first back-surface electrodes formed over the first back surface of the first semiconductor chip and the second surface electrodes of the second semiconductor chip to each other.

13. The method of manufacturing a semiconductor device according to claim 1,
wherein the step (b) comprises the steps of:
(b1) retaining the first adhesive material formed in film form via a film conveyor jig and conveying the first adhesive material to over the chip mounting surface of the wiring board;
(b2) pressing a plurality of protruding portions which the film conveyor jig has against the first adhesive material and locally pressing the first adhesive material, and
(b3) pressing the first adhesive material against the chip mounting surface of the wiring board under reduced pressure atmosphere to firmly attach the first adhesive material to the chip mounting surface of the wiring board.

14. The method of manufacturing a semiconductor device according to claim 1,
wherein the chip mounting surface of the wiring board covers therewith a plurality of wirings formed on the side of the chip mounting surface of the wiring board and is covered with an insulating film having therein an opening portion from which a plurality of terminals is exposed, and
wherein the insulating film has, in plan view, a plurality of trenches extending from the first chip mounting region overlapping with the first semiconductor chip in thickness direction in the step (c) to the outside.

15. A method of manufacturing a semiconductor device, comprising the steps of:
(a) providing a wiring board having a chip mounting surface, a plurality of terminals formed over the chip mounting surface, a plurality of wirings formed over the chip mounting surface and to be electrically coupled to the terminals, an insulating film covering therewith the wirings, and a packaging surface on the side opposite to the chip mounting surface,
(b) placing a first adhesive material in the first chip mounting region of the chip mounting surface of the wiring board, and
(c) after the step (b), mounting a first semiconductor chip having a first surface, a plurality of first surface electrodes exposed from the first surface, a plurality of first bump electrodes bonded to the plurality of first surface electrodes, respectively, and a first back surface on the side opposite to the first surface over the chip mounting surface of the wiring board via the first adhesive member so that the first surface of the first semiconductor chip faces to the first chip mounting region of the chip mounting surface of the wiring board and thereby electrically coupling the terminals and the first surface electrodes to each other,
wherein the insulating film of the wiring board has, in plan view, a plurality of trenches extending from the first chip mounting region to the outside.

16. The method of manufacturing a semiconductor device according to claim 15,
wherein the insulating film has, in a portion thereof overlapping with the first chip mounting region, a first opening portion extending along a first direction and exposing the terminals therefrom collectively,
wherein the trenches have a plurality of first trenches and a plurality of second trenches and a density of the first trenches placed on an extended line of the first opening portion and extending along the first direction is greater than a density of the second trenches placed to extend along a second direction orthogonal to the first direction.

17. The method of manufacturing a semiconductor device according to claim 15,
wherein a portion of each of the trenches is inside the first chip mounting region.

18. The method of manufacturing a semiconductor device according to claim 15,
wherein the insulating has a first insulating film covering therewith the wirings and a second insulating film stacked so as to cover a portion of the first insulating film; and
wherein the second insulating film has therein the trenches.

19. The method of manufacturing a semiconductor device according to claim 18,
wherein the second insulating film lies, in plan view, at a position not overlapping with the first chip mounting region;
wherein the first insulating film has therein the first trenches, and
wherein the trenches formed in the second insulating film are the second trenches.

20. The method of manufacturing a semiconductor device according to claim 18,
wherein the first insulating film does not have the trenches.
